(19) United States
(12) Patent Application Publication
(10) Pub. No.: US 2007/0170910 A1
(43) Pub. Date: Jul. 26, 2007

(54) Spectral resistor, spectral capacitor, order-infinity resonant tank, EM wave absorbing material, and applications thereof

(76) Inventors: Ming-Hoo Chang, Taipei (TW); Tsun-Cheng Lin, Taipei (TW); Yen-Tang Hsu, Taipei (TW); Yen-Weay Hsu, Taipei (TW)

Correspondence Address: LADAS & PARRY, 26 WEST 61ST STREET, NEW YORK, NY, 10023, US

(21) Appl. No.: 11/341,105

(22) Filed: Jan. 26, 2006

(51) Int. Cl. G01R 31/28

(52) U.S. Cl. 324/158.1

(57) ABSTRACT

A spectral resistor based on the constitute law of “elasticity of electricity” derived from the Riemann-Lebesgue lemma is provided to build a substantial order-∞ resonant tank. The substantial order-∞ resonant tank according to embodiments of the present invention can function as many different roles such as an electric filter, a harmonic and sub-harmonic power waveform distortion filter, a dynamic damper, a dynamic impedance matching circuit and a kind of electromagnetic wave absorbing material. By attaching an order-∞ resonant tank according to the present invention to an ordinary system with equivalent inductance in a suitable topology as an electric filter, a substantial snubber network, or so-called DeLenzor, is obtained. The duality of an electric system can be handled by coupling the system with an order-∞ resonant tank according to the present invention, and thus the disadvantageous effects caused by the duality of the system can be canceled immediately without any drawbacks. Furthermore, the reactive (or so-called regenerated) power caused by the duality of the electric system can be recycled according to embodiments of the present invention.

### FIELD OF THE INVENTION

The invention is related to nonlinear and/or dynamic electric circuits and systems, and also may be applicable to power recycling, power management, EM wave absorbing and signal extracting.

### BACKGROUND OF THE INVENTION

In the electric field, nonlinear loads, dynamic loads or unbalanced sources are the common working environments, for example, the electric vehicles, hybrid power vehicles as disclosed in Chapter 4 of [43] (please refer to Appendix I), the CD-ROMs as disclosed in [48], [47] and Chapter 6 of [50], high-power devices, and so on. However, to perform dynamic impedance matching to nonlinear loads is very difficult. Take the system shown in FIG. 47 for example, if only Load₁ 4701, Load₂ 4702 and Load₃ 4703 exist in the system originally, and then a new load(s) 4704 is added into the system, the total impedance of the system would suddenly change, and disadvantageous effects such as electric arc and power waveform distortions would possibly occur.

In an electrical power system, the nonlinearity comes from switching on/off actions and reactions when power converters (such as AC-to-DC converters, DC-to-DC converters, DC-to-AC converters, and AC-to-AC converters, referring to [80], [53] and Chapters 5-7 of [62]) are used. The nonlinearity brings into power waveform distortions such as harmonic and sub-harmonic distortions as discussed in Appendix E. How to remove the distorted power waveforms becomes a very important issue. Many researches (as disclosed in [72], [41], [62], [58], [52], [39], [8], [33], [59], [21], [16], and [15]) try to find practical ways to deal with these complex problems. However, since power sources are polluted by the harmonic, sub-harmonic or inter-harmonic distorted power waveforms contributed by inverter-base, switching-mode power driving devices or nonlinear loads/sources, according to the references [62], [53], [25], [54], [55] and [56], it is impossible for conventional techniques to clean the distorted power waveforms out entirely to obtain the best power quality.

The nonlinearity comes from the duality of an electric system. As shown in FIG. 4 (referring to Page 56 of [5] and Chapter 6 of [43]), when IGBT₁ (Integrated Gate Bipolar Transistor) 401 and IGBT₄ 402 are turned on at the same time, the current from point R 403 passing through coils Φ₁ 406 and Φ₂ 407 and then returning to point S 404 forms a loop. As IGBT₁ 401 and IGBT₄ 402 are turned off simultaneously, the current from S 404 immediately returns backward to the DC bus through the R 403 and via the dissipative diode D₁ 409, wherein the returning current will result in a conflicting voltage that will modify the V_{DC}. At the next stage, when IGBT₃ 410 and IGBT₆ 411 are turned on, the modified voltage V_{DC} is applied to a loop from point S 404 via coils Φ₂ 407 and Φ₃ 408 to point T 405; and when the IGBT₃ 410 and IGBT₆ 411 are turned off simultaneously, a returning voltage will modify the modified V_{DC} again. Therefore, the voltage V_{DC} will be modified many times by returning EMF (Electromotive Force). For a heavy load system, such as a high-power Electric Vehicle, this duality phenomenon will cause power interference (or (sub)harmonic distortion waveforms) at each phase, which results in high temperature occurring at the six IGBTs, diodes and the coils Φ₁ 406, Φ₂ 407 and Φ₃ 408, and thus the system may be damaged.

A common troublesome problem is the DC charger pump that works with low performance and produces a number of heat sources. For each phase, it is expressed in the form of

$${V}_{DC} - e = L \frac{ⅆ i}{ⅆ t} + R i$$

during phase-on period and in the form of

$$- {V}_{DC} - e = L \frac{ⅆ i}{ⅆ t} + Ri$$

during phase-off period, wherein L, e, i, R are the corresponding inductance, returning EMF, current and system resistance, respectively, and e>0. If it is under the condition of heavy loads, e will be greater than V_{DC} and its current i will increase even during phase-off period. This regenerated power source will seriously affect system reliability and create high operating temperature.

According to prior art references (Vol. 2 Chapter 8, 9, 10, 11, 22, 23 of [74], Page 173 of [24] and Page 181 of [5]), although to construct an order-k resonant tank is complex, it is still possible as long as k is a finite number as follows:
0<k<M
where M is a positive constant. An order-k resonant tank can be constructed based on the circuit shown in FIG. 46. According to Thevenin's theorem and Norton's theorem, the circuit shown in FIG. 46 is totally equivalent to a specific mode with specific Cₑ, Lₑ, and resonant frequency

$${ω}_{r} = \frac{1}{\sqrt{{L}_{e} {C}_{e}}} .$$

If k switches S₁, S₂, . . . , Sₖ are added to the circuit shown in FIG. 46, we can obtain an order-k resonant tank, wherein each mode of the order-k resonant tank can be obtained by turning on/off corresponding switches.

In practice, there exists much more complex interactions between nonlinear loads and power supplies in an electrical power system, and a finite-order resonant tank does not fully match to the system. Therefore, to construct an order-∞ resonant tank is desired for a long time. If the idea of constructing an order-k resonant tank is extended to that of an order-∞ resonant tank, infinite number of inductors, capacitors, and switches should exist and be electrically interconnected. Obviously, it is impossible to construct an order-∞ resonant tank based on the fundamental circuit shown in FIG. 46.

### SUMMARY OF THE INVENTION

To overcome the problems suffered by working on nonlinear and/or dynamic electric circuits and systems, the present invention provides a spectral resistor (which resistance varies with frequency) based on the constitute law of “elasticity of electricity” derived from the Riemann-Lebesgue lemma to successfully build a substantial order-∞ resonant tank. The substantial order-∞ resonant tank according to embodiments of the present invention can function as many different roles such as an electric filter, a harmonic and sub-harmonic power waveform distortion filter, a dynamic damper, a dynamic impedance matching circuit and a kind of electromagnetic wave absorbing material.

By attaching an order-∞ resonant tank according to the present invention to an ordinary system with equivalent inductance in a suitable topology as an electric filter, a substantial snubber network, or so-called DeLenzor, is obtained. The duality of an electric system can be handled by coupling the system with an order-∞ resonant tank according to the present invention, and thus the disadvantageous effects caused by the duality of the system can be canceled immediately without any drawbacks. Furthermore, the reactive (or so-called regenerated) power caused by the duality of the electric system can be recycled according to embodiments of the present invention. Therefore, according to embodiments of the present invention, an improved non-contact anti-skid braking system (ABS), a non-contact anti-crash transporting device (such as an elevator or a lift) can be obtained. Moreover, an electric vehicle or a hybrid-electric vehicle with better performance by utilizing the regenerated and/or recycled electric power can also be obtained.

To cope with the most complex power harmonic distortion problems, an order-∞ resonant tank according to the present invention is attached to a power system as a harmonic and sub-harmonic power waveform distortion filter to absorb, attenuate, damp, dissipate or even recycle the regenerated power. The primary benefit is that

$$\frac{ⅆ v}{ⅆ t} or \frac{ⅆ i}{ⅆ t}$$

is removed, and thus no interference source, such as RFI (Radio Frequency Interference), EMI (Electromagnetic Interference) and EMC (Electromagnetic Compatibility), appears. Therefore, the purified power has good qualities, i.e., the (sub)harmonic, notching, DC offset and noise waveforms are filtered out completely. DC offset (bias) is also an intrinsic factor of power waveform distortion, and it still exists in all dynamic systems, such as the inertial navigation system. By attaching an order-∞ resonant tank according to the present invention as an electric filter, the DC offset can be removed. According to the present invention, there are many other applications of an order-∞ resonant tank, such as a sparkless electric switch and a pseudo vacuum tube power amplifier.

By attaching an order-∞ resonant tank according to the present invention to a power system as a dynamic impedance matching circuit for performing dynamic impedance matching with nonlinear load(s) of the power system, a dynamic power factor corrector circuit can be obtained to substantially keep the power factor of the power system to be one such that the utilization of power can be optimized. In addition, the electric power extracted by the dynamic power factor corrector circuit can be recycled. An uninterruptible power supply apparatus and a redundant uninterruptible power supply system, comprising the dynamic power factor corrector circuit according to embodiments of the present invention, can be obtained. Moreover, improved electric power resource management systems, including the dynamic power factor corrector circuit according to embodiments of the present invention, for predicting the future need of power and dispatching power accordingly by using a prediction algorithm, such as Improved Discounted Least Square (IDLS) method, can be obtained.

An electromagnetic wave absorbing material having the characteristics of the order-∞ resonant tank according to embodiments of the present invention is provided. The provided electromagnetic wave absorbing material can be used to extract electric power from many different energy sources (such as source of radioactive decay energy) or damp out unwanted electric power (such as electrostatic discharge). Therefore, a microwave absorber, an electrostatic discharge protector, an antenna with arbitrary shape, a radio frequency identification device, a nuclear power converting apparatus for collecting the scattering-charged electrons and a data transmission bus using the provided electromagnetic wave absorbing material can be obtained.

Furthermore, according to embodiments of the present invention, a spectral capacitor (which capacitance varies with the frequency), based on the constitute law of elasticity of electricity, is provided and can be utilized in many applications, such as an adaptive voltage controlled oscillator circuit and a phase-locked loop circuit.

According to an embodiment of the present invention, a spectral resistor is provided, wherein at least a part of said spectral resistor is made of a dielectric material; and the resistance of said spectral resistor monotonically increases with increasing frequency.

According to a different embodiment of the present invention, another spectral resistor is provided, wherein at least a part of said spectral resistor is made of a dielectric material; and the resistance of said spectral resistor monotonically decreases with increasing frequency.

According to the present invention, a substantial Gunn diode can be used to be a spectral resistor with resistance monotonically decreases with increasing frequency.

According to an embodiment of the present invention, a spectral resistive element is provided, wherein the resistance of a first part of said spectral resistive element monotonically increases with increasing frequency, while the resistance of a second part of said spectral resistive element monotonically decreases with increasing frequency; and wherein said first part is electrically connected in series to said second part.

According to the present invention, a substantial order-∞ resonant tank is provided. The substantial order-∞ resonant tank comprises the spectral resistive element described above, a substantial capacitive element and a substantial inductive element; wherein said spectral resistive element, said substantial capacitive element and said substantial inductive element are electrically connected to form a substantial order-∞ resonant circuit.

According to a different embodiment of the present invention, another spectral resistive element is provided, wherein the resistance of a first part of said spectral resistive element monotonically increases with increasing frequency, while the resistance of a second part of said spectral resistive element monotonically decreases with increasing frequency; and wherein said first part is electrically connected in parallel to said second part.

According to the present invention, a substantial order-∞ electric filter, for electrically connecting to a substantial inductive circuit to perform filtering operation, comprises the provided substantial order-∞ resonant tank, wherein said substantial order-∞ resonant tank is electrically connected in parallel to said substantial inductive circuit.

According to the present invention, a harmonic and sub-harmonic power waveform distortion filter, for electrically connecting to a substantial inductive circuit to filter out harmonic and sub-harmonic power waveform distortion, comprises the provided substantial order-∞ resonant tank; wherein said substantial order-∞ resonant tank is electrically connected in parallel to said substantial inductive circuit.

According to the present invention, a dynamic damper, for electrically connecting to a substantial inductive circuit to perform damping operation, comprises the provided substantial order-∞ resonant tank; wherein said substantial order-∞ resonant tank is electrically connected in parallel to said substantial inductive circuit.

According to the present invention, an universal dissipative unit, for electrically connecting to a substantial inductive circuit to perform power dissipation operation, comprises the provided substantial order-∞ resonant tank; wherein said substantial order-∞ resonant tank is electrically connected in parallel to said substantial inductive circuit.

According to the present invention, a sparkless electric switch circuit, comprises a switching element and the provided substantial order-∞ resonant tank; wherein said substantial order-∞ resonant tank is electrically connected in parallel to said switching element.

According to the present invention, an inertial navigation system comprises a sensing element and the provided substantial order-∞ resonant tank; wherein said substantial order-∞ resonant tank is electrically connected to said sensing element for extracting pure AC signal from an output of said sensing element.

According to the present invention, a dynamic impedance matching circuit, for performing impedance matching with at least one nonlinear load, comprises the provided substantial order-∞-resonant tank; wherein said substantial order-∞ resonant tank is electrically connected in parallel to said at least one nonlinear load.

According to the present invention, a dynamic power factor corrector circuit, receiving power from an external power source and connected to at least one nonlinear load, comprises a switching element, a switching controller and the provided substantial order-∞ resonant tank; wherein said substantial order-∞ resonant tank is electrically connected in parallel to said at least one nonlinear load; and wherein said dynamic power factor corrector circuit receives power in a first form from said external power source, converts said power from said first form to a second form by switching said switching element on and off at an adjustable frequency, and provides said power in said second form to said at least one nonlinear load; and wherein said adjustable frequency is controlled by said switching controller according to said at least one nonlinear load.

According to the present invention, an uninterruptible power supply apparatus comprises the dynamic power factor corrector circuit as described above, a transformer, a AC-to-DC converter and an electric energy storage element, wherein said transformer regenerates power from the current induced by said at least one nonlinear load and extracted by said substantial order-∞ resonant tank, and said AC-to-DC converter converts said regenerated power to become DC power; and wherein said DC power is provided to said electric energy storage device; and wherein said uninterruptible power supply apparatus provides power to said at least one nonlinear load from said electric energy storage device.

According to the present invention, a redundant uninterruptible power supply system comprises a plurality of the uninterruptible power supply apparatuses as described above; wherein said plurality of uninterruptible power supply apparatuses are electrically connected in parallel to each other.

According to an embodiment of the present invention, an electric power resource management system comprises the dynamic power factor corrector circuit as described above, wherein said dynamic power factor corrector circuit reports power status data to said external power source; and wherein said external power source calculates a future need of power of said at least one nonlinear load by using said power status data and a prediction algorithm.

According to a different embodiment of the present invention, another electric power resource management system comprises the dynamic power factor corrector circuit as described above; wherein said dynamic power factor corrector circuit calculates a future need of power of said nonlinear load by using a prediction algorithm and reports the calculated data to said external power source.

According to the present invention, a pseudo vacuum tube power amplifier, connected between an audio signal source and a speaker, comprises a dynamic power factor corrector circuit as described above; wherein said dynamic power factor corrector circuit receives audio signal from said audio signal source, amplifies said audio signal, and provides the amplified audio signal to said speaker.

According to the present invention, an electromagnetic wave absorbing material comprises a first dielectric material and a second dielectric material; wherein at least a part of said first dielectric material is substantially electrically connected to at least a part of said second dielectric material; and wherein the resistance of said first dielectric material monotonically increases with increasing frequency, and the resistance of said second dielectric material monotonically decreases with increasing frequency.

According to the present invention, a microwave absorber comprises a surface and the electromagnetic wave absorbing material as described above; wherein said electromagnetic wave absorbing material is arranged on said surface.

According to the present invention, an electrostatic discharge protector comprises a surface and the electromagnetic wave absorbing material as described above; wherein said electromagnetic wave absorbing material is arranged on said surface.

According to the present invention, an antenna comprises a surface and the electromagnetic wave absorbing material as described above; wherein said electromagnetic wave absorbing material is arranged on said surface and is substantially electrically connected to said surface.

According to the present invention, a radio frequency identification device comprises a radio frequency identification controller and an antenna as described above, wherein said antenna is electrically connected to said controller.

According to the present invention, a nuclear power converting apparatus comprises a nuclear material, a container, containing said nuclear material and the electromagnetic wave absorbing material as described above; wherein said electromagnetic wave absorbing material is arranged on at least a part of the surface of said container to extract electric power from radioactive decay energy released by said nuclear material.

According to the present invention, a data transmission bus, electrically connected to digital controllers, comprises the electromagnetic wave absorbing material as described above.

According to the present invention, a fanless cooling system, for electrically connecting to a substantial inductive circuit, comprises a substantial order-∞ resonant tank according to the present invention, wherein said substantial order-∞ resonant tank is electrically connected in parallel to said substantial inductive circuit to perform power dissipation.

According to the present invention, a spectral capacitor comprises a first plate, a second plate, a first dielectric material and a second dielectric material; wherein said first and second dielectric materials are arranged between said first plate and said second plate; and wherein the capacitance of said first dielectric material monotonically increases with increasing frequency, and the capacitance of said second dielectric material monotonically decreases with increasing frequency.

According to the present invention, an adaptive voltage controlled oscillator circuit comprises a spectral capacitor as described above and a voltage controlled oscillator; wherein said spectral capacitor is connected in parallel to the input of said voltage controlled oscillator.

According to the present invention, a phase-locked loop circuit comprises a phase detector, a low pass filter connected to said phase detector, and an adaptive voltage controlled oscillator circuit as described above; wherein said voltage controlled oscillator circuit receives a signal from said low pass filter and provides a feedback signal to said phase detector.

According to the present invention, a non-contact anti-skid braking system, used in a vehicle having a transmission line, comprises a rotor driven by an element on said transmission line, an electric power storage device, a brake controller, a pulse-width modulation controller triggered by said brake controller to receive power from said electric power storage device and provide pulse-width modulated DC current to said rotor, a stator and the provided substantial order-∞ resonant tank connected in series to said stator; wherein when said DC current pass through said rotor, an AC current is induced at said stator and extracted by said substantial order-∞ resonant tank.

According to the present invention, a hybrid-electric vehicle comprises the non-contact anti-skid braking system as described above.

According to the present invention, an electric vehicle comprises the non-contact anti-skid braking system as described above.

According to the present invention, a power generating apparatus, for generating electrical energy, comprises a rotor, driven by a mechanical force; a stator; and a substantial order-∞ resonant tank according to the present invention, connected in series to said stator; wherein when said rotor is driven, an AC current is induced at said stator and extracted by said substantial order-∞ resonant tank.

According to the present invention, a non-contact anti-crash transporting device comprises a frame for providing vertical transportation, a first coil arranged vertically in parallel to said frame without contact, a second coil attached to said frame, a cable connected to said frame, a detector for detecting an event of a breach of said cable and for providing a signal indicating said event, a controller for providing power to said first coil in response to said signal, and the provided substantial order-∞ resonant tank connected in series to said second coil.

According to the present invention, a switching-mode power converting apparatus, receiving power from an external power source and connected to at least one nonlinear load, comprises a switching element, a switching controller and the provided substantial order-∞ resonant tank; wherein said substantial order-∞ resonant tank is electrically connected in parallel to said at least one nonlinear load; and wherein said switching-mode power converting apparatus receives power in a first form from said external power source, converts said power from said first form to a second form by switching said switching element on and off at an adjustable frequency, and provides said power in said second form to said at least one nonlinear load; and wherein said adjustable frequency is controlled by said switching controller according to said at least one nonlinear load.

According to the present invention, an electric vehicle comprises the switching-mode power converting apparatus as described above.

### BRIEF DESCRIPTION OF THE DRAWINGS

FIG. 1 illustrates an example of a parallel-RLC oscillator.

FIG. 2 illustrates an example of a series-RLC oscillator.

FIG. 3 illustrates a limit cycle of Van Der Pol oscillator.

FIG. 4 illustrates an example of the duality of a system.

FIG. 5 illustrates a conventional online uninterruptible power supply (UPS).

FIG. 6 illustrates a conventional standby uninterruptible power supply (UPS).

FIG. 7 illustrates a conventional line-interactive uninterruptible power supply (UPS).

FIG. 8 shows a conventional inertial navigation system.

FIG. 9 shows the flowchart of the proposed improved discounted least square (IDLS) method.

FIGS. 10-13 and 15 are embodiments of order-∞ resonant tank according to present invention.

FIG. 14 illustrates a symbol denoting the “spectral resistive element” according to the present invention.

FIG. 16 illustrates an application of a snubber network according to the present invention.

FIG. 17 illustrates an infrastructure of a power system adopting a Dynamic Power Factor Corrector (DPFC) according to the present invention.

FIG. 18 illustrates an embodiment of a soft-switching power converting apparatus comprising a DPFC according to the present invention.

FIG. 19 illustrates a typical power system adopting a DPFC according to the present invention.

FIG. 20 illustrates some electric energy storage devices with their respective energy densities.

FIG. 21 illustrates a symbol denoting a DC-to-AC inverter adopting a DPFC according to the present invention.

FIG. 22 illustrates an example of a DC-to-AC inverter adopting a DPFC according to the present invention.

FIG. 23 illustrates an embodiment of a power converting apparatus with power recycling ability for supplying power to a driving motor according to the present invention.

FIG. 24 illustrates a symbol denoting a DC-to-AC inverter adopting a DPFC according to the present invention and further including the power recycling ability according to the present invention.

FIG. 25 illustrates another embodiment for supplying power to a driving motor with a soft-switching power converting apparatus adopting a DPFC according to the present invention.

FIG. 26 illustrates an embodiment of a DC-to-DC converter adopting a DPFC according to the present invention.

FIG. 27 illustrates an embodiment of a universal charging pump according to the present invention.

FIG. 28 illustrates an embodiment of a non-contact anti-skid braking system according to the present invention.

FIGS. 29, 39 and 40 illustrates embodiments of an electric vehicle or a hybrid-electric vehicle according to the present invention.

FIG. 30 illustrates a conductive line under high-frequency operating condition in the real world.

FIG. 31 illustrates a basic phase-locked loop (PLL) circuit.

FIG. 32 illustrates the low pass filter within the basic PLL circuit shown in FIG. 31.

FIG. 33 illustrates an embodiment of a low pass filter according to the present invention.

FIG. 34 shows an embodiment of an adaptive voltage controlled oscillator (VCO) according to the present invention.

FIG. 35 illustrates an electrostatic discharge (ESD) protector according to the present invention.

FIG. 36 illustrates a symbol representing a spectral capacitor according to the present invention.

FIG. 37 shows an embodiment of a nuclear power converting apparatus according to the present invention.

FIG. 38 illustrates the power sources and related concepts that may be integrated into electric vehicles or hybrid-electric vehicles according to the present invention.

FIG. 41 illustrates an ideal conductive line.

FIG. 42 shows an embodiment of an uninterruptible power supply according to the present invention.

FIG. 43 shows an embodiment of a redundant uninterruptible power supply system according to the present invention.

FIG. 44 illustrates a vacuum tube power amplifier.

FIG. 45 illustrates an embodiment of the pseudo vacuum tube power amplifier according to present invention.

FIG. 46 illustrates a basic circuit for an order-k resonant tank.

FIG. 47 illustrates a system having variable loads.

FIG. 48 shows an embodiment of an elevator that is a non-contact anti-crash transporting device according to the present invention.

FIG. 49 illustrates an embodiment of the inertial navigation system according to the present invention.

### DETAILED DESCRIPTION OF THE INVENTION

1 Elasticity of Electricity

First of all, the “Elasticity of Electricity” is derived based on Riemann-Lebesgue lemma for supporting the possibility of constructing an order-∞ resonant tank. As disclosed on page 313 of [4] and pages 171-174 of [20], it is assumed that power is a trigonometric Fouries series generated by a function g(t)εL(I), where g(t) should be bounded, and L(I) denotes Lebesgue-integrable on the interval I. Then, for each real β we have

$$\begin{matrix}{lim}_{ω -> ∞} {\int }_{I} g ( t ) sin ( ω t + β ) ⅆ t = 0 \\ or taking β = \frac{π}{2} + β , & ( 1 ) \\ {lim}_{ω -> ∞} {\int }_{i} g ( t ) cos ( ω t + β ) ⅆ t = 0 & ( 2 )\end{matrix}$$

where equation (1) or (2) is called “Riemann-Lebesgue lemma” and the parameter ω is a positive real number. In fact, this parameter ω is an angular frequency 2πf term. If g(t) is a bounded constant and ω>0, it is natural that the equation (1) can be further derived as

$$\vert {\int }_{a}^{b} sin ( ω t + β ) ⅆ t \vert = \vert \frac{cos ( a ω + β ) - cos ( b ω + β )}{ω} \vert \leq \frac{2}{ω}$$

where [a, b]εI is the boundary condition and the result also holds if on the open interval (a, b). For an arbitrary positive real number ε>0, there exists a unit step function s(t) (refer to page 264 of [4]) such that

$${\int }_{I} \vert g ( t ) - s ( t ) \vert ⅆ t < \frac{ɛ}{2}$$

Now there is a positive real number M such that if ω≧M,

$$\vert {\int }_{I} s ( t ) sin ( ω t + β ) ⅆ t \vert < \frac{ɛ}{2} \qquad ( 3 )$$

holds. Therefore, we have

$$\begin{matrix}\vert {\int }_{I} g ( t ) sin ( ω t + β ) ⅆ t \vert \leq \vert {\int }_{I} ( g ( t ) - s ( t ) ) sin ( ω t + β ) ⅆ t \vert + \\ \vert {\int }_{I} s ( t ) sin ( ω t + β ) ⅆ t \vert \\ \leq {\int }_{I} \vert g ( t ) - s ( t ) \vert ⅆ t + \frac{ɛ}{2} \\ < \frac{ɛ}{2} + \frac{ɛ}{2} = ɛ\end{matrix} \qquad ( 4 )$$

i.e., equation (1) or (2) is verified and held.

Assume that the voltage ν(t)=Vₘₐₓ cos(ωt+α) and current i(t)=Iₘₐₓ cos(ωt+β) are given, the average power is defined as

$$\begin{matrix}\begin{matrix}\overline{P} = {lim}_{T -> ∞} \frac{1}{T} {\int }_{0}^{T} i ( t ) v ( t ) ⅆ t \\ = {lim}_{T -> ∞} \frac{{V}_{max} {I}_{max}}{T} {\int }_{0}^{T} cos ( ω t + α ) cos ( ω t + β ) ⅆ t \\ = {lim}_{T -> ∞} \frac{{V}_{max} {I}_{max}}{2 T} {\int }_{0}^{T} cos ( 2 ω t + α + β ) + cos ( α - β ) ⅆ t \\ = \frac{{V}_{max} {I}_{max}}{2} cos ( α - β ) \\ = \frac{{V}_{max}}{\sqrt{2}} \frac{{I}_{max}}{\sqrt{2}} cos ( θ )\end{matrix} \\ or & ( 5 ) \\ \begin{matrix}\overline{P} = \frac{{V}_{max}}{\sqrt{2}} \frac{{I}_{max}}{\sqrt{2}} cos ( θ ) \\ = {V}_{rms} {I}_{rms} cos ( θ )\end{matrix} & ( 6 )\end{matrix}$$

where θ=(α−β) is a difference in angle between the voltage ν(t) and current i(t). The term cos θ is called the power factor. Moreover, the rms (roots of mean squared) values of voltage and current are

$$\begin{matrix}{V}_{rms} = \frac{{V}_{max}}{\sqrt{2}} \\ and & ( 7 ) \\ {I}_{rms} = \frac{{I}_{max}}{\sqrt{2}} & ( 8 )\end{matrix}$$

respectively. If the power factor is equal to one,
cos(θ)=1
i.e.,
θ=2nπ
for n=0, 1, 2, . . . For a DC power source,

$$\begin{matrix}{P}_{d c} = {V}_{max} {I}_{max} \\ = 2 \overline{P}\end{matrix} \qquad ( 9 )$$

in equation (9), the DC power Pd, is twice as big as the average power P. That is, if using the DC power sources, and the current and voltage are limited to equations (8) and (7) respectively, then we can obtain the effective power.

If we consider that the electrical power is distorted by the harmonic and subharmonic (non-integer) waveforms (refer to page 174 of [62], [25] and [18]) then the rms voltage and current are expressed as

$$\begin{matrix}{V}_{1 rms} = \sqrt{{\sum }_{h = 1}^{{h}_{n}} \frac{{V}_{h}^{2}}{2}} \\ = {\frac{1}{\sqrt{2}} [ {V}_{1}^{2} + … + {V}_{{h}_{n}}^{2} ]}^{0.5}\end{matrix}$$

$$and$$

$$\begin{matrix}{I}_{1 rms} = \sqrt{{\sum }_{h = 1}^{{h}_{n}} \frac{{I}_{h}^{2}}{2}} \\ = {\frac{1}{\sqrt{2}} [ {I}_{1}^{2} + … + {I}_{{h}_{n}}^{2} ]}^{0.5}\end{matrix}$$

, respectively, where the constant hₙ is the maximized order of harmonic wave number. From equation (6) we can obtain the average power P̅₁
P̅₁=V₁ᵣₘₛI₁ᵣₘₛ cos(θ₁) (10)
where P₁ is called “Active Power” and its unit is “Watt”.
Also, the term V₁ᵣₘₛI₁ᵣₘₛ is defined as
S=V₁ᵣₘₛI₁ᵣₘₛ (11)
and called “Apparent Power” and its unit is “VA”. On the other hand, we also define the reactive power Q as

$$\begin{matrix}Q = S sin ( {θ}_{1} ) \\ = {V}_{1 rms} {I}_{1 rms} sin ( {θ}_{1} )\end{matrix} \qquad ( 12 )$$

where the unit of reactive power is “VAR”. For the power efficiency consideration, spending more effort on reducing the reactive power Q is called “power factor corrector”, i.e., PFC. This is the most important issue for addressing the power saving and electrical power efficiency. There are many relevant commercial products in the world, for example, STMicroelectronics—“L6561” and International Rectifier—“IR1150.”

Now we construct the foundation for dynamic PFC (DPFC). The basic formulation comes from the power definition as equation (5). One can obtain, for each time period I, the average power expressed in equation (1) or (2) without taking the limit term. From equations (1), (2), (5), (12) and the uniform convergence property, the reactive power Q can be reduced by searching for the frequency from ω₀ to ω, where ω is an unlimited value. We can find a frequency ωᵣₘₛ and
ωᵣₘₛ>ω₆₀,ω₅₀
where ω₆₀ and ω₅₀ are the angular frequencies with respect to 60 H_{z} and 50 H_{z}, such that equation (2) is equal to equation (10) without the concern of the different angle β of the voltage and current. There exist the values of ω such that

$$\begin{matrix}\begin{matrix}{lim}_{ω \to {ω}_{rms}} {\int }_{I} g ( t ) cos ( ω t + β ) ⅆ t = {I}_{rms} {V}_{rms} \\ = \frac{{I}_{max} {V}_{max}}{2}\end{matrix} \\ or & ( 13 ) \\ \begin{matrix}{ω}_{rms} = {min}_{arg ( ω )} \vert {I}_{rms} {V}_{rms} - {\int }_{I} g ( t ) cos ( ω t + β ) ⅆ t \vert \\ = {min}_{arg ( {ω}_{h} )} \vert {I}_{rms} {V}_{rms} - {\sum }_{h = 1}^{{h}_{n}} {g}_{h} ( t ) cos ( {ω}_{h} t + {β}_{h} ) \vert \end{matrix} & \begin{matrix}( 14 ) \\ ( 15 )\end{matrix}\end{matrix}$$

where the amplitude gₕ(t) is the product of voltage νₕ(t) and iₕ(t) as
gₕ(t)=iₕ(t)νₕ(t)
Based on equation (13), for performing a constant pulse width modulation (PWM), the DC power source can be modulated by frequency ωᵣₘₛ or switching-mode power. For further implementation of the dynamic power factor corrector, equation (13) provides a scenario of the frequency modulation. For arbitrary operating time interval I, ωᵣₘₛ is determined by the power consumption and varied with system loads. Equation (13) or (14) becomes a general criterion of varied frequency modulation, instead of a constant frequency modulation. From equation (15), its corresponding phase angle is detected as
Δφ=βᵣₘₛ−β₀ (16)
where β₀ is the phase angle of the reference signal. The above equation (16) induces the general principle for designing a phase-locked loop circuit.

According to the Riemann-Lebesgue lemma as equations (2) and (1), as the frequency ωᵣₘₛ approaches infinity,

$${\dot{ω}}_{rms} 〉 〉 {ω}_{60} , {ω}_{50} \\ then \\ {lim}_{{ω}_{rms} \to ∞} {\int }_{I} g ( t ) cos ( ω t + β ) ⅆ t = 0 \qquad ( 17 )$$

Equation (17) is a foundation for the broadband band-pass filter. For removing any destructive power component, equation (17) tells us the truth about whatever the frequencies are produced by the harmonic (subharmonic) waveforms, they will be completely “damped” out by the ultra-high frequency modulation. This is a broadband damper with varied damping ratio. If driving the equation (17) at some specific frequencies, phases or bandwidths, the signals are detected and locked or filtered out. This is a simple but effective principle for high-quality (HQ) antenna designs.

From equation (4), the selection of the positive constant ε gives rise to many advantages for the general-purpose power system development. For instance, if we take the constant ε as the form

$$ɛ = {min}_{arg ( {h}_{n} )} [ \frac{{V}_{rms}}{{V}_{sys}^{{h}_{n}}} ]$$

where V_{sys}^{h}^{ₙ} is contributed by any inductive component with respect to the hₙ^{th} harmonic or subharmonic power waveform or system limitation, the selection of M is equal to ωᵣₘₛ^{h}^{ₙ}:

$$\begin{matrix}\begin{matrix}M = {ω}_{rms}^{{h}_{n}} \\ = {max}_{arg ( {h}_{n} )} [ \frac{{V}_{rms} ( {ω}_{rms} )}{{V}_{sys}^{{h}_{n}} ( ω )} ]\end{matrix} \\ or & ( 18 ) \\ \begin{matrix}M = {ω}_{rms}^{{h}_{n}} \\ = {max}_{arg ( {h}_{n} )} [ \frac{{I}_{rms} ( {ω}_{rms} )}{{I}_{sys}^{{h}_{n}} ( ω )} ]\end{matrix} & ( 19 )\end{matrix}$$

where V_{sys}^{h}^{ₙ}(ω), I_{sys}^{h}^{ₙ}(ω) are the system voltage and current limitations, respectively. Now applying equation (18) or (19) to equation (13), we can obtain:

$${lim}_{ω \to {ω}_{rms}^{{h}_{n}}} {\int }_{I} g ( t ) cos ( ω t + β ) ⅆ t = {I}_{rms}^{{h}_{n}} {V}_{rms}^{{h}_{n}} + ζ \\ or \\ {ζ}_{{ω}_{rms}^{{h}_{n}}} = {min}_{arg ( {ω}_{h} )} \vert {I}_{rms}^{{h}_{n}} {V}_{rms}^{{h}_{n}} - {\sum }_{h = 1}^{{h}_{n}} {g}_{h} ( t ) cos ( {ω}_{h} t + {β}_{h} ) \vert \qquad ( 20 )$$

where ζωᵣₘₛ^{h}^{ₙ} is the attenuated and the non-zero part of power contributed from applying to ωᵣₘₛ^{h}^{ₙ} modulation
ω<ωᵣₘₛ^{h}^{ₙ}.

The left term of equation (20) is less destructive than that of equation (13). The crisis of unpredictable high power (contributed by Lenz's voltage, inrush current or harmonic (subharmonic) distorted power waveforms, etc.) disappears completely. Consequently, equation (20) becomes the key vector of a power attenuation mechanism such that the attenuated power can be recycled.

After above creative descriptions, there exists a driver to maneuver the frequencies within a broadband domain
0≦ω<∞,
search for the best response frequencies ωᵣₘₛ and finally lock them on to produce the best performance of power. The subject of how to achieve the electrical power efficiency has transformed to that of how to drive the frequency fast moving on any bandwidth, detect the best response frequencies and finally lock them on at once.

Observing equation (17), the function g(t) is amplitude of power that is amplitude-frequency dependent, see Chapter 3 of [18]. It means that the higher frequency is excited, the more g(t) is attenuated, i.e., when moving along with higher frequency, the power of equation (17) is diminished more rapidly. In conclusion, a large part of the power has been dissipated to the excited frequency ω fast drifting across the band of each reasonable resonant point, rather than transformed into the thermal energy (heat). After all, applying electrical power to a system periodically causes the ω to be drifted continuously from low to very high frequencies for power absorbing and dissipating. After removing the power, the frequency rapidly returns to nominal state. It is a fast recovery feature. Also, the power input results in the resistance change depending on the drifting rate of excited frequency.

As previously described, it is realized that the behavior of the frequency becomes high as the amplitude of electricity is increased, and vice versa, expressed in the form of
ω=ω(g(t)) (21)
which is similar to the general Hook's law (see [64] and [40]),
σ=H(ε)
where σ, ε are the stress, strain tensors respectively for an elastic body. The amplitude-frequency relationship as shown in equation (21) is the so-called “elasticity of electricity” which induces the adaptivity of system. It tells which value of power produces the corresponding frequency excitation as a nonlinear spring and damper combination. This is a key feature of elasticity of electricity. For identifying an input unknown power level system, the excited frequency detection helps us to identify the amplitude of power, and thus the bandwidth is also determined. Therefore, the power is easily detected and extracted without any complicated computation.

Based on the theory of elasticity, dielectric materials with good frequency response and dipole properties can be used for carrying out the elasticity of electricity. Therefore, to look for suitable dielectric materials is a straightforward progress. Many dielectric materials such as GaAs, BaTiO₃ (refer to Vol 2, Chapter 11 of [74] and metal Oxide and Gunn diode (refer to Page 328 of [75]) have been investigated.

2 Spectral Resistor and Order-∞ Resonant Tank

After the “Elasticity of Electricity” is derived from the Riemann-Lebesgue lemma. A spectral resistor (the resistance of which varies with the frequency) is proposed to build an order-∞ resonant tank by using skills in the electric circuit analysis as disclosed in chapter 10 of [27], Vol 1, 2 (Chapter 11) of [74], [18] and [75].

2.1 Motivation

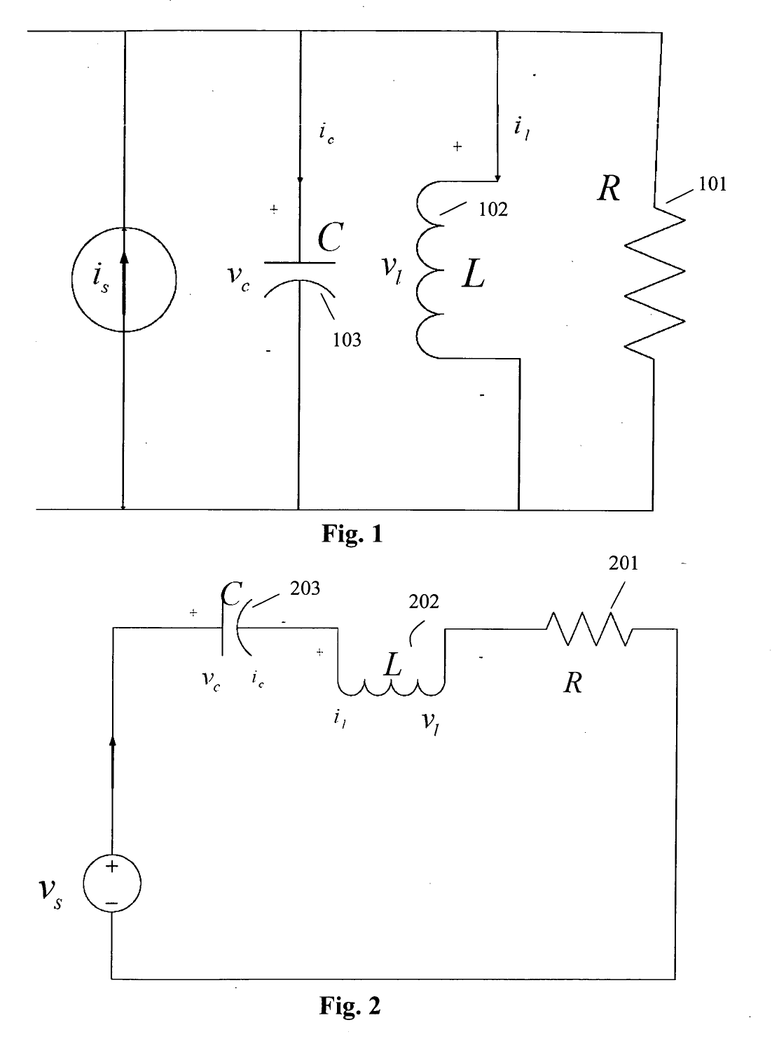

The state equation of the parallel-RLC oscillator as shown in FIG. 1 is

$$\frac{{ⅆ}^{2} i}{ⅆ {t}^{2}} + \frac{1}{RC} \frac{ⅆ i}{ⅆ t} + \frac{1}{LC} i = \frac{1}{LC} {i}_{s} \qquad ( 22 )$$

and the corresponding eigenvalues λ_{1,2} in terms of the resistance of resistor 101 (i.e., R), the inductance of inductor 102 (i.e., L) and the capacitance of capacitor 103 (i.e., C) are

$$\begin{matrix}{λ}_{1 , 2} = \frac{1}{2} ( - \frac{1}{RC} \pm \sqrt{{( \frac{1}{RC} )}^{2} - \frac{4}{{RLC}^{2}}} ) \\ = \frac{1}{2 RLC} ( L \pm \sqrt{{L}^{2} - 4 {CLR}^{2}} )\end{matrix}$$

where
RLC≠0,
i.e., any one of the magnitudes of R, L, and C can not be zero. The oscillating condition is

$${L}^{2} - 4 {CLR}^{2} < 0 , \\ i . e . , \\ {f}_{r} < \frac{R}{π L} \qquad ( 23 )$$

where

$${f}_{r} = \frac{1}{2 π \sqrt{LC}}$$

is called the resonance frequency. Let the resistance R be regulated by the system temperature T, i.e., the resistance R is denoted as R(T),

$$\frac{R ( T )}{π L} > {f}_{r} \qquad ( 24 )$$

such that the system is parameterized by the temperature T. In other words,
πLfᵣ<R(T) (25)
or
πLfᵣ<R(fᵣ) (26)
The quality factor Q is defined as

$$Q ≡ \frac{{ω}_{r} R}{L} \qquad ( 27 )$$

where ωᵣ=2πfᵣ. Assume that the input voltage is
ν(t)=ε₀ cos(ωt+β),
and the complex form of the current i(t) is

$$i ( t ) = [ \frac{1}{R} + ⅈ ( ω C - \frac{1}{ω L} ) ] {ɛ}_{0} cos ( ω t + β ) , \\ where \\ β = {tan}^{- 1} [ R ( ω C - \frac{1}{ω L} ) ] . \qquad ( 28 )$$

Observing the equation (28), let the resistance R be moved toward zero
R [symbol] 0 (29)
then the initial phase angle β becomes zero without being affected by ω.

Again, we consider a system for designing a series-RLC oscillator as shown in FIG. 2. According to Kirchhoff's law,

$$\frac{{ⅆ}^{2} v}{ⅆ {t}^{2}} + \frac{R}{L} \frac{ⅆ v}{ⅆ t} + \frac{1}{LC} v = \frac{1}{LC} {v}_{s} . \qquad ( 30 )$$

The corresponding characteristic values of equation (30) are λ_{1,2} as

$$\begin{matrix}{λ}_{1 , 2} = \frac{- \frac{R}{L} \pm \sqrt{{( \frac{R}{L} )}^{2} - \frac{4}{LC}}}{2} \\ = \frac{1}{2 LC} [ - RC \pm \sqrt{{R}^{2} {C}^{2} - 4 LC} ]\end{matrix}$$

where L (i.e., the inductance of inductor 202) and C (i.e., the capacitance of capacitor 203) can not be zero. If R (i.e., the resistance of resistor 201) equals to zero, the characteristic values become

$${λ}_{1 , 2} = \pm \frac{1}{\sqrt{LC}} i$$

This system is still oscillated by its corresponding natural frequency

$${ω}_{0} = \frac{1}{\sqrt{LC}} .$$

Physically, it is called “shortcut effect”. This provides obvious evidence, leading the high power to an electrical absorber, for a power absorber design.

In a sequel, the corresponding oscillating condition is

$${( π RC )}^{2} < 4 {π}^{2} LC$$

$$or$$

$${ω}_{r} < \frac{1}{π RC}$$

i.e., the temperature factor T is attached into the resistor as

$${ω}_{r} < \frac{1}{π CR ( T )} \\ or \\ R ( {ω}_{r} ) < ( \frac{1}{π C {ω}_{r}} ) \qquad ( 31 )$$

In equations (24) and (31), the balance between temperature and resonance frequency is performed dynamically. And the corresponding Q value is

$$Q = \frac{{ω}_{r} L}{R ( {ω}_{r} )} \qquad ( 32 )$$

where ωᵣ=2πfᵣ. Assume that the input voltage is
νₛ(t)=ε₀ cos(ωt)
the current becomes

$$i ( t ) = \frac{{ɛ}_{0}}{\sqrt{{R}^{2} + {( ω L - \frac{1}{ω C} )}^{2}}} cos ( ω t + β ) \\ where \\ β = {tan}^{- 1} ( \frac{ω L - \frac{1}{ω C}}{R} ) \qquad ( 33 )$$

Moreover, observing equation (33), let the resistance be moved towards infinity
R→∞ (34)
then initial phase angle β becomes zero without being affected by ω.

Equations (29) and (34) remind us that the resistance should vary with excited frequency. In equation (26) or (31), R(fᵣ) or R(ωᵣ) can be a basic prototype concept of the “Spectral Resistor”.

Equation (27) and equation (32) tell us that an order-∞ resonant tank can be constructed by linking different types of oscillators together. Such an order-∞ resonant tank is suitable for designing a constant high Q system with varying frequency (such as a broadband band-pass filter and an antenna).

The total impedance Z(f) becomes a function of the excited frequency f as shown in equation (35)
Z(f)=\sqrt{σ²(f)+μ²(f)} (35)
The complex form of impedance (as shown below in equation (36)) and its total derivative with respect to frequency, temperature and time are

$$\begin{matrix}\begin{matrix}z ( f ) = σ ( f ) + ⅈ μ ( f ) \\ = R ( f ) + ⅈ [ {X}_{L} + {X}_{C} ]\end{matrix} & ( 36 ) \\ dz = \frac{ⅆ σ}{ⅆ f} df + ⅈ \frac{ⅆ μ}{ⅆ f} df & ( 37 ) \\ dz = \frac{ⅆ σ}{ⅆ f} \frac{ⅆ f}{ⅆ T} dT + ⅈ \frac{ⅆ μ}{ⅆ f} \frac{ⅆ f}{ⅆ T} dT \\ and & ( 38 ) \\ dz = \frac{ⅆ σ}{ⅆ f} \frac{ⅆ f}{ⅆ T} \frac{ⅆ T}{ⅆ t} dt + ⅈ \frac{ⅆ μ}{ⅆ f} \frac{ⅆ f}{ⅆ T} \frac{ⅆ T}{ⅆ t} dt \\ or & ( 39 ) \\ \begin{matrix}dz = \frac{ⅆ σ}{ⅆ f} \frac{ⅆ f}{ⅆ T} \frac{ⅆ T}{ⅆ t} dt + ⅈ \frac{ⅆ μ}{ⅆ f} \frac{ⅆ f}{ⅆ T} \frac{ⅆ T}{ⅆ t} dt \\ = \frac{ⅆ σ}{ⅆ f} \frac{ⅆ f}{ⅆ T} \frac{ⅆ T}{ⅆ t} dt + ⅈ [ {dX}_{L} + {dX}_{C} ]\end{matrix} & \begin{matrix}( 40 ) \\ ( 41 )\end{matrix}\end{matrix}$$

respectively. From equation (40), the term

$$\frac{ⅆ σ}{ⅆ f}$$

is the resistance change with respect to frequency variation df and is the primary dominant character for the attenuator design. Also,

$$\frac{ⅆ σ}{ⅆ f}$$

being zero becomes a common usage resistor. In fact, there exist two types of resistance effects—positive or negative (if

$$\frac{ⅆ σ}{ⅆ f}$$

is a positive value, it is a positive resistance effect, and vice versa). The term

$$\frac{ⅆ f}{ⅆ T}$$

is the frequency change rate with respect to temperature. The terms

$$\frac{ⅆ T}{ⅆ t}$$

and dt are the diffusion rate and the operating period, respectively. This system needs a perfect cooling system to remove the

$$\frac{ⅆ T}{ⅆ t}$$

effectively.

When a system continuously working, the temperature becomes abruptly high, and finally the system stops working. This bursts into a terribly instable saturation situation. Concerning the stability, using one type resistor which is

$$\frac{ⅆ ω}{ⅆ f} > 0 or \frac{ⅆ σ}{ⅆ f} < 0$$

only is not enough to handle the full functions. If μ=0, resonance frequency ωᵣ is obtained.

For a simply series-RLC oscillator case as shown in FIG. 2, the terms

$$d {X}_{L} = 2 π L d f$$

$$and$$

$$d {X}_{C} = ( \frac{1}{2 π {f}^{2} C} ) d f$$

are the inductance and capacitance change with respect to frequency variation df.
2.2 Spectral Resistors and Order-∞ Resonant Tank

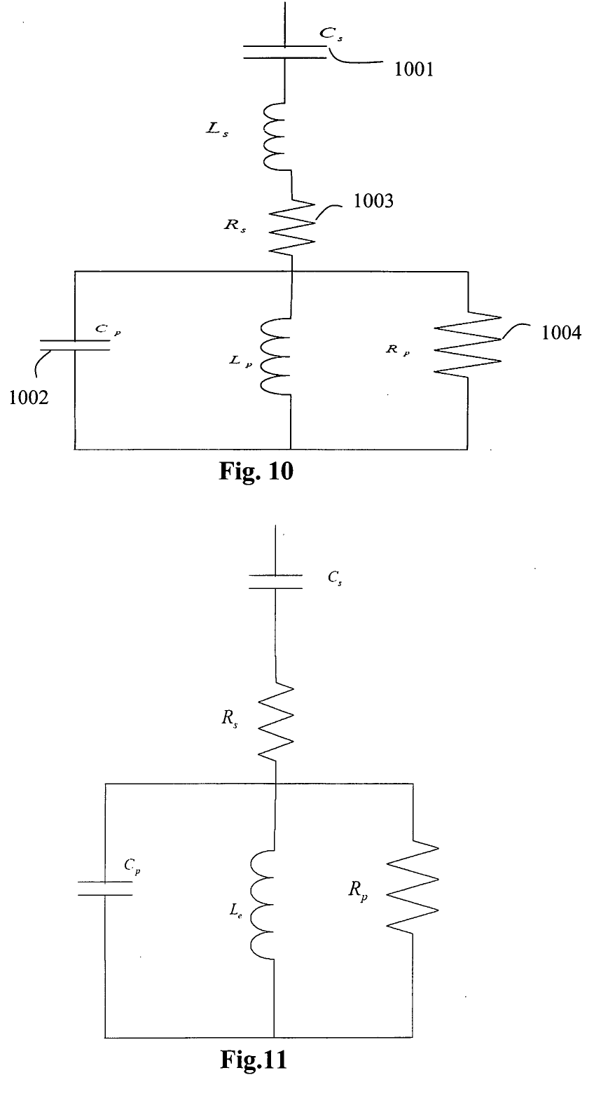

The previous discussions on the simple oscillators and that the resistance is dependent on the frequency or temperature change provides opportunity to establish an order-∞ resonant tank as following. If the oscillators as shown in FIG. 1 and FIG. 2 are combined into one series-parallel resonant tank as shown in FIG. 10, the total impedance z is as follows:

$$\begin{matrix}z = {z}_{s} + {z}_{p} & ( 42 ) \\ = {R}_{sp} + ⅈ {Q}_{sp} & ( 43 )\end{matrix}$$

where the real and image parts of z are

$${R}_{sp} = [ \frac{{R}_{p}}{1 + {{R}_{p}^{2} ( ω {C}_{p} - \frac{1}{ω {L}_{p}} )}^{2}} + {R}_{s} ] and$$

$${Q}_{sp} = [ ( ω {L}_{s} - \frac{1}{ω {C}_{s}} ) - \frac{{R}_{p}^{2} ( ω {C}_{p} - \frac{1}{ω {L}_{p}} )}{1 + {{R}_{p}^{2} ( ω {C}_{p} - \frac{1}{ω {L}_{p}} )}^{2}} ]$$

, respectively. The impedance zₚ of parallel-RLC circuit is

$$\begin{matrix}{z}_{p} = \frac{1}{\frac{1}{{R}_{p}} + ⅈ ( ω {C}_{p} - \frac{1}{ω {L}_{p}} )} \\ = \frac{{R}_{p} - ⅈ {R}_{p}^{2} ( ω {C}_{p} - \frac{1}{ω {L}_{p}} )}{1 + {{R}_{p}^{2} ( ω {C}_{p} - \frac{1}{ω {L}_{p}} )}^{2}}\end{matrix}$$

and the impedance zₛ of RLC series is

$${z}_{s} = {R}_{s} + ⅈ ( ω {L}_{s} - \frac{1}{ω {C}_{s}} ) .$$

As the resonance occurs, the complex part of equation (43) is zero

$${Q}_{sp} = 0 \\ i . e . , \\ ( ω {L}_{s} - \frac{1}{ω {C}_{s}} ) = \frac{{R}_{p}^{2} ( ω {C}_{p} - \frac{1}{ω {L}_{p}} )}{1 + {{R}_{p}^{2} ( ω {C}_{p} - \frac{1}{ω {L}_{p}} )}^{2}} \qquad ( 44 )$$

Furthermore, the value of Rₚ² is expressed as follows

$$\begin{matrix}{R}_{p}^{2} = \frac{( ω {L}_{s} - \frac{1}{ω {C}_{s}} )}{( ω {C}_{p} - \frac{1}{ω {L}_{p}} ) - {( ω {C}_{p} - \frac{1}{ω {L}_{p}} )}^{2} ( ω {L}_{s} - \frac{1}{ω {C}_{s}} )} \\ = \frac{( {ω}^{2} {L}_{s} {C}_{s} - 1 ) {ω}^{2} {L}_{p}^{2}}{( 1 - {ω}^{2} {p}_{2} + {ω}^{4} {p}_{4} - {ω}^{6} {p}_{6} )}\end{matrix} \qquad ( 45 )$$

where the coefficients are
p₂=(CₛLₚ+CₛLₛ+2CₚLₚ)
p₄=2CₚLₚ(LₛCₛ+CₛLₚ+CₚLₚ) and
p₆=Cₚ²CₛLₚ²Lₛ
, where the Cₛ and Cₚ should be the dielectric capacitors designing the by-pass, coupling and resonant functions. In equation (45), the squared resistance

$${R}_{p}^{2}$$

at the resonant tank of a series-parallel oscillator is a function of the excited frequency ω and is rarely decoupled. Also Rₚ may be a negative resistance effect, the value of Rₛ should accordingly be a positive value for balancing between Rₛ and Rₚ in equation (43) and short-circuit protection. The rate of resistance change

$$\frac{ⅆ {R}_{s}}{ⅆ ω}$$

is concretely higher than

$$\frac{ⅆ {R}_{p}}{ⅆ ω} .$$

Nevertheless, the real part of equation (43) has never been zero but is oscillated and adaptively convergent to the stable equilibria such that it transits into a harmonic balance. According to equation (41), Rₛ can be chosen to be positive,

$$\frac{ⅆ {R}_{s}}{ⅆ ω} > 0 , i . e . , {R}_{s}$$

monotonically increases with increasing frequency (for example, this type of resistor is at least partly made of a kind of dielectric material with resistance monotonically increases with increasing frequency, such as GaAs or BaTiO₃) (see Vol 2 (Chapter 11) of [74,]); while Rₚ is accordingly chosen to be negative,

$$\frac{ⅆ {R}_{p}}{ⅆ ω} < 0 , i . e . , {R}_{p}$$

monotonically decreases with increasing frequency (for example, this type of resistor is at least partly made of a kind of dielectric material with resistance monotonically decreases with increasing frequency, such as metal oxide). A Gunn diode (page 328 of [75]) can be used as the resistor with its resistance monotonically decreases with increasing frequency.

Note that the initial values of Rₚ and Rₛ are
Rₚ,RₛεO (1).
According to the Hopf's bifurcation analysis in the Appendix G, a Hopf's bifurcation parameter ω is artificially created by electrically connecting two different types of resistors in series, such that the bifurcation conditions are repetitively crossed, and thus that makes the resonant tank become alive and oscillating. The electrically connecting of two different types of resisters in series, wherein one resistor is of positive resistance as defined above and the other is of negative resistance as defined above, can be regarded as one spectral resistive element. Similarly, the electrically connecting of two different types of resistors in parallel can be regarded as another type of spectral resistive element.

For each excited frequency ω in the series-parallel resonant tank shown in FIG. 10, there exist one or many resonant frequencies ωᵣ such that equation (44) holds. Equation (42) and the following equations (46) and (47) are functions of frequency, denoted as
Rₚ=Rₚ(ω) (46)
and
Rₛ=Rₛ(ω) (47)
Consequently, the total impedance as shown in equation (42) becomes a pure resistance (i.e., the imaginary part of the total impedance equals to zero) as

$$z ( {ω}_{r} ) = [ \frac{{R}_{p} ( {ω}_{r} )}{1 + {R}_{p}^{2} ( {ω}_{r} ) {( {ω}_{r} {C}_{p} - \frac{1}{{ω}_{r} {L}_{p}} )}^{2}} + {R}_{s} ( {ω}_{r} ) ] .$$

From equation (43), the resistances Rₚ and Rₛ are not constants; on the contrary, they are active and alive. The resistances Rₚ and Rₛ relatively depend on the properties of the dielectric materials (such as the dipole and dielectric properties) and the working circumstance (especially the temperature). As current passing through, the total impedance as shown in equation (42) will be transferred into a harmonic balance, i.e., resonance, bounded amplitude and periodic oscillating, and convergent to the limit cycles everywhere (see [18], [5] and [24]). In addition, a resonant tank comprising two resistors, of which the resistances are that shown in equations (46) and (47), connected in series has the fast recovery feature.

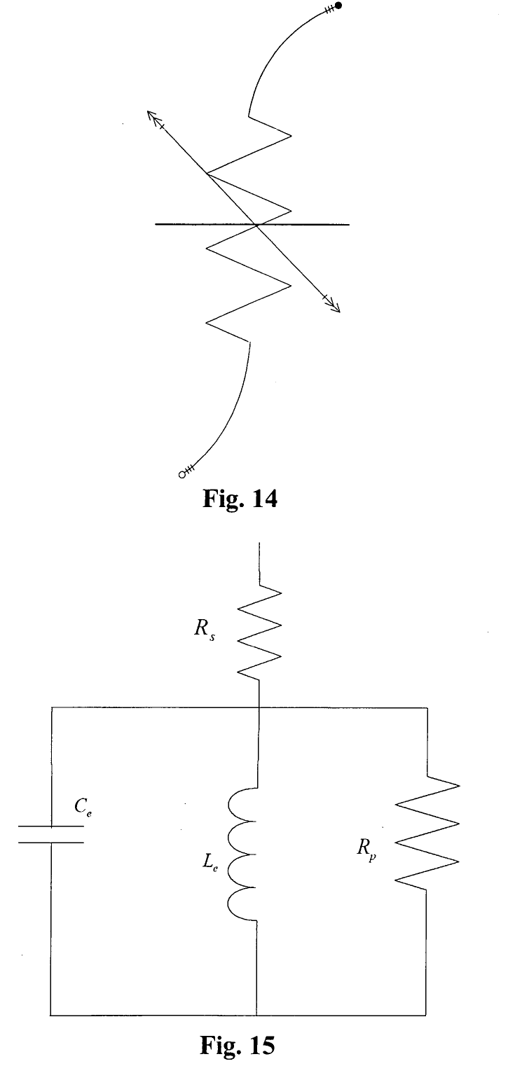

Therefore, a resistor having resistance varying with frequency (such as that shown in equations (46) and (47)) is proposed in the present invention, and named as “spectral resistor” hereafter. The proposed “spectral resistor” will be denoted as the symbol shown in FIG. 14; wherein the shape similar to the letter “f” denotes that the resistor varies with the frequency; the tilted line indicates that the resistance is continuously varying with the frequency; the token of double arrows shown on two directions of the tilted line means that the resistance has fast recovery feature and indicates that the resistance is of high sensitivity to frequency variation; the small-dashed line at the tilted line indicates rapid convergence to the harmonic balance; the black and white points at two ends of the letter “f” represent a sink and a source, respectively; the horizontal line at the center is the sign of a self-attenuation mechanism; and the three small-dashed lines indicate that the spectral resistor suppresses the duality of system. The proposed spectral resistor is suitable for constructing an order-∞ resonant tank.

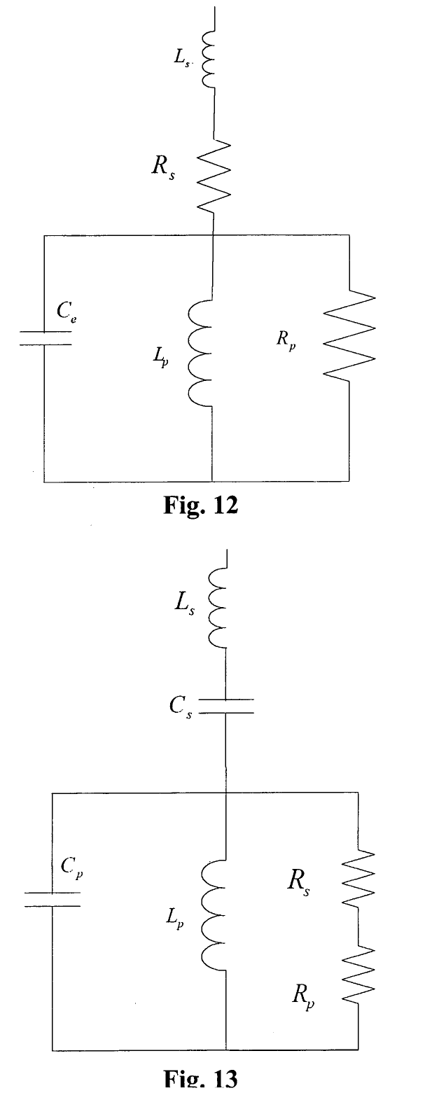

FIGS. 10-13 and 15 are different embodiments of the order-∞ resonant tank constructed with the proposed spectral resistive element, wherein FIG. 15 illustrates a basic embodiment of an order-∞ resonant tank according to the present invention. As shown in FIGS. 10-13 and 15, an order-∞ resonant tank may comprise: a spectral resistive element, wherein the resistance of a first part (Rₛ) of said spectral resistive element monotonically increases with increasing frequency, while the resistance of a second part (Rₚ) of said spectral resistive element monotonically decreases with increasing frequency; a substantial capacitive element (Cₑ); and a substantial inductive element (Lₑ). Since any conductive line will have inductance under some conditions and any two conductive parts will have capacitance between them, according to the present invention, the substantial inductive element can be a conductive line, a system with equivalent inductance, or an inductor; and the substantial capacitive element can be any two conductive parts, a system with equivalent capacitance, or a capacitor.

3 Electric Filter

The proposed order-∞ resonant tank can function as an order-∞ electric filter by electrically connecting an order-∞ resonant tank according to the present invention in parallel to a substantial inductive element to perform filtering operation. This kind of electric filter can be functioned as a substantial all-pass filter.

Moreover, because the proposed electric filter provides the ability to quickly absorb and dissipate the reactive power (coming from the reactive effects (i.e., inertial effects): Lenz's voltage

$$( i . e . , \frac{ⅆ v}{ⅆ t} )$$

or inrush current

$$( i . e . , \frac{ⅆ i}{ⅆ t} )$$

of a resonant circuit as the status (on/off) of a switching element is changed), this kind of electric filter can function as a DeLenzor (or called a generic snubber network or a snubber circuit). If the order-∞ resonant tank as shown in FIG. 10 is selected to implement a DeLenzor, the capacitors Cₛ 1001 and Cₚ 1002 may be sintered type or metallized type according to the operation needs. For example, for using in a switching-mode power supply, the capacitors Cₛ 1001 and Cₚ 1002 could be made of dielectric materials with high working-tolerant voltage (the typical value is about 2 kV).

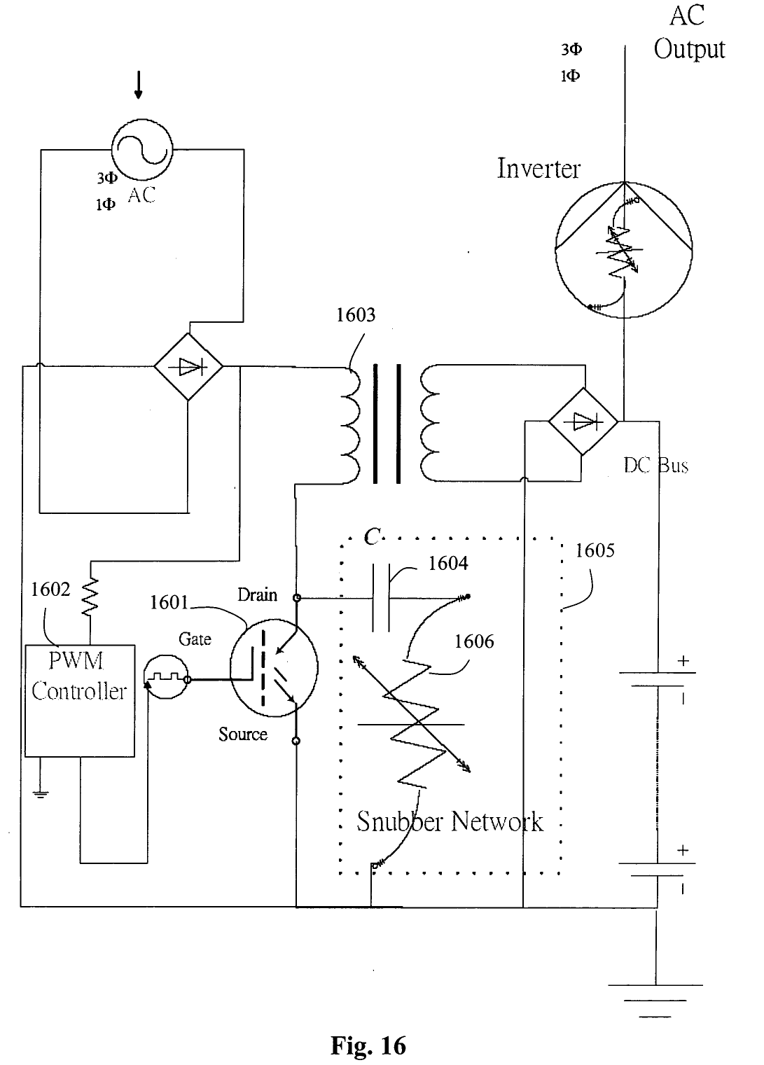

As shown in FIG. 16, a proposed generic snubber network 1605 is connected in parallel to a power transistor 1601 to absorb the back electromotive force (i.e., Lenz's voltage) or regenerated power (i.e., reactive power). After the PWM controller 1602 is turned on/off, an AC current would be induced by the inductive element 1603. DC current will be isolated by the capacitor 1604, and thus only the AC current passes through the spectral resistor 1606. The AC current would be damped out very quickly through the order-∞ resonant tank (formed by the snubber network 1605 and the inductive element 1603). Here, the spectral resistor 1606 within the snubber network 1605 is a kind of dissipative resistor, and can be called as spectral dissipative resistor.

Similarly, the proposed electric filter can be used to implement a sparkless electric switch circuit. When the switching element of the sparkless electric switch circuit (comprising an order-∞ resonant tank electrically connected in parallel to the switching element) is turned on/off, the order-∞ resonant tank will absorb the inrush current due to the sudden connection to a AC power source. With this sparkless electric switch circuit, fire disaster can be avoided.

4 Dynamic Damper

According to equations (30) and (22), the damping terms of a parallel-RLC oscillator and a series-RLC oscillator are

$$\frac{R}{L} and \frac{1}{RC} ,$$

respectively. And the common term in

$$\frac{1}{RC} and \frac{R}{L}$$

is the resistance R. The eigenvalues λ_{1,2} can be further derived as

$$\begin{matrix}\begin{matrix}{γ}_{1 , 2} = \frac{1}{2 LC} [ - RC \pm \sqrt{{R}^{2} {C}^{2} - 4 LC} ] \\ = [ - \frac{R}{2} \sqrt{\frac{C}{L}} \pm \sqrt{{( \frac{R}{2} \sqrt{\frac{C}{L}} )}^{2} - 1} ] {ω}_{0} \\ = ( - ζ \pm \sqrt{{ζ}^{2} - 1} ) {ω}_{0}\end{matrix} \\ where & ( 48 ) \\ \begin{matrix}ζ = \frac{R}{2} \sqrt{\frac{C}{L}} \\ = \frac{CR ( ω )}{2} {ω}_{0}\end{matrix} & \begin{matrix}( 49 ) \\ ( 50 )\end{matrix}\end{matrix}$$

is the damping ratio. Equation (48) illustrates a way to design a damper with variable damping ratio ζ, i.e., a dynamic damper, if the resistance R in equation (50) is replaced with that of a spectral resistor, Rₚ(ω) or Rₛ(ω).

Therefore, a dynamic damper that comprises an order-∞ resonant tank according to the present invention is provided. By electrically connecting the order-∞ resonant tank of the provided dynamic damper to a substantial inductive circuit in parallel, the heating problem of the substantial inductive circuit will be substantially completely solved. Furthermore, a universal dissipative unit (such as a universal frequency modulation dissipative unit) can be implemented by adapting the provided dynamic damper.

5 Harmonic and Sub-Harmonic Power Waveform Distortion Filter

As discussed, when both the resistors Rₚ 1004 and Rₛ 1003 within the series-parallel RLC oscillator shown in FIG. 10 are spectral resistors having resistances as shown in equations (46) and (47), the series-parallel RLC oscillator becomes an order-∞ resonant tank in which the stimulating frequency is condensed over all operating domain (0≦ω<∞), i.e., all of the resonant points can be effectively and immediately detected. In equation (1), frequency can shift from zero to infinity including all real numbers, i.e. elasticity of electricity. However, there is a bandwidth limitation due to the properties of materials, for instance, GaAs is limited within the bandwidth of 2.5 Ghz. Fortunately, this bandwidth is wide enough to cope with a lot of realistic conditions.

According to the elasticity of electricity derived from the Riemann-Lebesgue lemma, a harmonic and sub-harmonic power waveform distortion filter to attenuate the random-order (sub)harmonic power waveforms contributed from nonlinear loads is presented. To neutralize the factors of unbalancing sources takes the top priority of obtaining high quality. Since the operating bandwidth of an order-∞ resonant tank is a full range with fast recovery feature, i.e., elasticity of electricity, (which means that the current oscillating between the sink and source is everywhere and is quickly convergent to some resonant points, keeping in under-damping condition, the power is damped out, and returning to the equivalent state as soon as possible), for each resonant point the order-∞ resonant tank is functioned as a dynamic damper as shown in equations (46), (47), and (50). Thus it is possible to meet any order of the generated (sub)harmonic power waveforms and damp them out entirely. Observing equations (104) and (105) in Appendix F, the material defect ε, the nonlinear damper-spring h(dx/dt, x) and the near integer Ω are related to the (sub)harmonic sources. Given the (sub)harmonic sources in nonlinear term,

$$h ( \frac{ⅆ x}{ⅆ t} , x )$$

the material parameter
ε (51)
and equation (99), order-∞ resonant tank is added to remove the total effects of equations (104), (99) and (51). Theoretically, we can construct a conjugated system for this parameter ε in equations (2) and (99) as

$$\frac{{ⅆ}^{2} x}{ⅆ {t}^{2}} + ( {N}^{2} + ɛβ ) x = F ( ω t ) - ɛ h ( \frac{ⅆ x}{ⅆ t} , x ) \qquad ( 52 )$$

but the material parameter as shown in (51) is a negative value

$$\frac{{ⅆ}^{2} x}{ⅆ {t}^{2}} + ( {N}^{2} - ɛβ ) x = F ( ω t ) + ɛ h ( \frac{ⅆ x}{ⅆ t} , x ) \qquad ( 53 )$$

Thus, taking the sum of equations (52) and (53), the system

$$\frac{{ⅆ}^{2} x}{ⅆ {t}^{2}} + {N}^{2} x = F ( ω t ) \qquad ( 54 )$$

obviously has no any (sub)harmonic source, where |N−ω|≧≧0. If changing the dielectric material shown in equation (51) for the fiber-optical needs, any (sub)harmonic source existence on the fiber-optical systems is reasonably vanished.

Once all of (sub)harmonic powers have been guided into an order-∞ resonant tank, performing the power attenuation and damping is a straightforward direction. For realistic improvement, the THD (Total Harmonic Distortion) is below 0.5%. Therefore, purified electrical power source is obtained by using the proposed Harmonic and sub-harmonic power waveform distortion filter, having an order-∞ resonant tank according to the present invention connected in parallel to a substantial inductive circuit, to remove the unbalance sources.

6 Dynamic Impedance Matching Circuit and Dynamic Power Factor Corrector Circuit

In the electric field, nonlinear loads, dynamic loads or unbalanced sources are the common working environments, for example, electric vehicles, CD-ROMs and high-power devices. However, to perform dynamic impedance matching to nonlinear loads is very difficult. Take the system shown in FIG. 47 for example, if only Load₁ 4701, Load₂ 4702 and Load₃ 4703 exist in the system originally, and then a new load(s) 4704 is added into the system, the total impedance of the system would suddenly change, and disadvantageous effects such as electric arc and power waveform distortions would possibly occur.

The present invention provides a dynamic impedance matching circuit comprising a substantial order-∞ resonant tank, wherein the provided dynamic impedance matching circuit is connected in parallel to a nonlinear load (such as a large inductor, a motor or a transformer) for performing impedance matching dynamically.

As discussed in the elasticity of electricity section, the power consumption of a system would be minimized when the power factor of the system is always kept as one, i.e., the reactive power shown in equation (12) is removed, and the operation for keeping the power factor as one is called “power factor correction.” Moreover, according to equation (13), the power factor of a system having nonlinear loads would be corrected as one when the supplying power to the system is modulated by frequency ωᵣₘₛ, which depends on the nonlinear loads of the system; the above operation is called “dynamic power factor correction.” However, it is very difficult to adjust the frequency ωᵣₘₛ according to the nonlinear loads dynamically. Therefore, the current power system only keeps the frequency ωᵣₘₛ at a fixed frequency (e.g., 50 Hz or 60 Hz) using the conventional switching-mode power converting apparatuses (such as AC-to-DC rectifiers/adapters, DC-to-DC converters, DC-to-AC inverters, and AC-to-AC converters). In addition, the conventional switching-mode power converting apparatuses cause many side effects due to the nonlinearity coming from the switching on/off actions. Therefore, there is a trade-off between the power efficiency and side effects when the conventional switching-mode power converting apparatuses are used.

The present invention provides a dynamic power factor corrector (DPFC), wherein the dynamic power factor corrector comprises a switching element, a switching controller and a substantial order-∞ resonant tank according to the present invention, electrically connected in parallel to at least one nonlinear load to function as a dynamic impedance matching circuit. The provided DPFC converts the power from a first form to a second form by switching the switching element on and off at an adjustable frequency, and provides the power in the second form to nonlinear loads, wherein the adjustable frequency is controlled by the switching controller according to the nonlinear loads. The switching controller can be a pulse-width modulation (PWM) controller or any other controllers, and the provided DPFC can be adopted in any kind of power converting apparatuses (such as AC-to-DC rectifiers/adapters, DC-to-DC converters, DC-to-AC inverters, and AC-to-AC converters). Furthermore, for recycling power, the provided DPFC can further comprises a transformer and a AC-to-DC converter, wherein the transformer regenerates power from the current induced by the nonlinear load and extracted by the substantial order-∞ resonant tank, and the AC-to-DC converter converts the regenerated power to become DC power. The DC power can be provided to DC bus or electric energy storage device within the DPFC. Moreover, the DC power can be provided to any external electric energy storage devices as a charging pump. Because this kind of charging pump can charge any kind of electric energy storage devices (such as the battery of a mobile phone and the battery of a digital camera), this charging pump is a substantial “universal charging pump.”

Note that, in the present invention, a DC-to-AC inverter adopting the provided DPFC can be denoted as a symbol shown in FIG. 21; and a DC-to-AC inverter adopting the provided DPFC and further including the power recycling ability can be denoted as a symbol shown in FIG. 24.

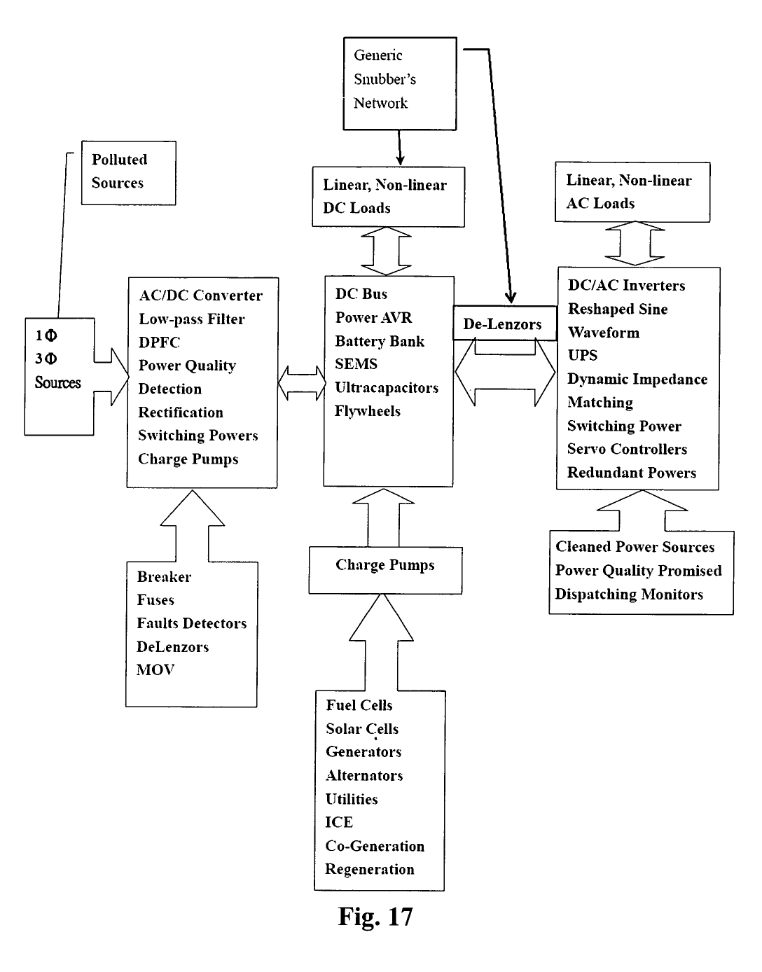

FIG. 17 illustrates an infrastructure of a power system adopting a DPFC according to the present invention. The polluted AC power source input is transferred into DC form, and the DeLenzor according to embodiments of the present invention is added for performing the DPFC and power quality detections. A DC bus at one voltage level is obtained via the different types of the DC charging pumps, which may integrate any available resources, such as Internal Combustion Engine (ICE), agent-base power generators and alternators, regenerating and cogeneration powers, fuel cells, solar cells, flywheels, SEMSs, battery packs, ultracapacitors, or other resources. Therefore, a more robust DC bus is provided. The DC bus provides the DC power via DC/DC converter to the DC devices. For obtaining the reformed sinewave AC power (i.e., purified AC power), a DC-to-AC inverter adopting the provided DPFC is used.

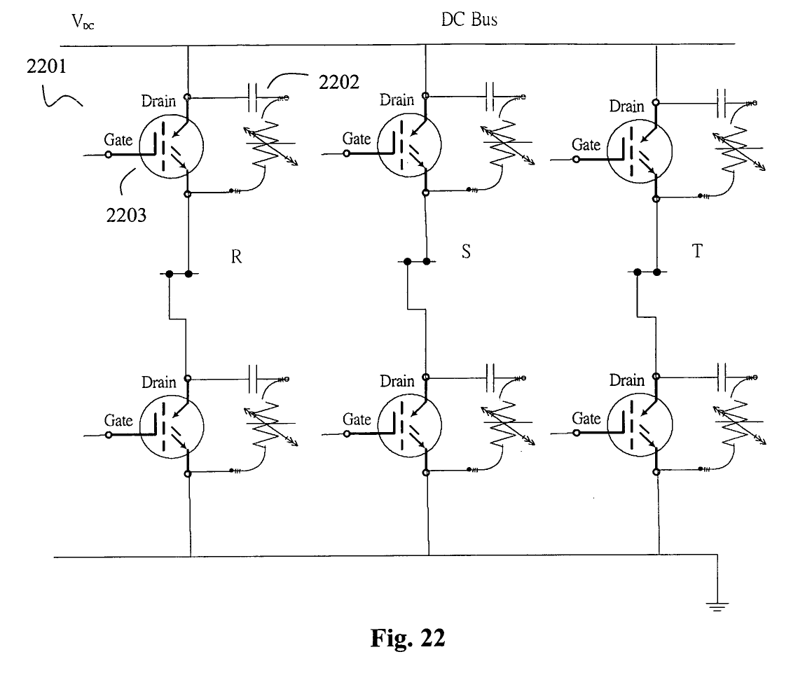

FIG. 22 illustrates an example of a DC-to-AC inverter adopting the provided DPFC, which comprises a full-bridge IGBT-base inverter 2201 with a DeLenzor 2202 according to the present invention, wherein the virtual load locating is performed, i.e., the DeLenzor 2202 is disabled in the normal state (i.e., IGBT 2203 is turned on), and the DeLenzor 2202 absorbs the power when the reactive power appears (i.e., IGBT 2203 is turned off).

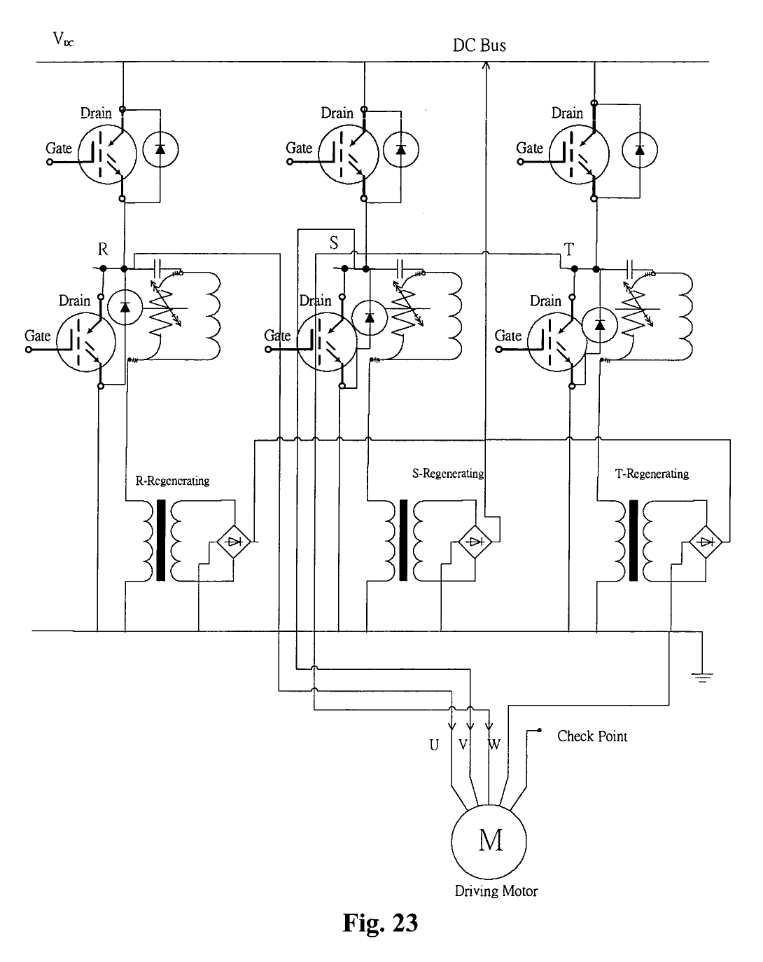

FIG. 23 shows an embodiment of a power converting apparatus with power recycling ability for supplying power to a driving motor according to the present invention.

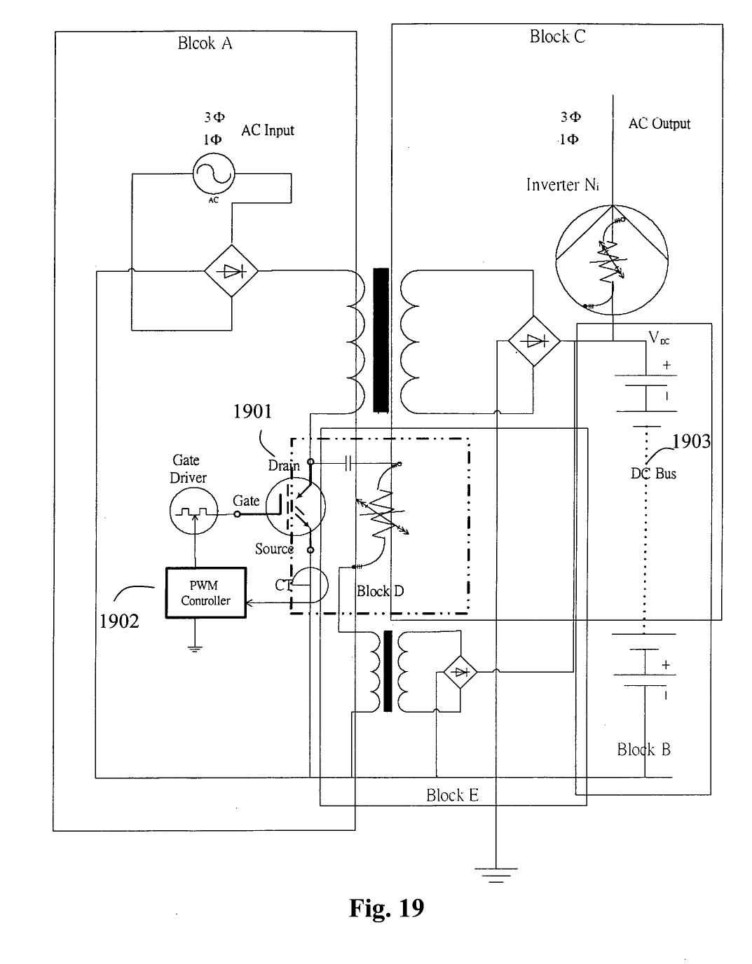

A typical power system having the provided DPFC is illustrated in FIG. 19, wherein more than one inverter can be adopted simultaneously in the power system. Block A comprises a AC-to-DC converter 1901 and a PWM controller 1902 (providing the pulse-width modulated switching-mode signal) which combine with the snubber network in Block D to form a DPFC for producing the average power as defined in equation (13) via monitoring and charging DC bus dynamically. Block B comprises a DC bus 1903 as a buffer for dynamic balancing between charging and system load. In particular, the scale of the DC bus is determined according to the electrical resources integration and system loading scale. Block C comprises an inverter adopting the provided DPFC for providing purified AC power. Block D comprises a snubber network for removing the side effects (such as EMC, EMI, RFI) of the switching actions. Finally, block E demonstrates a unit for recycling the regenerated power as the switching is turned on and off.

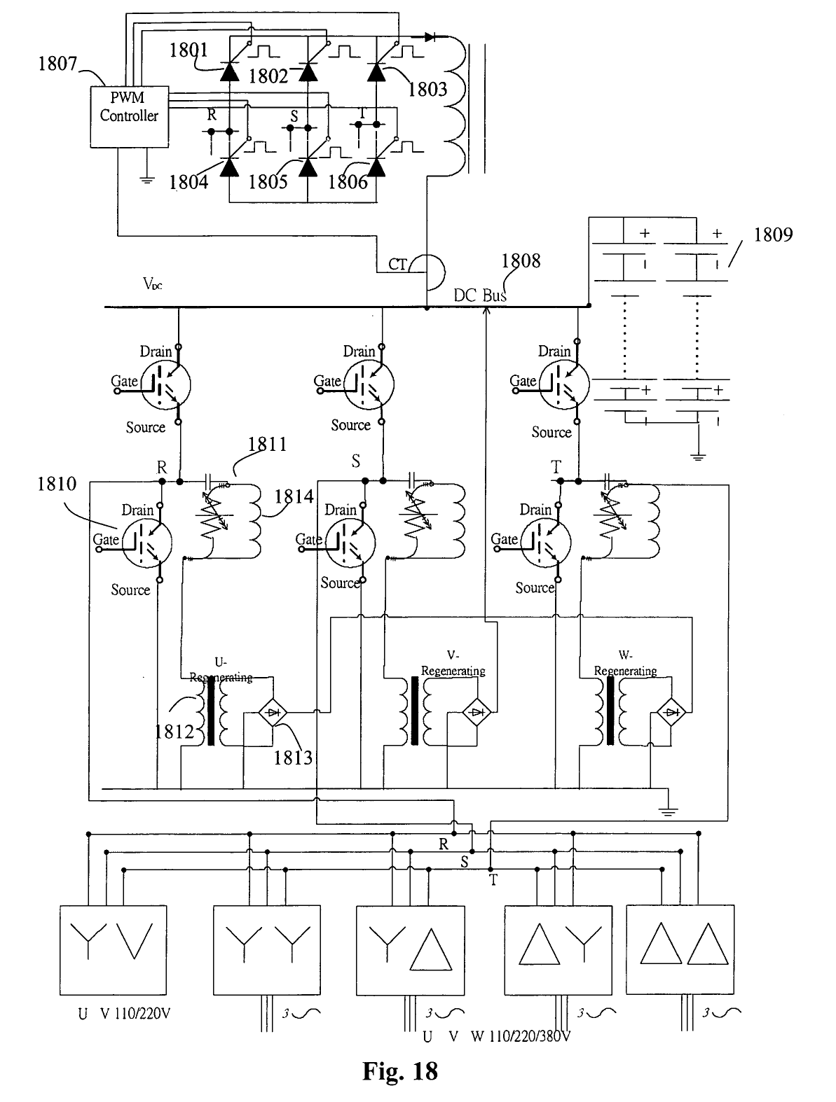

FIG. 18 illustrates a soft-switching power converting apparatus (for high-power required system) comprising the provided DPFC. The three-phase AC power source is provided through six SCRs 1801-1806 (Silicon Controlled Rectifier) controlled by a PWM controller. If high performance and strict operation are concerned, the SCRs can be replaced by IGCTs (Integated Gate Commuated Thyristor) or more advanced integrated power modules (IPMs). Via SCRs 1801-1806 (controlled by the PWM controller 1807), DC power is obtained on the DC bus 1808. And the DC bus 1808 is consisted of a large number of battery packs 1809 for deploying the high-power outputs. The DC bus 1808 in parallel expansion is demonstrated. At the outputs of a full-bridge IGBT-base inverter 1810, an order-∞ resonant tank 1811 is attached to overcome the regenerated power when the IGBT-base inverter 1810 is switching on and off. To recycle the regenerated power will become easier when the current (induced by the nonlinear load) is absorbed by the order-∞ resonant tank 1811. A transformer 1812 regenerates power from the induced current, and the Schottky diode 1813 (functioned as an AC-to-DC converter) converts the regenerated power to become DC power. The regenerated DC power is provided to the DC bus. Note that the inductor 1814 within the order-∞ resonant tank 1811 is for stabilizing the system and avoiding singularity, thus it is not an essential element. The IGBTs outputs are connected with many types of isolated transformers, for example, Y-Y, Y-Δ, Δ-Y, Δ-Δ, Y-V and so on, to provide power supplies at different power levels for fitting the realistic usages. These isolated transformers will substantially filter the DC offsets out completely.

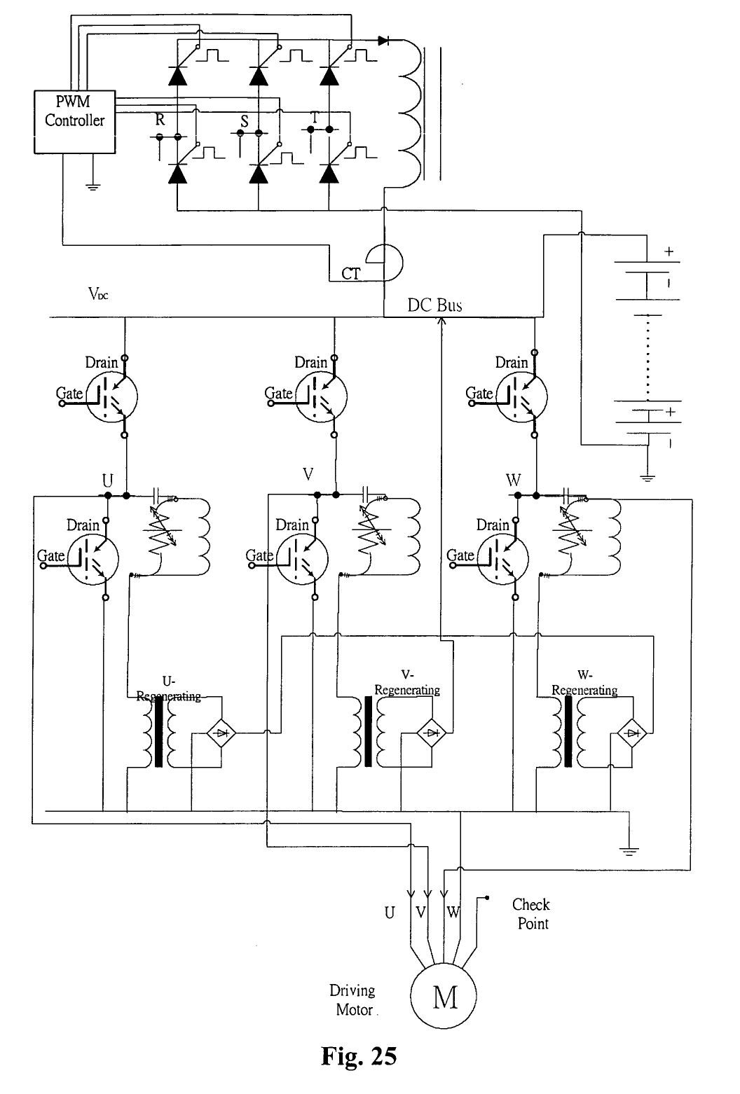

FIG. 25 illustrates another embodiment for supplying power to a driving motor with a soft-switching power converting apparatus adopting a DPFC according to the present invention.

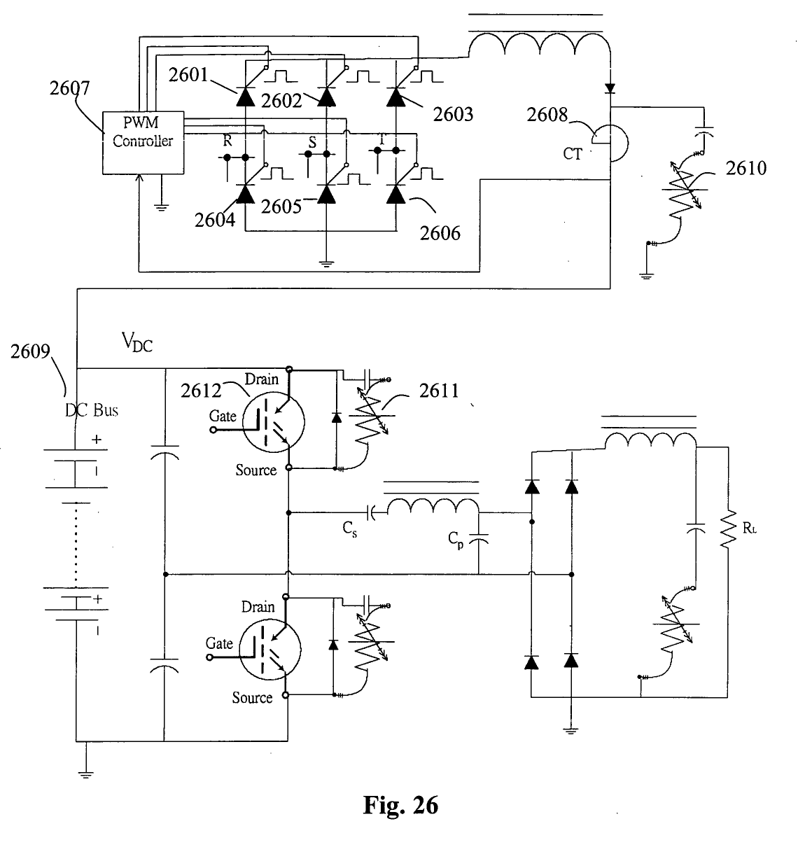

FIG. 26 illustrates an embodiment of a DC-to-DC converter adopting a DPFC according to the present invention. The six SCRs 2601-2606 are controlled by the PWM controller 2607 to produce DC current and voltage. A sensor 2608 provides the voltage level at DC bus 2609 as a feedback to the PWM controller 2607. An order-∞ resonant tank 2610 connected in parallel to the sensor 2608 is for filtering the ripple of the current or voltage on the DC bus 2609. In addition, another order-∞ resonant tank 2611 is connected in parallel to the IGBT 2612 for protecting the IGBT 2612.

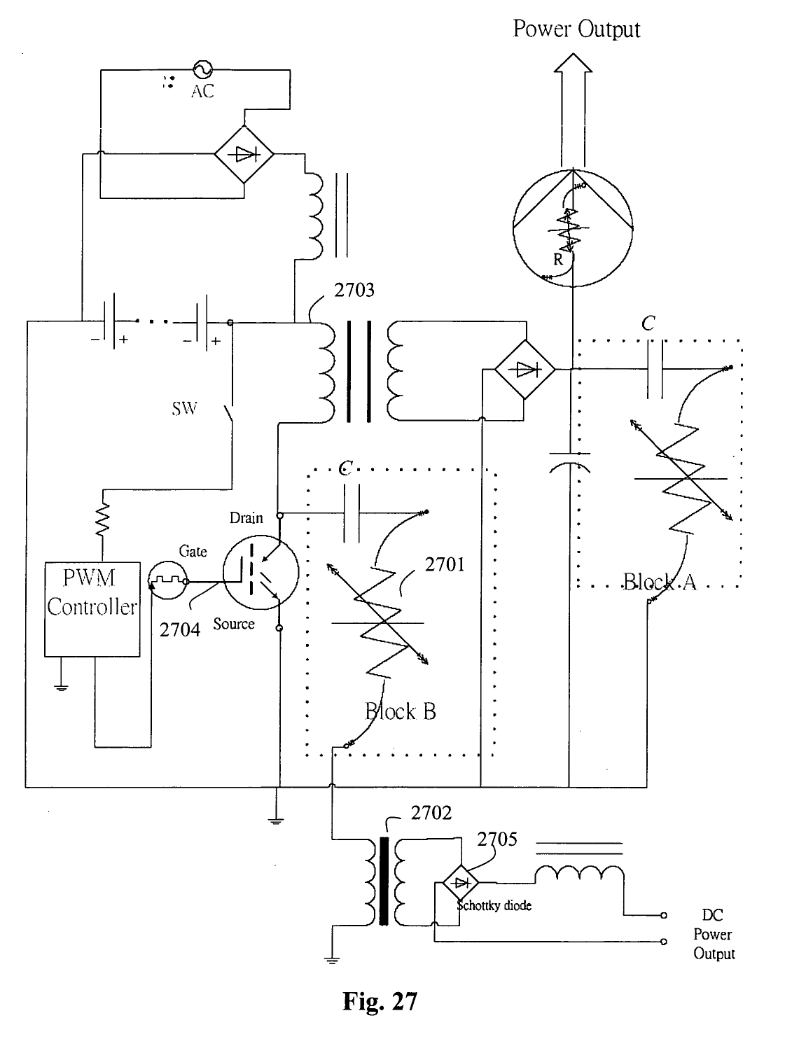

FIG. 27 illustrates an embodiment of a universal charging pump. In Block B, a dynamic damper 2701 extracts the current induced by the substantial inductive element 2703 due to the switching on/off actions of the switching element 2704, and passes the extracted induced current to a transformer 2702. The transformer 2702 regenerates power from the induced current and a Schottky diode 2705 converts the regenerated power to become DC power. The DC power can be provided to any electric energy storage device. Moreover, a spectral resistive element according to the present invention can be placed between the two ends of the DC power output as a spectral dissipative resistor to remove the temperature shock, and thus the system becomes more reliable and stable, without need of any cooling fans or cooling subsystems.

7 Uninterruptible Power Supply

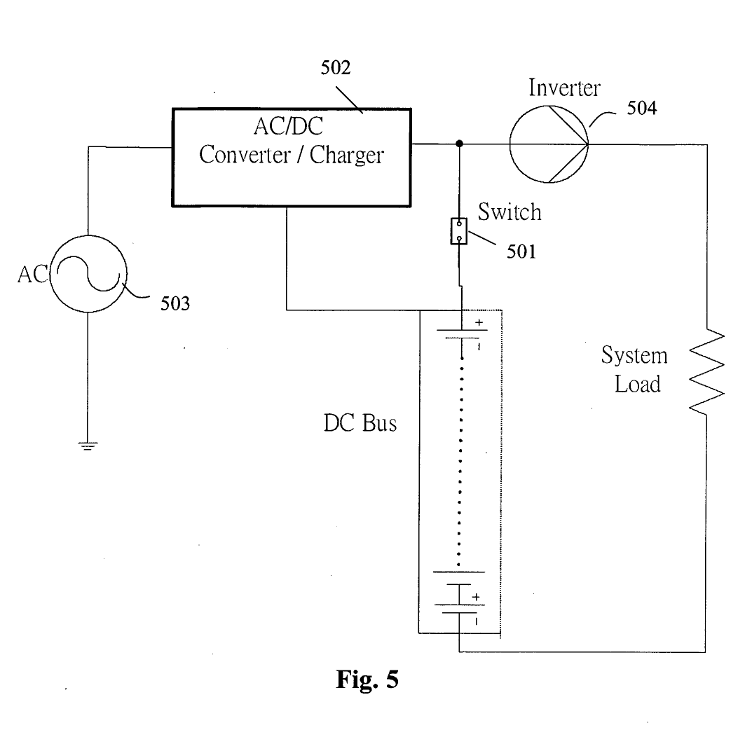

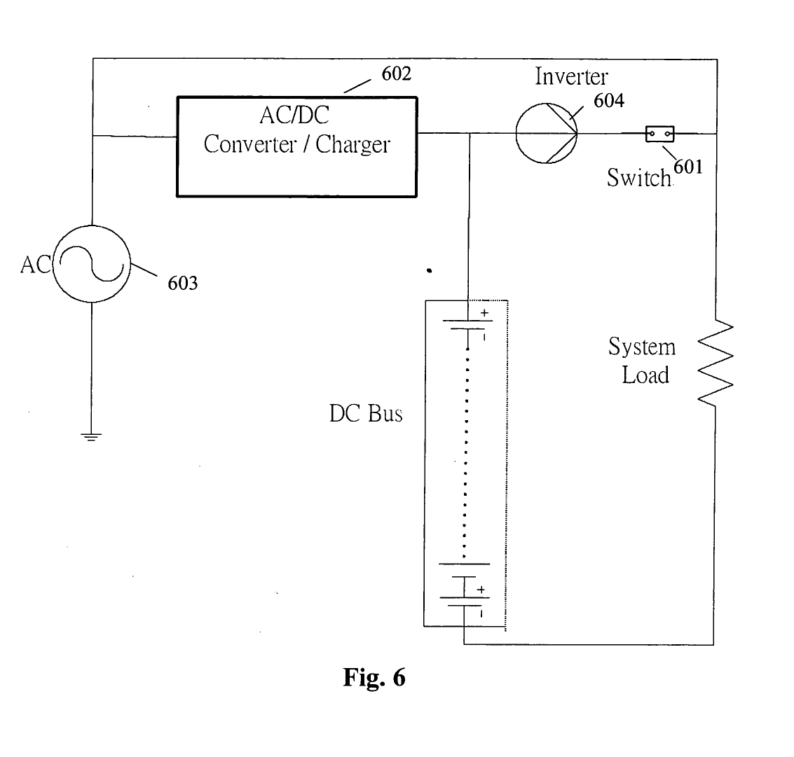

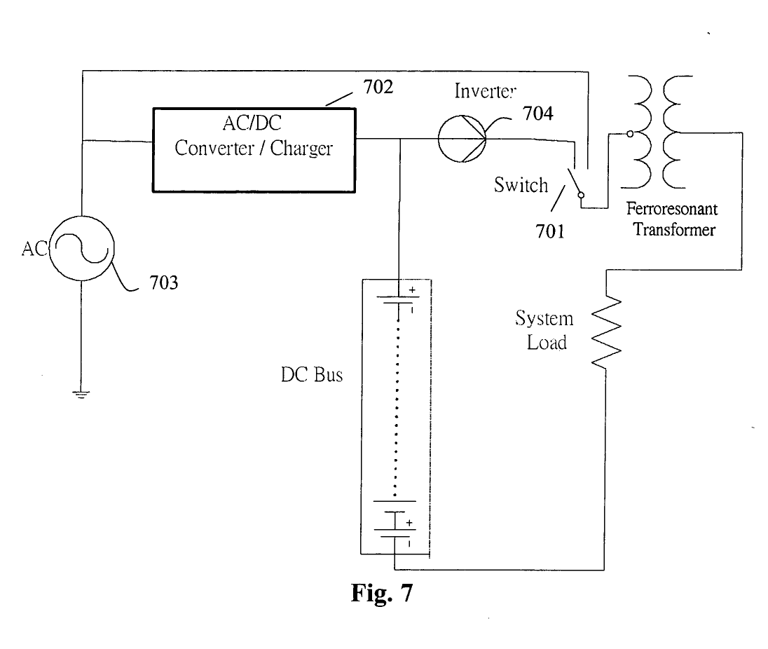

Conventionally, there are three types of uninterruptible power supplies (UPSs)—online, standby and line-interactive as shown in FIGS. 5, 6 and 7, respectively; wherein the switches 501, 601 and 701 are respectively controlled by AC/DC Converter/Charger 502, 602 and 702 when there is an interrupt of AC power sources 503, 603 and 703, respectively. Moreover, the line-interactive UPS uses a ferroresonant transformer for producing a constant voltage output.

However, there are two critical and obvious limitations in these conventional UPSs. One is that the system load should be constantly fixed due to the inverter within the UPS (such as the inverters 504, 604 and 704 shown in FIGS. 5-7) cannot perform dynamic impedance matching. The other one is that the converter within the UPS (such as the AC/DC Converter/Charger 502, 602 and 702 shown in FIGS. 5-7) does not implement the dynamic power factor correction function, and thus the power quality is not guaranteed.

An UPS without above limitations is provided according to the present invention; wherein the UPS is a kind of power converting apparatus described above, which comprises a DPFC according to the present invention with power recycling ability and an electric energy storage device to store the recycled power, such that the UPS according to the present invention can provide high-quality power to system load when there is an interrupt of power source. Actually, the UPS according to the present invention is a new type UPS and named as full-time UPS due to the fact that the UPS can provide power to system load all the time.

FIG. 42 shows an embodiment of this full-time UPS; wherein the converter with DPFC 4201 dynamically detects and monitors the loading variation and maintains the power factor as one all the time, and the inverter 4202 performs the dynamic load impedance matching and power recycling.

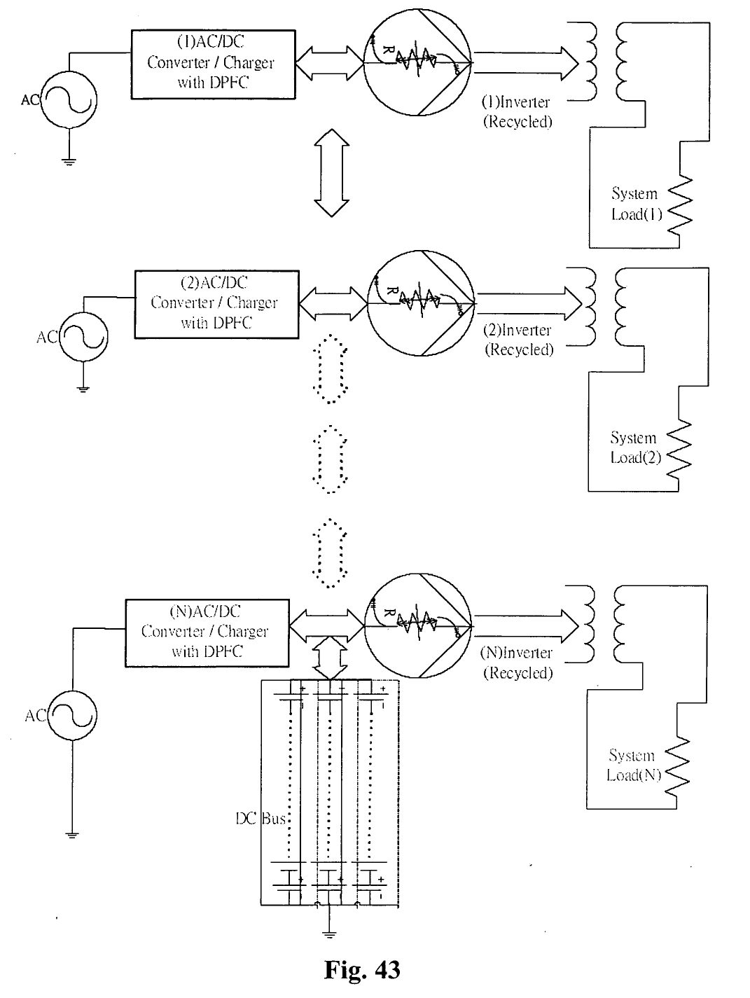

Furthermore, a redundant uninterruptible power supply system can be achieved by electrically connecting a plurality of the UPS according to the present invention in parallel. FIG. 43 shows an embodiment of this redundant uninterruptible power supply system, wherein there are N AC/DC converters and N inverters, and the DC buses are interconnected.

8 Power Resource Management

According to the present invention, power resource of a power system can be well managed when a power converting apparatus having a DPFC according to the present invention (or called agent-base power supply, because this power converting apparatus also functions as an agent to distribute power) exists in the power system. In a centralized power resource management system, the agent-base power supply reports power status data to the power source of the system, and the power source calculates a future power need of the load (to which the agent-base power supply provides power) by using the status data and a prediction algorithm. In a distributed power resource management system, the agent-base power supply calculates a future power need of the load (to which the agent-base power supply provides power) by using a prediction algorithm and reports the calculated data to the power source. Therefore the power source, which can be a power plant, a transformer station, a power converter or a power inverter, can dispatch power to meet the need of power according to the calculated data.

The prediction algorithm can be any kind of existing prediction algorithm. A suitable prediction algorithm—Improved Discounted Least Square (IDLS) method is discussed in Appendix D. Take a centralized power resource management system having m agent-base power supplies for example, when each agent-base power supplies reports its power consumption data at the n^{th} time instant to the power plant, the power plant have all the data from m agent-base power supplies (i.e., [yₙ⁽¹⁾, yₙ⁽²⁾, . . . , yₙ^{(m-1)}, yₙ^{(m)}]), then a reasonable prediction of the future power need for each agent-base power supplies can be obtained by using the IDLS method. Take a distributed power resource management system having m agent-base power supplies for another example, each agent-base power supplies calculates its future power need by using the IDLS method, and reports the state vector

$${x}_{n}^{ⅈ} = [ \begin{matrix}{S}_{n}^{i} \\ {b}_{n}^{i}\end{matrix} ]$$

and corresponding error covariance matrix

$${P}_{n}^{i} = [ \begin{matrix}{p}_{n 11}^{i} & {p}_{n 12}^{ⅈi} \\ {p}_{n 21}^{i} & {p}_{n 22}^{i}\end{matrix} ]$$

to the power plant. According to the framework of covariance intersection as disclosed in [68], [45], Chapter 10 of [7] and [34], the estimated state is

$$[ \begin{matrix}{\hat{S}}_{n + 1} \\ {\hat{b}}_{n + 1}\end{matrix} ] = {\sum }_{i = 1}^{N} {w}^{ⅈ} [ \begin{matrix}{\hat{S}}_{n + 1}^{i} \\ {\hat{b}}_{n + 1}^{i}\end{matrix} ]$$

$$where$$

$${\sum }_{i = 1}^{N} {w}^{i} = 1$$

$$and$$

$${w}^{ⅈ} = \frac{{α}_{i} {p}_{i}^{- 1}}{{\sum }_{i = 1}^{N} {α}_{i} {P}_{i}^{- 1}}$$

The above solution of fusing all information reported by each agent-base power supplies is obtained by applying equation (95) (please refer to Appendix D) to produce the weight \hat{α}ᵢ (and thus the weight \hat{ω}ⁱ is obtained).

9 Pseudo Vacuum Tube Power Amplifier

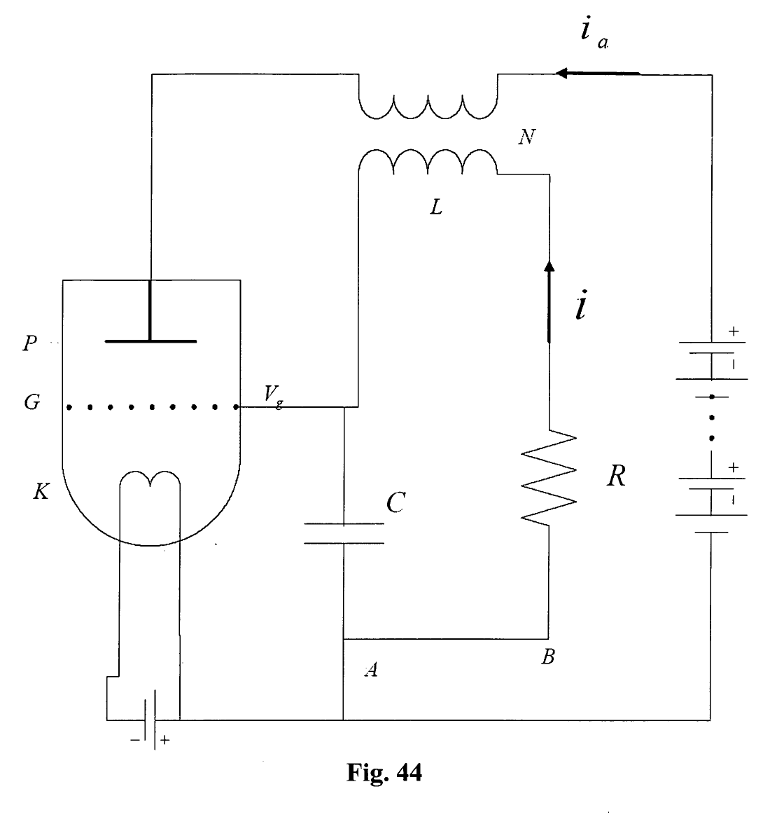

A vacuum tube power amplifier is illustrated in FIG. 44. According to the Kirchhoff's law, the gate voltage V_{g} must satisfy

$$L \frac{ⅆ ⅈ}{ⅆ t} + ⅈ R + {V}_{g} - M {i}_{a} = 0 \qquad ( 55 )$$

The amplified current i_{α} is controlled by the gate voltage V_{g} as follows:

$${i}_{a} = {SV}_{g} ( 1 - \frac{{V}_{g}^{2}}{3 {K}^{2}} ) \qquad ( 56 )$$

where S, M and K are the constants, and

$$C \frac{ⅆ {V}_{g}}{ⅆ t} = i$$

Then equation (55) becomes a second-order nonlinear differential equation

$$LC \frac{{ⅆ}^{2} {V}_{g}}{ⅆ {t}^{2}} + ( \frac{MS}{{K}^{2}} {V}_{g}^{2} + RC - MS ) \frac{ⅆ {V}_{g}}{ⅆ t} + {V}_{g} = 0 \\ Let \\ x = [ \frac{1}{K} \sqrt{( \frac{MS}{MS - RC} )} ] {V}_{g} \\ α = \frac{MS - RC}{LC \cdot } \\ and \\ {ω}^{2} = \frac{1}{LC} \qquad ( 57 )$$

The equation (57) will be as follows

$$\frac{{ⅆ}^{2} x}{ⅆ {t}^{2}} + α ( {x}^{2} - 1 ) \frac{ⅆ x}{ⅆ t} + {ω}^{2} x = 0 \qquad ( 58 )$$

This is a famous equation known as Van der Pol system. For most large power amplifier systems, it is more effective than all other power electronics systems. One superior feature of the system (58) is that it is a completely isolated and damped power amplification system. Comparing the system shown in equations (52) and (53) to that shown in equation (58), the nonlinear spring-damping term becomes

$$h ( x , \frac{ⅆ x}{ⅆ t} ) = ( {x}^{2} - 1 )$$

The system (58) has the positive or negative damper effects according to
α=±ε

In fact, the bifurcation condition exists in equation (58).

However, there are two primary drawbacks in the vacuum tube power amplifier as shown in FIG. 44. One is that heat (or temperature shock) is produced, and the other is that the frequency response is low.

According to the present invention, a pseudo vacuum tube power amplifier is provided, and none of the above drawbacks exist in this pseudo vacuum tube power amplifier. The pseudo vacuum tube power amplifier comprises a power converting unit with a DPFC according to the present invention and is connected between an audio signal source (such as CD player or MP3 player) and a speaker, wherein the power converting unit receives audio signal from the audio signal source, amplifies the audio signal, and provides the amplified audio signal to the speaker for playing. The order-∞ resonant tank formed by the power converting unit with DPFC and the speaker provides this pseudo vacuum tube power amplifier with the ability to remove any noise from the reactive power of the speaker, and thus the audio quality of the amplified audio signal is as good as a conventional vacuum tube power amplifier.

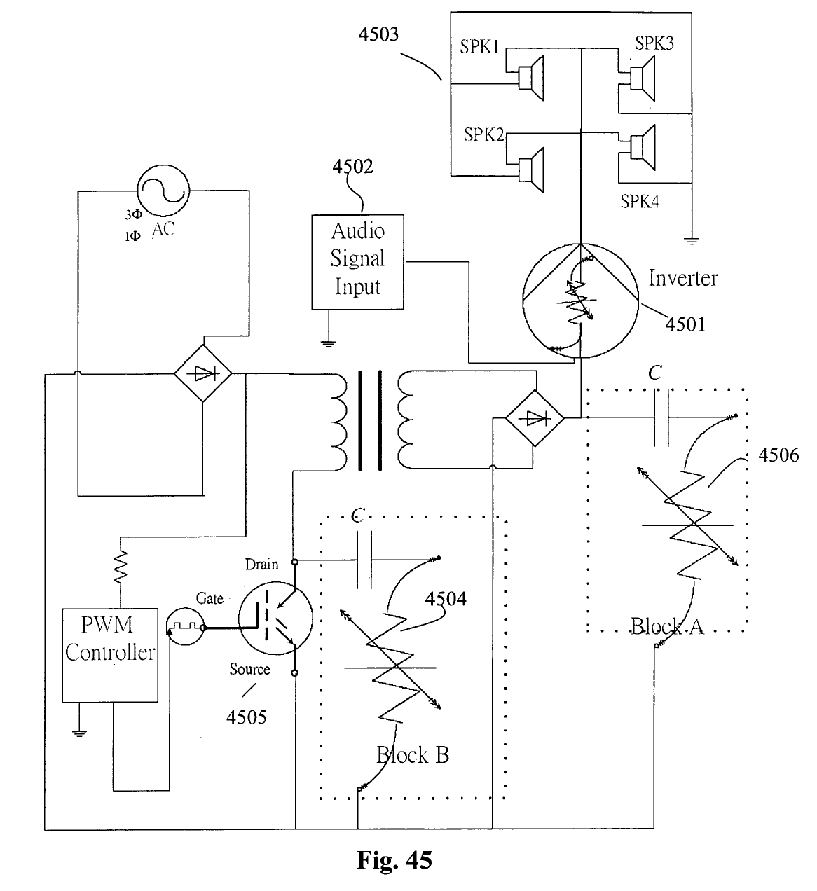

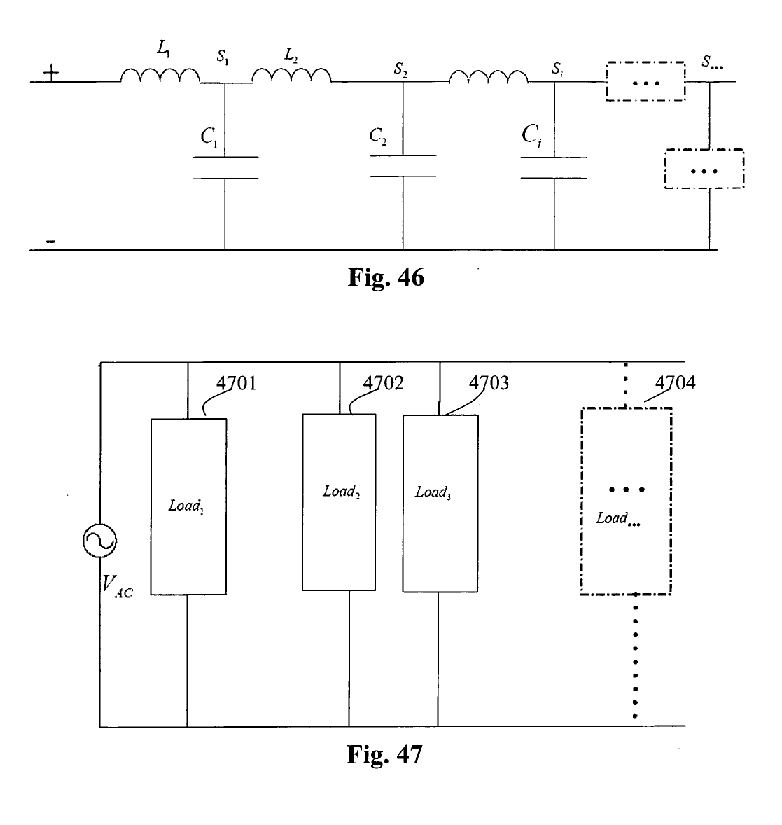

FIG. 45 illustrated an embodiment of the pseudo vacuum tube power amplifier.

The inverter 4501 receives audio signal from the audio signal input 4502, amplifies the audio signal, and provides the amplified audio signal to speakers 4503 for playing. In Block A, a dynamic damper 4506 is as functioned as a ripple filter for smoothing the voltage and current on DC bus. In Block B, the DeLenzor 4504 is adopted to clear out the reactive power due to the switching on/off actions of the switching-mode power converter 4505.

10 Inertial Navigation System

Having DC bias signal (or DC drifting signal) within the original signal sensed by inertial navigation sensors (such as accelerometers or gyroscopes) is an intrinsic problem in the existing inertial navigation systems (INS) (see [38], page 94 of [70], [81], [3], page 343 of [36] and [17]). Persons skilled in the art tried many ways but still failed to remove such unwanted DC bias signal from the original signal.

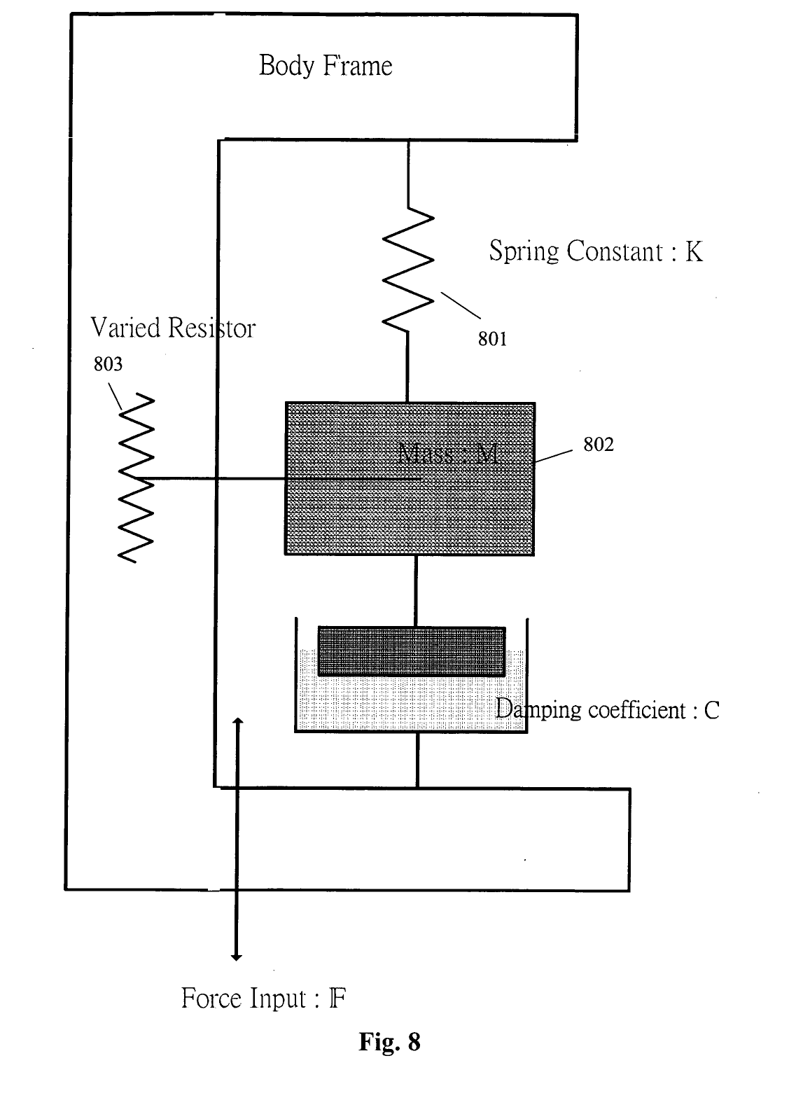

FIG. 8 shows a simple but typical mechanical accelerometer (see page 45 of [38]) of a INS inside a vehicle. When the vehicle accelerates, the mass 802 moves, and the spring 801 moves along with the mass 802 such that the resistance of the variable resistor 803 is adjusted accordingly. Therefore, the acceleration signal can be extracted by sensing the voltage across the variable resistor 803. However, spring is nearly impossible to be consistent after a time period (due to the fatigue and ageing of the spring); therefore, the sensed acceleration signal may contain unwanted DC bias signal and cause the incorrectness of the INS.

According to the present invention, an inertial navigation system (INS) with de-bias ability is provided, wherein a substantial order-∞ resonant tank according to the present invention is electrically connected to an inertial navigation sensor (such as a accelerometers or a gyroscope) for extracting pure AC signal (real signal without DC bias) from the output of the inertial navigation sensor. The substantial order-∞ resonant tank filters out any interferences, especially the DC bias signal; in other words, the benefit contributed from this order-∞ resonant tank is to keep the signal-noise ratio (SNR) of the INS sensor maximized at each sampling period. Therefore, this INS is an on-line auto-calibration system.

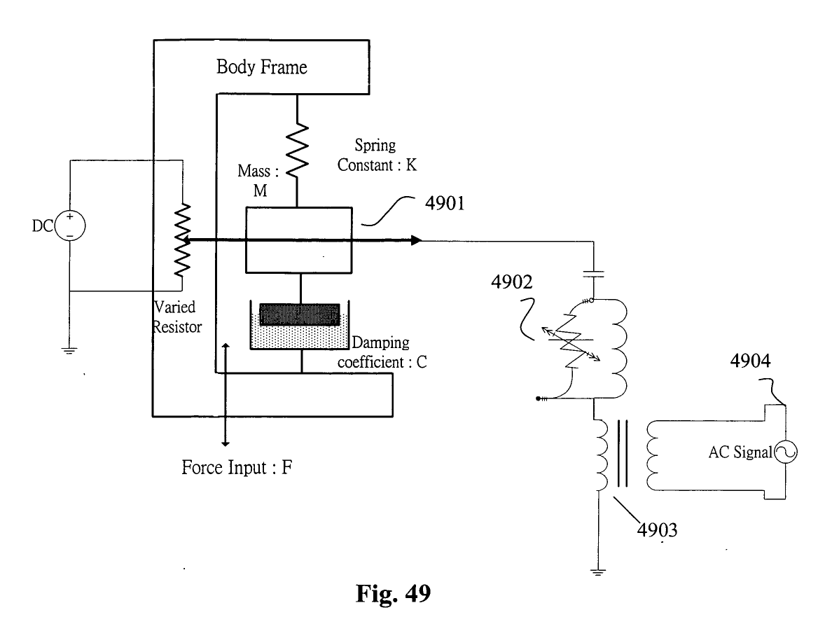

FIG. 49 shows an embodiment of the INS according to the present invention. When the force F occurs, the acceleration signal (AC signal with DC bias) sensed by accelerometer 4901 would pass through the order-∞ resonant tank 4902. Then, the AC part of the acceleration signal will be extracted by the order-∞ resonant tank 4902 and passes through the isolated transformer 4903; thus, the DC bias is removed. Finally, the isolated transformer 4903 will regenerate a purified AC signal 4904, which indicates the real acceleration.

The reason why the proposed INS can remove DC bias successfully is theoretically discussed as follows. Basically, the equation of motion for this spring-damper-mass system is

$$M \frac{{ⅆ}^{2} y}{ⅆ {t}^{2}} + C \frac{ⅆ y}{ⅆ t} + Ky = F \qquad ( 59 )$$

with corresponding eigenvalues

$${λ}_{1 , 2} = \frac{- C \pm \sqrt{{C}^{2} - 4 MK}}{2 M} .$$

When the resonance frequency is defined as

$${ω}_{r} = \sqrt{\frac{K}{M}} ,$$

elgenvalues are

$${λ}_{1 , 2} = ( - ζ \pm \sqrt{{ζ}^{2} - 1} ) {ω}_{r}$$

wherein the damping ratio ζ is defined as

$$\begin{matrix}ζ = \frac{C}{2 \sqrt{KM}} \\ = \frac{1}{2} \frac{C}{M} \frac{1}{{ω}_{r}}\end{matrix}$$

The resonant frequency ω is
ω=ωᵣ\sqrt{1=ζ²} (60)
where damping ratio ζ is
0<ζ<1.

That is, this spring-damper-mass system is an under-damping-response system. The Q factor is then obtained as

$$Q = \frac{1}{2 ζ} \qquad ( 61 )$$

When the signal is detected and is at the extreme of equation (61), i.e., the damping ratio is minimum (at the resonant point), and thus the SNR is effectively large (i.e. the signal has good quality). However, the fatigue or ageing of the material may make the damping ratio drift, and the deviation of the damping ratio cannot be detected conventionally. After coupling an order-∞ resonant tank to the original system, the damping ratio deviation would be corrected (i.e. the DC bias is blocked and removed) due to the fact that the order-∞ resonant tank can function as a damper with variable damping ratio to correct the damping ratio deviation of original system.

11 Electromagnetic Wave Absorbing Material

An electromagnetic wave absorbing material having the characteristics of the order-∞ resonant tank is provided. This electromagnetic wave absorbing material comprises a first dielectric material and a second dielectric material; wherein at least a part of the first dielectric material is electrically connected to at least a part of the second dielectric material; and wherein the resistance of one of the first and second dielectric materials monotonically increases with increasing frequency, while the resistance of the other one of the first and second dielectric materials monotonically decreases with increasing frequency. The first and second dielectric materials can be any dielectric materials having dipole property (see [74]), such as GaAs, BaTiO₃ and metal oxide. This electromagnetic wave absorbing material can extract electric power from power in other manifestations (such as radioactive decay energy) or damp out unwanted electric power (such as electrostatic discharge).

11.1 Microwave Absorber

A microwave absorber can be implemented by arranging (e.g., coating) this electromagnetic wave absorbing material on the surface of any objects. Because the directions and wavelength of microwave are stochastic, the microwave will be absorbed and damped out by this electromagnetic wave absorbing material when the microwave reaches the surface. In other words, no any charged electron of the microwave will be reflected, and thus radar base stations will not detect the object with this electromagnetic wave absorbing material on its surface.

11.2 Electrostatic Discharge Protector

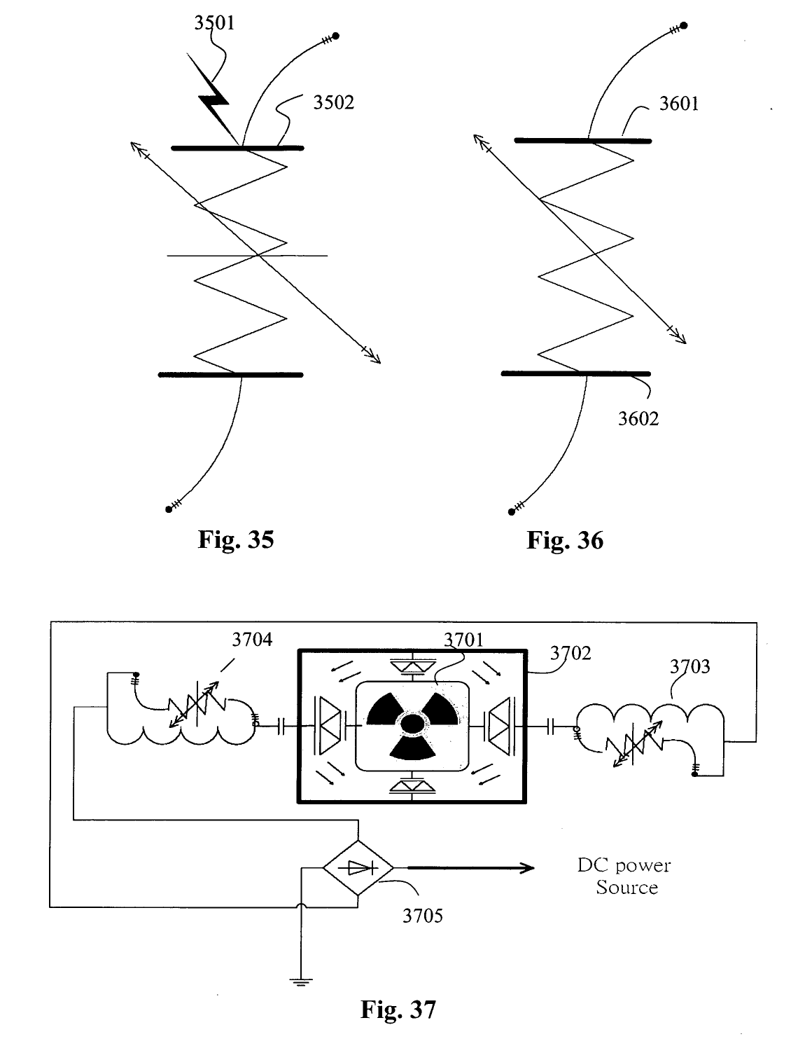

An electrostatic discharge (ESD) protector can also be implemented by arranging (e.g., coating) this electromagnetic wave absorbing material on its surface. When the surface current passing through this electromagnetic wave absorbing material, the power is quickly damped out. This provided ESD protector can be denoted as the symbol shown in FIG. 35, wherein when surface current 3501 passing through the surface 3502, on which this electromagnetic wave absorbing material is arranged, the power is quickly damped out.

11.3 Antenna

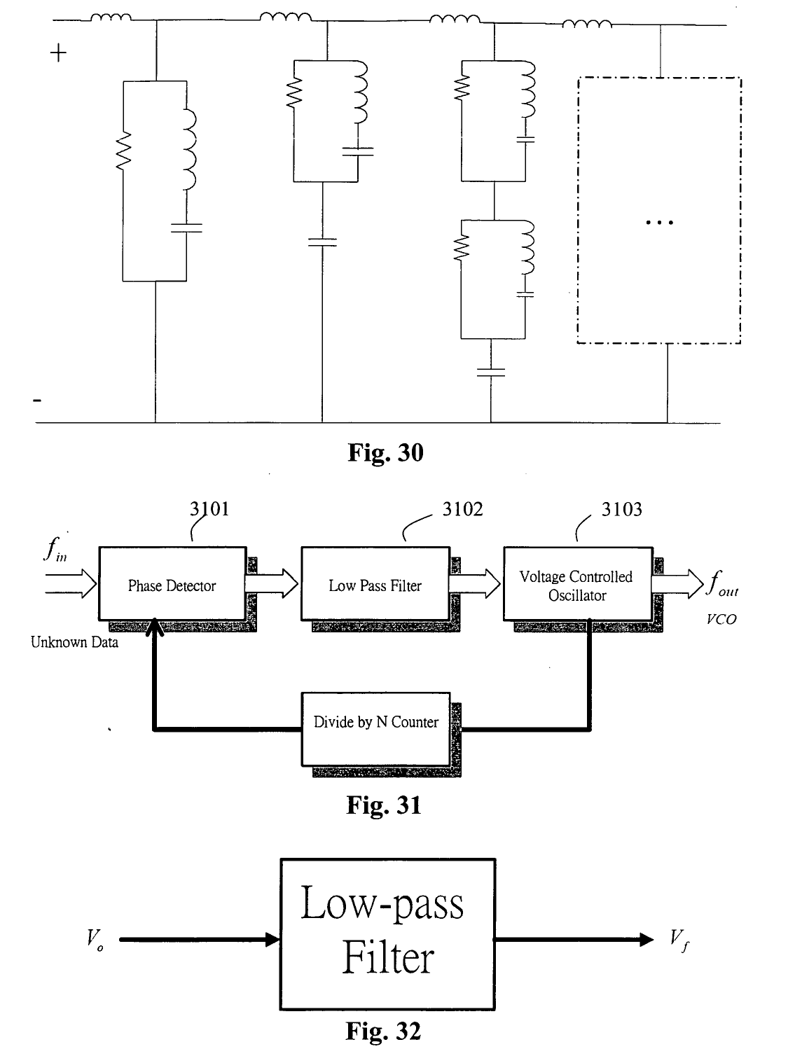

Moreover, an antenna with arbitrary shape can be implemented by using this electromagnetic wave absorbing material to receive and transmit radio waves. Fundamental skills and techniques for the antenna design have been disclosed in Chapter 7 of [6], [44] and [23]. In the real world, under high-frequency operating condition, any conductive line is made of many types of complicated R. L and C combination as shown in FIG. 30. Therefore, it is not easy to determine the total impedance of the system in any working environment, and thus an antenna with high Q is not easy to implement.

According to the present invention, an antenna with the provided electromagnetic wave absorbing material arranged on and electrically connected to its surface is equivalent to a plurality of order-∞ resonant tanks coupled to each other. According to equations (50) and (49), the variation of Q can be expressed as

$$\begin{matrix}Δ Q = \frac{1}{2 {ζ}^{2}} Δ ζ \\ = - ( \sqrt{\frac{L}{C}} ) ( \frac{1}{{R}^{2}} ) ( Δ R ) - ( \sqrt{\frac{L}{C}} ) ( \frac{1}{2 RC } ) ( Δ C ) + \\ ( \sqrt{\frac{1}{LC}} ) ( \frac{1}{2 R} ) ( Δ L )\end{matrix} \qquad ( 62 )$$

When the coefficients of ΔR, ΔC, ΔL, C and L are selected as constants (or with small variations), the most sensitive term is 1/R² during the searching for the maximized Q value. Therefore, a plurality of order-∞ resonant tanks coupled to each other can function as a Q-factor regulator. Furthermore, because the antenna according to the present invention can be implemented in a very small size, this antenna is a kind of dielectric mold-injection antenna with infinitesimal dipole
L<<λ
where λ is the wavelength of radio carrier and L is the length of the antenna.

This antenna is especially suitable for a radio frequency identification (RFID) device. A RFID device is a wireless device that some information (e.g. bar codes) is stored therein (usually managed by the RFID controller within the RFID device) and the stored information can be read out when the RFID is within the proximity of a transmitted radio signal from a RFID reader. A passive type RFID device has no power source but uses the electromagnetic waves transmitted from a RFID reader. For this application, the operating condition (high Q-value maintenance) is much restricted, i.e., high RF power quality between the RFID device and the RFID reader is needed. Moreover, in most general cases, the size and weight of the RFID device is very crucial. Obviously, the antenna according to the present invention is suitable for RFID device for its high Q characteristic and small size.

11.4 Nuclear Power Converting Apparatus

A resonant nuclear battery was invented by Dr. Paul M. Brown (refer to U.S. Pat. No. 4,835,433, entitled “Apparatus for Direct Conversion of Radioactive Decay Energy to Electrical Energy.”) to extract electric energy through the nuclear fission or fusion process. However, the efficiency of the conventional resonant nuclear battery is not satisfied. The present invention provides a nuclear power converting apparatus comprising a nuclear material, a container containing the nuclear material, and the electromagnetic wave absorbing material according to the present invention, arranged (e.g. coating) on at least a part of the surface of the container to extract electric power from radioactive decay energy released by the nuclear material. Moreover, according to the present invention, the nuclear power converting apparatus can further comprise an AC-to-DC converter electrically connected to said at least part of the surface of said container for converting the extracted electric power to be DC power.

FIG. 37 shows an embodiment of a nuclear power converting apparatus according to the present invention. The nuclear material 3701 (such as the waste resulting from the nuclear fission) is placed in the container 3702, coated with the electromagnetic wave absorbing material according to the present invention, and thus the surface can function as an antenna to absorbed the charged electrons released by the nuclear material 3701. Moreover, substantial dynamic impedance matching circuits 3703 and 3704 are formed with the electromagnetic wave absorbing material on the surface. Therefore, the absorbed charged electrons can pass through the Schottky diode 3705 to become DC power.

The main benefits of the nuclear power converting apparatus are that no cooling system is required, the spectrums distribution are perfectly identified, the imposed high-electrical energy is attenuated and extracted over all available and identified spectrum domain, and no additional isolation cover is required. Therefore, the nuclear power converting apparatus according to the present invention can effective extracts electric power with small weight and volume.

11.5 Data Transmission Bus

For transmitting logic state information (such as address, data and control signals) between digital controllers (such as CPUs, DSPs, ASICs, PICs and SOCs), heavy power is applied in a small-mill area for pushing the logic state. When an ultra-high frequency (>1.0 GH_{z}) current passing through a small-mill conductive line (commonly, it is made of metal, such as gold), the corresponding resistance of the conductive line becomes high and thus raises the thermo shock. Therefore, how to prevent overheat due to the thermo-shock becomes an essential design issue.

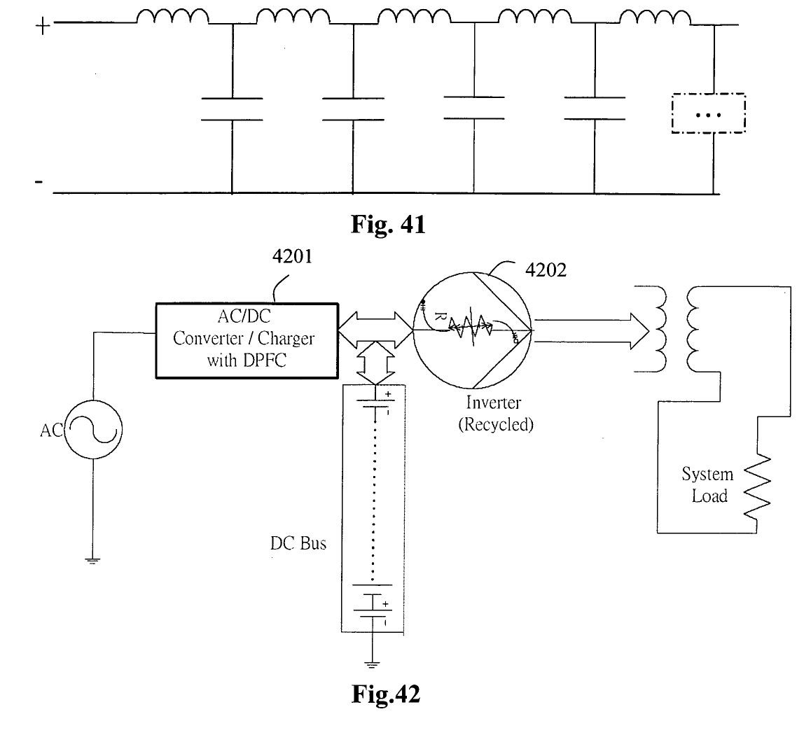

As discussed, in the real world, under high-frequency operating condition, any conductive line is made of many types of complicated R, L and C combination as shown in FIG. 30, and there are many undetermined impedances with frequencies interactions. Therefore, it is a complex problem to determine the order of resonant tank required to couple with the real conductive line for making the conductive line become an ideal conductive line as shown in FIG. 41.

According to the present invention, a data transmission bus comprising the provided electromagnetic wave absorbing material is equivalent to a plurality of order-∞ resonant tanks coupling to each other, and thus can fit-in any operating mode. Each of the order-∞ resonant tanks functions as a buffer to collect the state information, thereby performing the dynamic impedance matching, lock the state information and transmit the state information by coupling. That is, each data transmission bus according to the present invention is an ultra-wide band pass filter and signals are extracted from its corresponding resonant point. Consequently, digital controllers do not need heavy power any more, and thermo-shock extinguishes directly; thus, there is no need of any cooler or fan in the system, and power saving is achieved. The data transmission bus can be a control bus, address bus or a data bus electrically connected between digital controllers.

Moreover, as described above, a substantial order-∞ resonant tank according to the present invention can be electrically connected to a substantial inductive circuit in parallel to perform power dissipation operation. Therefore, such a substantial order-∞ resonant tank is functioned as a fanless cooling system.

12 Spectral Capacitor

A spectral capacitor based on the constitute law of elasticity of electricity is provided and denoted as the symbol shown in FIG. 36. This spectral capacitor comprises a first plate 3601, a second plate 3602, a first dielectric material and a second dielectric material; wherein the first and second dielectric materials are arranged between the first plate and the second plate (e.g. the first and second dielectric materials may be coated on the first plate and the second plate, respectively); wherein the capacitance of one of the first and second dielectric materials monotonically increases with increasing frequency, and the capacitance of the other one of the first and second dielectric materials monotonically decreases with increasing frequency. The first and second dielectric materials can be any dielectric materials having dipole property (see [74]), such as GaAs, BaTiO₃ and metal oxide.

12.1 Adaptive Voltage Controlled Oscillator

According to the present invention, an adaptive voltage controlled oscillator (VCO) can be implemented by connecting a spectral capacitor according to the present invention in parallel to the input of a voltage-controlled oscillator (where the control voltage is applied). FIG. 34 shows an embodiment of this adaptive VCO.

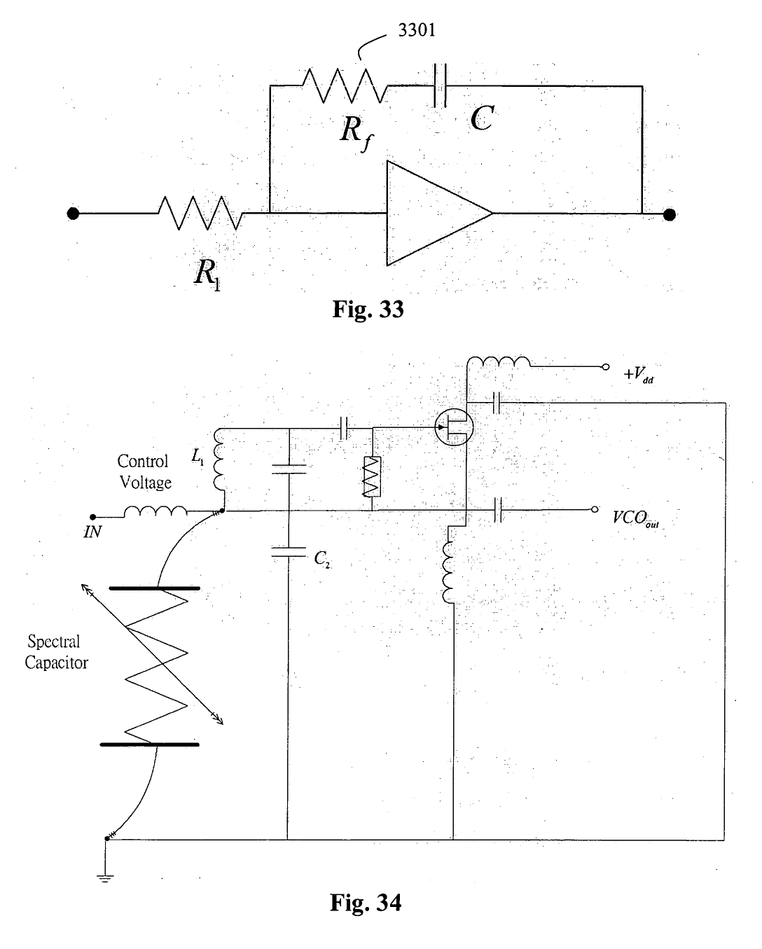

This adaptive VCO is suitable for a phase-locked loop (PLL) circuit—a closed-loop feedback control circuit to generate a signal in a fixed phase relationship to a reference signal for synchronizing or tracking purposes. FIG. 31 shows a basic PLL circuit, wherein the phase detector 3101 detects the phase angle of an input signal (i.e., βᵣₘₛ in equation (16)) and the phase difference (i.e., Δφ in equation (16)) between the input signal and the reference signal according to equation (16). The average output voltage Vₒᵤₜ of the phase detector can be expressed as
Vₒᵤₜ=K_{φ}Δφ
where K_{φ} is the phase detector conversion gain. The input and output signal of the low pass filter 3102 is shown in FIG. 32:
V_{f}=F(s)Vₒ
where F(s) is the transfer function of the low-pass filter 3102. If the low pass filter 3102 is implemented as shown in FIG. 33 according to the present invention (i.e., comprising the spectral resistor 3301), the cutoff frequency of the low pass filter would be

$${ω}_{Lpf} = \frac{1}{{R}_{1} C} ,$$

and the loop natural frequency ωₙ and damping factor are

$${ω}_{n} = \sqrt{K {ω}_{Lpf}}$$

$$and$$

$$ζ = \frac{{R}_{f} C}{2} {ω}_{n}$$

respectively, wherein the term K is the DC loop gain. Moreover, if the VCO 3103 is the adaptive VCO according to the present invention, the frequency difference between the input signal and the reference signal would be detected and adjusted automatically.
13 Non-Contact Anti-Skid Braking System

A non-contact anti-skid braking system (ABS) can be achieved according to the present invention, wherein the braking force comes from the interaction between a rotor and a stator. This non-contact ABS can be used in a vehicle and comprises a rotor driven by one element on the transmission line of the vehicle (such as a wheel, a rotary motor or a propeller), an electric power storage device (such as a battery or a capacitor), a brake controller (such as a brake pedal or a brake button), a pulse-width modulation (PWM) controller triggered by the brake controller to receive power from the electric power storage device and provide pulse-width modulated DC current to the rotor, a stator, and an order-∞ resonant tank according to present invention connected in series to the stator. The rotor rotates along with the element on the transmission line of the vehicle when the vehicle is moving, and once the PWM controller is triggered by the brake controller (e.g., when the driver steps on the brake pedal or presses the brake button), the PWM controller will receive power from the electric power storage device and provide pulse-width modulated DC current to the rotor. When the DC current passes through the rotor (which is rotating due to the moving of the vehicle), an electromagnet is formed and thus an AC current is induced at the stator and extracted by the substantial order-∞ resonant tank. The induced AC current will cause a magnetic field that opposes against that of the electromagnet, and thus the rotating speed of the rotor (attaching to the element on the transmission line of the vehicle) is decelerated, and thus the vehicle is decelerated. Note that while the braking controller triggers the PWM controller, the PWM controller can substantially be controlled by one or more of the factors including the strength sensed by the brake controller (e.g., the force applied on the brake pedal or the brake button), the speed of the vehicle and the tilt level of the vehicle. And because the PWM controller controls the braking force, this braking force is a kind of frequency modulated braking force. Moreover, the ABS according to the present invention may further comprise a AC-to-DC converter to receive the power extracted by the substantial order-∞ resonant tank, convert the received power to be DC power and provide to any electric power storage device (such as a battery or a capacitor); by this way, the provided ABS becomes a regenerative ABS.

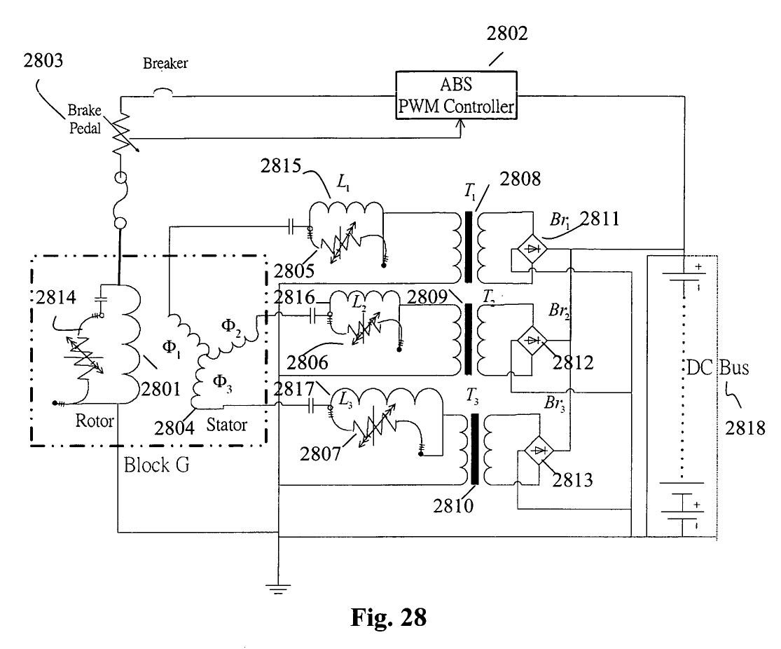

FIG. 28 illustrates an embodiment of the non-contact ABS according to present invention. The DC current passing through the rotor 2801 is controlled by the PWM controller 2802 (which is triggered by the brake pedal 2803), i.e. the DC current is pulse-width modulated. The AC current induced at stator 2804 (Φ₁, Φ₂, Φ₃) will be extracted by the order-∞ resonant tanks 2805, 2806 and 2807 (corresponding to each phase). The transformers T₁ 2808, T₂ 2809 and T₃ 2810 regenerate an AC power from the power extracted by the order-∞ resonant tanks 2805, 2806 and 2807 and pass the regenerated AC power to Schottky diodes 2811, 2812 and 2813 to rectify the regenerated AC power to be DC power. The rectified DC power is provided to DC bus 2818. An order-∞ resonant tank 2814 can be connected in parallel to the rotor 2801 to remove any AC current on the DC bus 2818. The inductors L₁ 2815, L₂ 2816 and L₃ 2817 are merely for providing the compensation for the inductances fluctuation.

The non-contact ABS according to the present invention can be used in electric vehicles, hybrid-electric vehicles or any other kinds of vehicles.

14 Power Generating Apparatus

Conventionally, a generator is used to convert mechanical energy (such as wind power, water power or tidal power) into electrical energy. However, such generator is usually not stable due to the mechanical energy providing to it is discontinous and unpredictable. The instability of conventional power generators will create many heat sources, which will cause the problem of thermo-shock, and will adversely affect the efficiency of electrical power generation. According to the present invention, a power generating apparatus (such as a generator, a dynamo or an alternator) for generating electrical power from mechanical energy (such as wind power, water power or tidal power) or other kinds of energy is provided. This power generating apparatus comprises a rotor driven by a mechanical force, a stator, and a substantial order-∞ resonant tank according to present invention connected in series to the stator. When the rotor is rotating due to the mechanical force (e.g., when wind power, water power or tidal power applies on the blades of a turbine connected to the rotor, the rotor rotates along with the blades), the magnet or electromagnet of the rotor will create a electro-magnetic field, and thus an AC current is induced at the stator and extracted by the substantial order-∞ resonant tank. By this way, when the applied mechanical force varies, the substantial order-∞ resonant tank can absorbs the transient current. Consequently, thermo-shock extinguishes directly and the efficiency of electrical power generation will be significant increased.

15 Non-Contact Anti-Crash Transport Device

How to avoid the uncontrolled crash of a device providing vertical transportation (such as an elevator or a lift) due to the event of a breach of the cable pulling up and down the device is a vital concern of designing such device. According to the present invention, a non-contact anti-crash transporting device is provided. This non-contact anti-crash transporting device comprises a frame (for providing vertical transportation of people or goods, such as a cage, a car or a platform), a first coil arranged vertically parallel to the frame without any physical contact, a second coil attached to the frame, a cable connected to the frame, a detector for detecting an event of a breach of the cable and for providing a signal indicating the event, a controller for providing power to the first coil in response to the signal, and a substantial order-∞ resonant tank according to the present invention connected in series to the second coil. Therefore, when the event of a breach of the cable is detected, an DC current will pass the first coil to form an electromagnet (due to the moving (falling) of the frame), and thus an AC current is induced at the second coil and extracted by the substantial order-∞ resonant tank. The induced AC current will cause a magnetic field that opposes against that of the electromagnet, and thus the falling speed of the frame is decelerated; as a result, the frame will not crash. The anti-crash force comes from the magnetic reluctance between the first and second coils.

Moreover, the provided non-contact anti-crash transporting device may further comprise a AC-to-DC converter to receive the power extracted by the substantial order-∞ resonant tank, convert the received power to be DC power and provide to any electric power storage device (such as a battery or a capacitor).

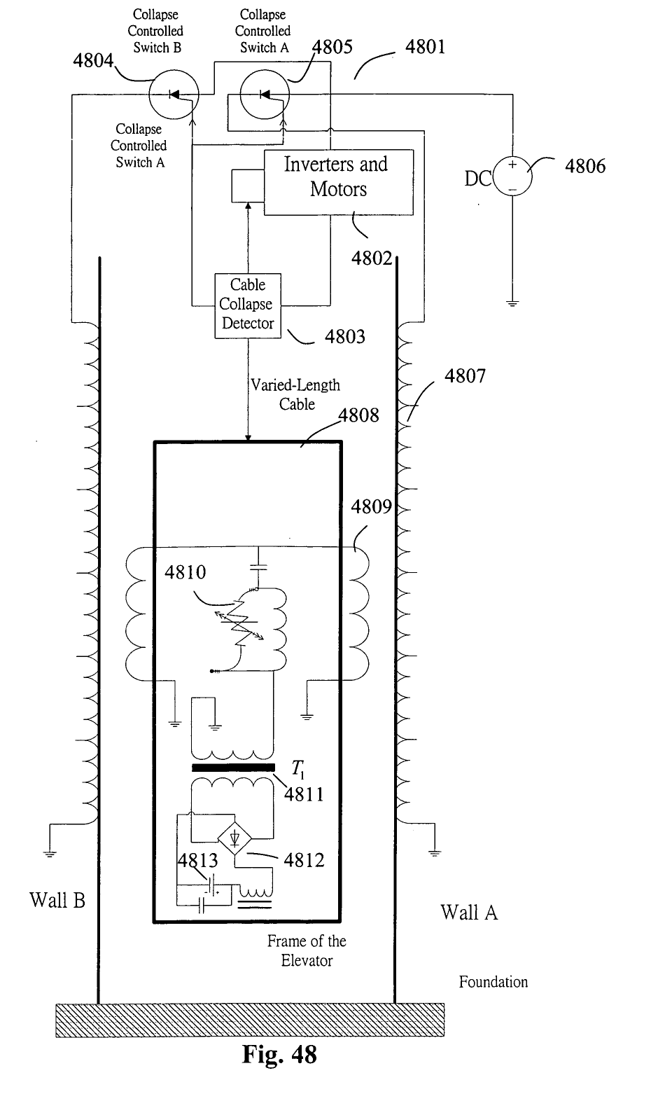

FIG. 48 shows an embodiment of an elevator that is a non-contact anti-crash transporting device according to the present invention. The elevator 4801 is driven and controlled by the inverters and motors 4802. When cable collapse detector 4803 provides a cable-collapse signal to collapse-controlled switches 4804 and 4805 for indicating the even of a breach of the cable, the collapse-controlled switches 4804 and 4805 will be turned on. Consequently, DC current (from the DC source 4806) will pass coil 4807 arranged on the wall vertically parallel to the frame 4808, and thus results in a magnetic flux. Therefore, an AC current is induced at coil 4809 attached to the frame 4808 and extracted by the order-∞ resonant tank 4810. Finally, the isolated transformer T₁ 4811 regenerates an AC power from the power extracted by the order-∞ resonant tank 4810 and passes the regenerated AC power to a rectifier 4812 to rectify the regenerated AC power to be DC power. And the DC power is provided to an electric energy device 4813.

16 Hybrid Electric Vehicle and Electric Vehicle

Electric vehicles (EV), of which the propulsion simply comes from electric energy, and hybrid-electric vehicles (HEV), of which the propulsion comes from electric energy and one or some other propulsion systems (e.g., gasoline), are better in the viewpoint of environmental protection than conventional gasoline-powered vehicles. Daimler-Benz has developed a series of Polymer Electrolyte Fuel Cell (PEFC) vehicles (see [47]), and Toyota and Honda also have developed similar vehicles (FCHV and FCX, respectively). However, nowadays, EV and HEV are generally heavier and tend to be out of power (need to recharge and thus can only be capable of running in a short distance) due to the low efficiency in using the electric energy.

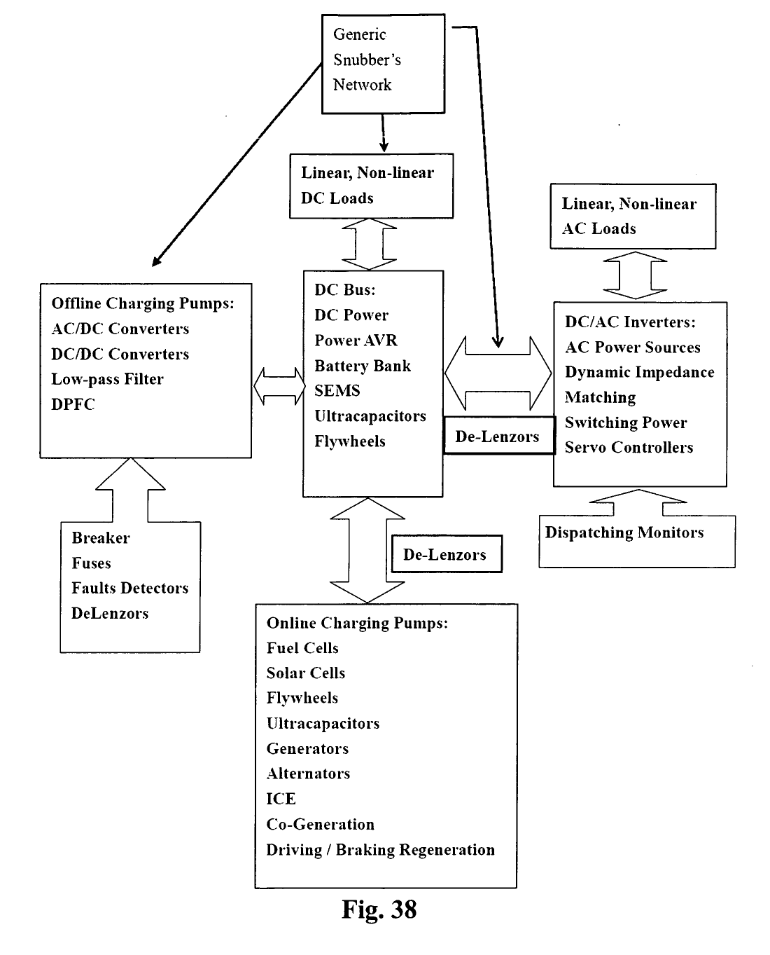

Electric vehicles and hybrid-electric vehicles with better performance by utilizing the regenerated and recycled electric power are provided according to present invention. FIG. 38 shows the power sources and related concepts that may be integrated into the EV and HEV. When the vehicle (EV or HEV) is idle (or parked), an offline charging system can recharge the power level of an internal electric energy storage device. When the vehicle is running, the vehicle may use electric energy either from its original power source (e.g. an internal electric energy storage device) and other available power resource (such as the regenerated power from the braking system or the regenerated power from an internal power converting apparatus). For example, if the vehicle comprises the regenerative ABS system according to the present invention, the regenerated power comes from the braking operation of the vehicle can be used as one of the power resources (by using the regenerated power directly or charging it to an internal electric energy storage device). Another example is that, if the vehicle comprises a power converting apparatus with power recycling ability according to the present invention (such as the inverter shown in FIG. 24), the recycled power comes from the power converting apparatus is another available power resource for the vehicle. By this way, the proposed EV and HEV may use not only the original power source but also other available recycled or regenerated electric power, and thus the proposed EV and HEV have the ability of running in a longer distance than conventional ones.

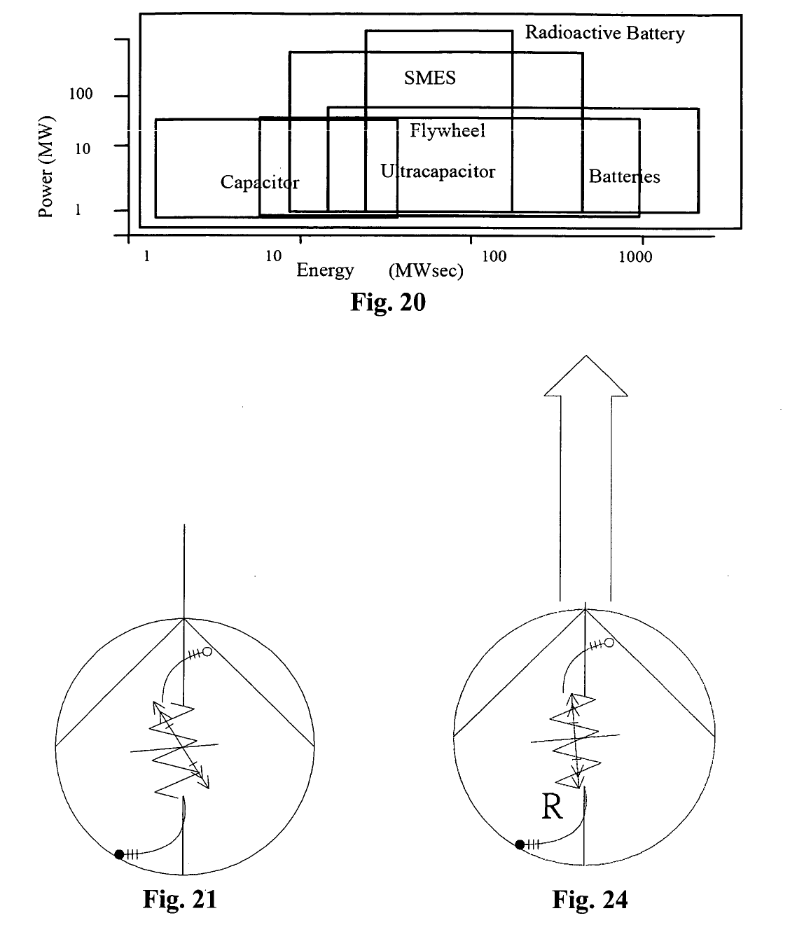

Moreover, nowadays, there are many electric energy storage devices (such as batteries, flywheels, SMES (Superconducting Magnetic Energy Storage), and ultracapacitors). According to FIG. 20 (which shows some electric energy storage devices with their respective energy densities) and the following table (which shows a comparison list of some electric energy storage devices, from the website of Electricity Storage Association: http://www.electrictystorage.org), the radioactive battery provides the most effective energy density and high power output. Therefore, the radioactive battery is suitable for using in an EV or a HEV. Especially, if the radioactive battery is a nuclear power converting apparatus according to the present invention, the performance of the proposed EV and HEV would be further improved.

| Storage Devices | Advangages | Disadvantage | Power | Energy |
|---|---|---|---|---|
| NaS | Density & Efficiency↑ | ↑Cost, Safety | good | good |
| Li-ion | Density & Efficiency↑ | ↑Cost, Charging | good | no |
| NiCd | Density & Efficiency↑ | Charging Circuit | good | ok |
| Flywheel | High Power | ↓ Density | good | ok |
| Radioactive Battery | Density & Efficiency ↑, Life↑ | RF-Energy Safety | Best | Best |
| Ultracapacitor | Efficiency↑, Life↑ | ↓ Density | good | ok |
| SEMS, DSMES | High Power | Density↓, Cost↑ | good | ok |
| Metal-Air Battery | Very High Density | Charging Difficult | no | good |
| Fuel Cell | Good Performance | Fuel Requirement | ok | good |
| Lead-Acid Battery | Low Cost | Life Cycle Limited | good | no |
| Flow Batteries | High Capacity | Low Density | ok | good |
| Pumped Storage | ↑Capacity, ↓Cost | Too Large & Heavy | no | good |
| Solar Cell | Without Pollution | Cost↑, ↓Reliability | no | no |
| CAES | ↑Capacity, ↓Cost | Fuel Requirement | ok | good |

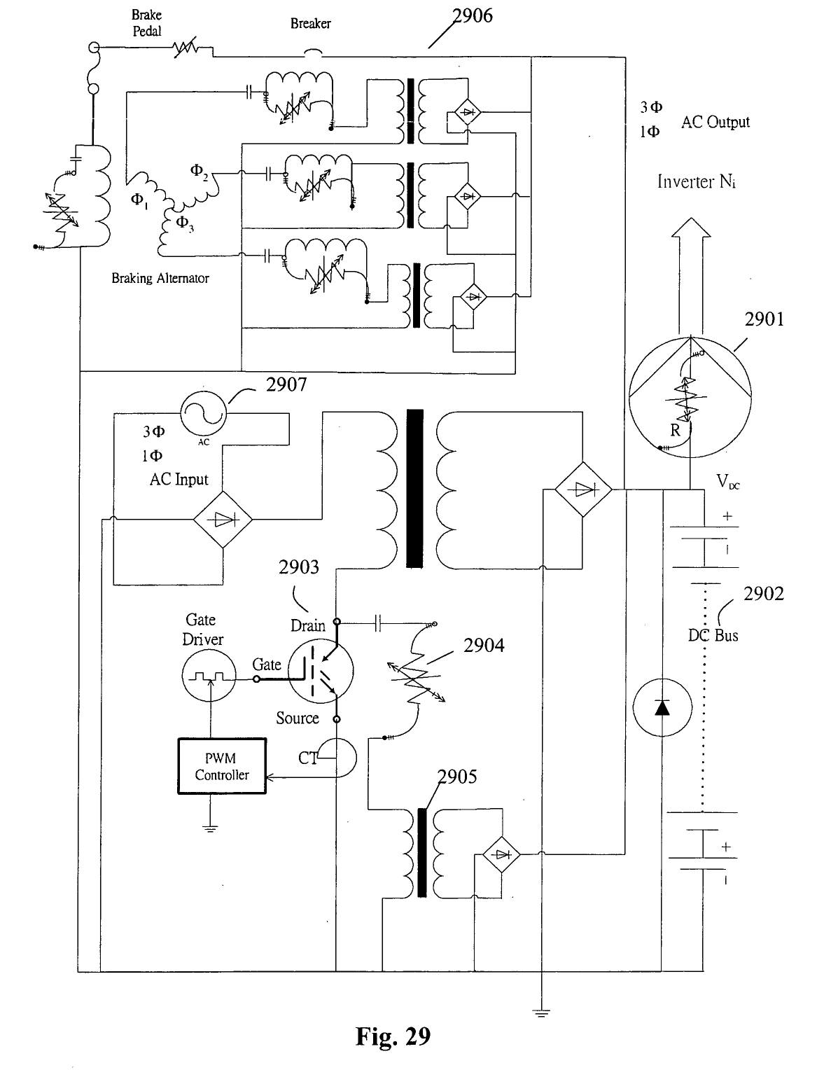

FIG. 29 illustrates an embodiment of proposed vehicle (EV or HEV). The inverter 2901 provides power to the driving motor, regenerates power (from the induced current due to the inductance of the driving motor), coverts the regenerated power to be DC power, and provides the DC power back to DC bus 2902. The AC-to-DC power converting apparatus 2903 with an order-∞ resonant tank 2904 according to the present invention not only converters AC power from the AC power source 2907 to be suitable for providing to the DC bus 2902, but also returns the recycled power (by AC-to-DC converter 2905) to the DC bus 2902. Moreover, the regenerative ABS 2906 can also provide regenerated power to DC bus 2902 during the braking operation. Therefore, the proposed vehicle can use not only the original power source but also other available recycled or regenerated electric power.

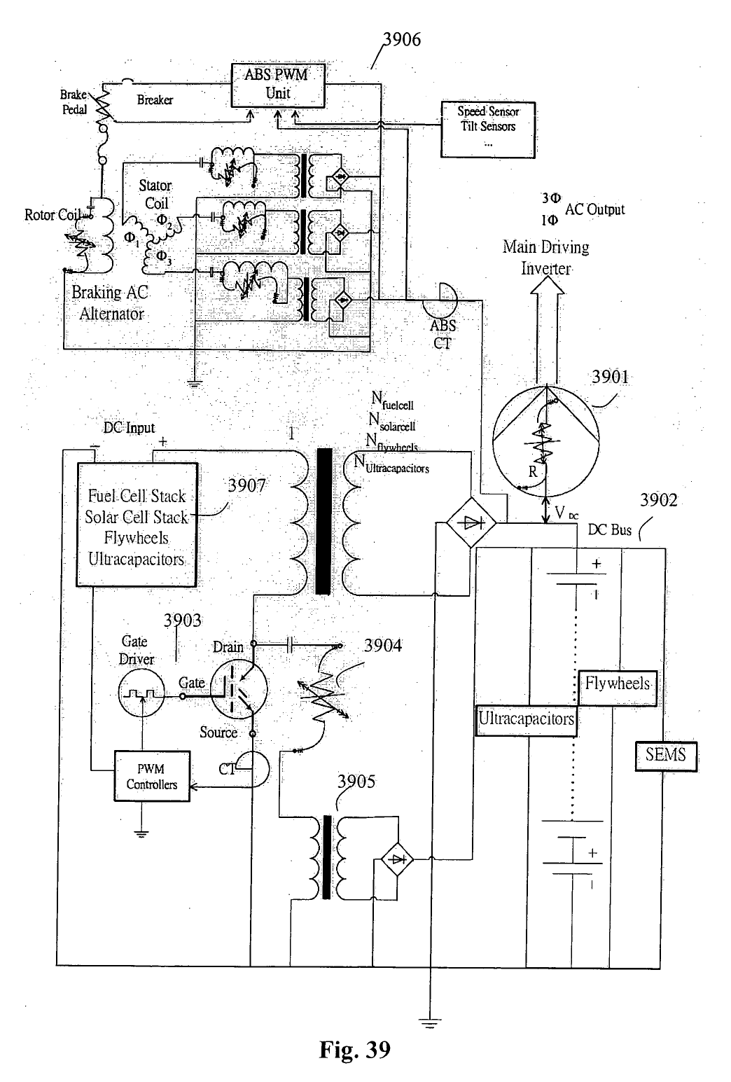

FIG. 39 is another embodiment of the proposed vehicle (EV or HEV). The inverter 3901 provides power to the driving motor, regenerates power (from the induced current due to the inductance of the driving motor), coverts the regenerated power to be DC power, and provides the DC power back to DC bus 3902. The DC-to-DC power converting apparatus 3903 with an order-∞ resonant tank 3904 according to the present invention not only converters the DC power from the DC power source 3907 to be suitable for providing to the DC bus 3902, but also returns the recycled power (by AC-to-DC converter 3905) to the DC bus 3902. Moreover, the regenerative ABS 3906 can also provide regenerated power to DC bus 3902 during the braking operation. Therefore, the proposed vehicle can use not only the original power source but also other available recycled or regenerated electric power. Note that the DC power source 3907 and the DC bus 3902 can comprise one or more energy storage devices such as flywheels, SEMS, fuel cells, solar cells and batteries.

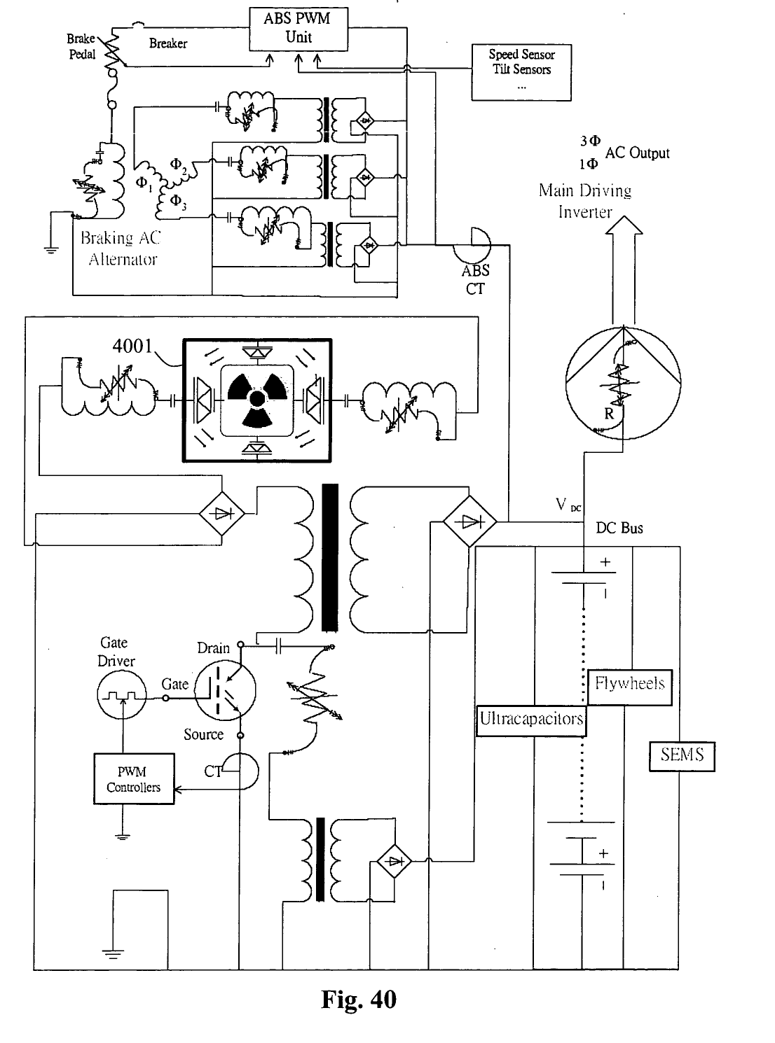

FIG. 40 illustrates another embodiment of the proposed vehicle (EV or HEV), wherein the DC power source 4001 is a nuclear power converting apparatus according to the present invention.

### List of Reference Numerals

101 Resistor
102 Inductor
103 Capacitor
201 Resistor
202 Inductor
203 Capacitor
301 Closed phase orbit
401 IGBT₁ (Integrated Gate Bipolar Transistor)
402 IGBT₄
403 Point R
404 Point S
405 Point T
406 Coil Φ₁
407 Coil Φ₂
408 Coil Φ₃
409 Dissipative diode D₁
410 IGBT₃
411 IGBT₆
501 Switch
502 AC/DC Converter/Charger
503 AC power source
504 Inverter
601 Switch
602 AC/DC Converter/Charger
603 AC power source
604 Inverter
701 Switch
702 AC/DC Converter/Charger
703 AC power source
704 Inverter
801 Spring
802 Mass
803 Variable resistor
1001 Capacitor Cₛ
1002 Capacitor Cₚ
1003 Resistor Rₛ
1004 Resistor Rₚ
1601 Power transistor
1602 Pulse-Width Modulation (PWM) controller
1603 Inductive element
1604 Capacitor
1605 Snubber network
1606 Spectral resistor
1801 Silicon Controlled Rectifier (SCR)
1802 Silicon Controlled Rectifier (SCR)
1803 Silicon Controlled Rectifier (SCR)
1804 Silicon Controlled Rectifier (SCR)
1805 Silicon Controlled Rectifier (SCR)
1806 Silicon Controlled Rectifier (SCR)
1807 Pulse-Width Modulation (PWM) controller
1808 DC bus
1809 Battery packs
1810 Full-bridge IGBT-base inverter
1811 Order-∞ resonant tank
1812 Transformer
1813 Schottky diode (functioned as an AC-to-DC converter)
1814 Inductor
1901 AC-to-DC converter
1902 Pulse-Width Modulation (PWM) controller
1903 DC bus
2201 Full-bridge IGBT-base inverter
2202 DeLenzor
2203 IGBT
2601 Silicon Controlled Rectifier (SCR)
2602 Silicon Controlled Rectifier (SCR)
2603 Silicon Controlled Rectifier (SCR)
2604 Silicon Controlled Rectifier (SCR)
2605 Silicon Controlled Rectifier (SCR)
2606 Silicon Controlled Rectifier (SCR)
2607 Pulse-Width Modulation (PWM) controller
2608 Sensor
2609 DC bus
2610 Order-∞ resonant tank
2611 Order-∞ resonant tank
2612 IGBT
2701 Dynamic damper
2702 Transformer
2703 Inductive element
2704 Switching element
2705 Schottkey diode
2801 Rotor
2802 Pulse-Width Modulation (PWM) controller
2803 Brake pedal
2804 Stator
2805 Order-∞ resonant tank
2806 Order-∞ resonant tank
2807 Order-∞ resonant tank
2808 Transformer T₁
2809 Transformer T₂
2810 Transformer T₃
2811 Schottkey diode
2812 Schottkey diode
2813 Schottkey diode
2814 Order-∞ resonant tank
2815 Inductor L₁
2816 Inductor L₂
2817 Inductor L₃
2818 DC bus
2901 Inverter
2902 DC bus
2903 AC-to-DC power converting apparatus
2904 Order-∞ resonant tank
2905 AC-to-DC converter
2906 Regenerative ABS (Anti-skid Braking System)
2907 AC power source
3101 Phase detector
3102 Low pass filter
3103 Voltage Controlled Oscillator
3301 Spectral resistor
2501 Surface current
3502 Surface
3601 First plate
3601 Second plate
3701 Nuclear material
3702 Container
3703 Dynamic impedance matching circuit
3704 Dynamic impedance matching circuit
3705 Schottky diode
3901 Inverter
3902 DC bus
3903 DC-to-DC power converting apparatus
3904 Order-∞ resonant tank
3905 AC-to-DC converter
3906 Regenerative ABS (Anti-skid Braking System)
3907 DC power source
4201 Converter with DPFC (Dynamic Power Factor Corrector)
4202 Inverter
4501 Inverter
4502 Audio signal input
4503 Speakers
4504 DeLenzor
4505 Switching-mode power converter
4506 Dynamic damper
4701 Load₁
4702 Load₂
4703 Load₃
4704 New load
4801 Elevator
4802 Inverters and motors
4803 Cable collapse detector
4804 Collapse-controlledcable-collapse switch
4805 Collapse-controlledcable-collapse switch
4806 DC source
4807 Coil
4808 Frame
4809 Coil
4810 Order-∞ resonant tank
4811 Isolated transformer
4812 Rectifier
4813 Electric energy device
4901 Accelerometer
4901 Order-∞ resonant tank
4903 Isolated transformer
4904 Purified AC signal

### Appendix

A Kalman Filtering Algorithm

Referring to [7] and page 42 of [31], some basic formula in estimation theory are reviewed. As the following descriptions, in the conditional mean framework for the normal jointly probability distribution, let a vector-valued Gaussian random variable has the density

$$N ( x ; \overline{x} , P ) = \frac{1}{\sqrt{2 π det ( P )}} {ⅇ}^{- \frac{1}{2} {( x - \overline{x} )}^{t} {P}^{- 1} ( x - \overline{x} )}$$

where P is the covariance matrix and x is its mean value. Two vectors x and z are jointly Gaussian if the stacked vector

$$y = [ \begin{matrix}x \\ z\end{matrix} ]$$

is Gaussian.
p(x,z)=p(y)=N(y; y̅,P_{yy})
where the mean is

$$\overline{y} = [ \begin{matrix}\overline{x} \\ \overline{z}\end{matrix} ]$$

and covariance matrix is

$${P}_{yy} = [ \begin{matrix}{P}_{xx} & {P}_{xz} \\ {P}_{zx} & {P}_{zz}\end{matrix} ]$$

$$where$$

$${P}_{xx} = E ⌊ ( x - \overline{x} ) {( x - \overline{x} )}^{t} ⌋$$

$${P}_{xz} = E [ ( x - \overline{x} ) {( z - \overline{z} )}^{t} ] \\ = {P}_{zx}$$

$${P}_{zz} = E [ ( z - \overline{z} ) {( z - \overline{z} )}^{t} ]$$

The conditional pdf of x given z is

$$p ( x \vert z ) = \frac{p ( x , z )}{p ( z )}$$

Let the new variables are shifted to mean zero

$$ζ = x - \overline{x}$$

$$η = z - \overline{z}$$

$$and$$

$$p ( x \vert z ) = \frac{p ( x , z )}{p ( z )} \\ = \frac{{[ 2 π det ( {P}_{yy} ) ]}^{- \frac{1}{2}} {ⅇ}^{- \frac{1}{2} ( y - \overline{y} ) {P}_{yy}^{- 1} ( y - \overline{y} )}}{{[ 2 π det ( {P}_{zz} ) ]}^{\frac{- 1}{2}} {ⅇ}^{- \frac{1}{2} {( z - \overline{z} )}^{t} {P}_{zz}^{- 1} ( z - \overline{z} )}}$$

then the Gaussian densities in the exponent becomes the quadratic form

$$q = {{[ \begin{matrix}ζ \\ η\end{matrix} ]}^{t} [ \begin{matrix}{P}_{xx} & {P}_{xz} \\ {P}_{zx} & {P}_{zz}\end{matrix} ]}^{- 1} [ \begin{matrix}ζ \\ η\end{matrix} ] - {η}^{t} {P}_{zz}^{- 1} η \\ = {[ \begin{matrix}ζ \\ η\end{matrix} ]}^{t} [ \begin{matrix}{T}_{xx} & {T}_{xz} \\ {T}_{zx} & {T}_{zz}\end{matrix} ] [ \begin{matrix}ζ \\ η\end{matrix} ] - {η}^{t} {P}_{zz}^{- 1} η$$

Recall the inversion of partitioned n×n matrix is, see the contexts disclosed in [61, page 560] and [7, page 295],

$${[ \begin{matrix}A & B \\ C & D\end{matrix} ]}^{- 1} = [ \begin{matrix}E & F \\ G & J\end{matrix} ]$$

$$where$$

$$E = {( A - {BD}^{- 1} C )}^{- 1} = {A}^{- 1} + {A}^{- 1} {BJCA}^{- 1}$$

$$F = - {A}^{- 1} BJ = - {EBD}^{- 1}$$

$$G = - {JCA}^{- 1} = - {D}^{- 1} CE$$

$$J = {( D - {CA}^{- 1} B )}^{- 1} = {D}^{- 1} + {D}^{- 1} {CEBD}^{- 1} .$$

The simplest proof is to multiply matrices and obtain I. Multiply the row [A B] by CA⁻¹ and substrate from the [C D]:

$$[ \begin{matrix}I & 0 \\ - {CA}^{- 1} & I\end{matrix} ] [ \begin{matrix}A & B \\ C & D\end{matrix} ] = [ \begin{matrix}A & B \\ 0 & D - {CA}^{- 1} B\end{matrix} ]$$

Similarly, multiply the row [C D] by BD⁻¹ and substrate from the [A B]:

$$[ \begin{matrix}I & - {BD}^{- 1} \\ 0 & I\end{matrix} ] [ \begin{matrix}A & B \\ C & D\end{matrix} ] = [ \begin{matrix}A - {BD}^{- 1} C & 0 \\ C & D\end{matrix} ] .$$

Inverting the right-hand side matrices yields different formulas for the block matrix E. Now we pay attention to the (1,1) component, they become

$$\begin{matrix}E = {( A - {BD}^{- 1} C )}^{- 1} \\ = {A}^{- 1} + {A}^{- 1} {BJCA}^{- 1} .\end{matrix}$$

and (2,2) component is

$$\begin{matrix}J = {( D - {CA}^{- 1} B )}^{- 1} \\ = {D}^{- 1} + {D}^{- 1} {CEBD}^{- 1} .\end{matrix}$$

We substitute the matrix J into E, then
(A−BD⁻¹C)⁻¹=A⁻¹+A⁻¹B(D−CA⁻¹B)⁻¹CA⁻¹
The matrix inversion lemma as disclosed in [61, page 560] and [7, page 295].
The block matrices are
Tₓₓ⁻¹=Pₓₓ−P_{xz}P_{zz}⁻¹P_{zx}
P_{zz}⁻¹=T_{zz}−T_{zx}Tₓₓ⁻¹T_{xz}
Tₓₓ⁻¹T_{xz}=−P_{xz}P_{zz}⁻¹.

The q can be as

$$\begin{matrix}q = {ζ}^{t} {T}_{xx } ζ + {ζ}^{′} {T}_{xz} η + {η}^{t} {T}_{zx} ζ + {η}^{t} {T}_{zz} η - {η}^{t} {P}_{zz}^{- 1} η \\ = {( ζ + {T}_{xx}^{- 1} {T}_{xz} η )}^{t} {T}_{xx} ( ζ + {T}_{xx}^{- 1} {T}_{xz } η ) + {η}^{t} ( {T}_{zz} - {T}_{zx} {T}_{xx}^{- 1} {T}_{xz} ) η - {η}^{t} {P}_{zz}^{- 1} η \\ = {( ζ + {T}_{xx}^{- 1} {T}_{xz} η )}^{t} {T}_{xx} ( ζ + {T}_{xx}^{- 1} {T}_{xz} η ) .\end{matrix}$$

Substitute the P_{xz} and P_{zz}⁻¹ into the ζ+Tₓₓ⁻¹T_{xz}η then
ζ+Tₓₓ⁻¹T_{xz}η=x− x̅−P_{xz}P_{zz}⁻¹(z− z̅)

The conditional mean of x given z is defined as
E[x|z]=\hat{x}= x̅+P_{xz}P_{zz}⁻¹(z− z̅) (63)

The corresponding conditional covariance is

$$\begin{matrix}cov ( x \vert z ) = {P}_{xx \vert z} \\ = {T}_{xx}^{- 1} \\ = {P}_{xx} - {P}_{xz} {P}_{zz}^{- 1} {P}_{zx}\end{matrix} \qquad ( 64 )$$

If x and z are random variables but not the Gaussian, the conditional mean is very difficult to obtain. In particular, the linear case can be derived as the following: let \hat{x}=Az+b such that the mean-square error J is minimized as
minJ=minE[(x−\hat{x})^{t}(x−\hat{x})].

The best linear MMSE estimated error
\tilde{x}=x−\hat{x}
is zero and orthogonal to the observation z. The unbiased requirement is
E[\tilde{x}]= x̅−(Az+b)=0
b= x̅−Az.

The estimation error \tilde{x} is
\tilde{x}=x−\hat{x}=x− x̅−A(z− z̅).
and

$$\begin{matrix}0 = E [ \tilde{x} {z}^{t} ] \\ = E [ ( x - \overline{x} - A ( z - \overline{z} ) ) {z}^{t} ] \\ = {P}_{xz} - {AP}_{zz}\end{matrix}$$

i.e.,
A=P_{xz}P_{zz}⁻¹
such that the best linear MMSE estimator of \hat{x} obtained as
\hat{x}= x̅+P_{xz}P_{zz}⁻¹(z− z̅)
The MSE error matrix is given by

$$\begin{matrix}E [ \tilde{x} {\tilde{x}}^{t} ] = E [ ( x - \overline{x} - {P}_{xz} {P}_{zz}^{- 1} ( z - \overline{z} ) ) {( x - \overline{x} - {P}_{xz} {P}_{zz}^{- 1} ( z - \overline{z} ) )}^{t} ] \\ = {P}_{xx} - {P}_{xz} {P}_{zz}^{- 1} {P}_{zx} \\ = {P}_{xx \vert z}\end{matrix}$$

Let x, z be random vectors, from the observation Z on z, it is desired to estimate x. The MMSE (Minimum mean-square error) estimator is defined to be

$${\hat{x}}^{MMSE} = {min}_{arg ( \hat{x} )} E [ {( \hat{x} - x )}^{2} \vert Z ]$$

It can be shown that the solution of the previous minimization problem is
\hat{x}^{MMSE}=E[x|Z] (65)

Furthermore, if x, z are jointly Gaussian with covariance matrices denoted by

$$\begin{matrix}{P}_{xx} = E [ ( x - \overline{x} ) {( x - \overline{x} )}^{′} ] \\ {P}_{xz} = E [ ( x - \overline{x} ) {( z - \overline{z} )}^{′} ] \\ = {P}_{zx}^{′} \\ {P}_{zz} = E [ ( z - \overline{z} ) {( z - \overline{z} )}^{′} ]\end{matrix} \qquad ( 66 )$$

where x̅, z̅ are the mean vectors of x, z respectively, the conditional mean can be further expressed as
E[x|Z]= x̅+P_{xz}P_{zz}⁻¹(z− z̅) (67)

The associated conditional variance is
P_{xx|z}=Pₓₓ−P_{xz}P_{zz}⁻¹P_{zx} (68)

Accordingly, the MMSE estimate as shown in equation (65) can be found as
\hat{x}= x̅+P_{xz}P_{zz}⁻¹(Z− z̅) (69)
and the corresponding covariance matrix is computed through equation (68). On the other hand, by the least-square type argument, the estimator in equation (69) can be also obtained for the estimation of Non-Gaussian random vectors.

Consider a linear system
x(k+1)=Φ(k)x(k)+u(k+1) (70)
with measurement
z(k)=H(k)x(k)+w(k) (71)
where the process noise u(k+1) and the measurement noise w(k) are assumed to be independent with Gaussian distributions N(0,Q(k)) and N(0,R(k)), respectively. The problem is to estimate \hat{x}(k+1), given measurement
Z^{k}={z(1), z(2), . . . , z(k)}

A recursive process, termed the Kalman filter, was developed to perform the estimation, and the process can be divided into two parts. One is to predict the state at k+1 from the observations through k. Next is to correct the prediction by current measurement at k. The predictions of both the states and measurement based on Z^{k} can be obtained from the MMSE estimator as
\hat{x}(k+1|k)=E[x(k+1)|Z^{k}]
\hat{z}(k+1|k)=E[z(k)|Z^{k}]

Regarding the above equations as the means of x, z respectively. The correction step based on the observation z(k) is then performed through equation (69),
\hat{x}(k+1|k+1)=\hat{x}(k+1|k)+P_{xz}(k+1|k)P_{zz}⁻¹(k+1|k)(z(k)−\hat{z}(k+1|k)) (72)
and
Pₓₓ(k+1|k+1)=Pₓₓ(k+1|k)−P_{xz}(k+1|k)P_{zz}⁻¹(k+1|k)P_{zx}(k+1|k) (73)
where the conditional covariance matrices, P_{xz} and P_{zz} are defined similar to equation (66), denoted as
\tilde{x}(k+1|k)=x(k+1)−\hat{x}(k+1|k)
and
ν(k)=z(k+1)−\hat{z}(k+1|k)
, then the elements of covariance are
Pₓₓ(k+1|k)=E[\tilde{x}(k+1|k)\tilde{x}(k+1|k)′|Z^{k}]
P_{xz}(k+1|k)=E[\tilde{x}(k+1|k)\tilde{z}(k+1|k)′|Z^{k}]
and
P_{zz}(k+1|k)=E[\tilde{z}(k+1|k)\tilde{z}(k+1|k)′|Z^{k}]

From the dynamic equations (70) and (71), the prediction \hat{x}(k+1|k) can be further expressed in terms of \hat{x}(k|k) as
\hat{x}(k+1|k)=Φ(k)\hat{x}(k|k)

The corresponding update rule for the covariance matrix is

$${P}_{xx} ( k + 1 \vert k ) = Φ ( k ) {P}_{xx} ( k \vert k ) {Φ}^{′} ( k ) + Q ( k )$$

The gain in equation (72) is called the Kalman gain
K(k)=P_{xz}(k+1|k)P_{zz}⁻¹(k+1|k)

The covariance of the innovation ν(k) can be computed as

$$\begin{matrix}B ( k ) = {P}_{zz} ( k + 1 \vert k ) \\ = H ( k ) {P}_{xx} ( k + 1 \vert k ) {H}^{′} ( k ) + R ( k )\end{matrix}$$

The Kalman filtering algorithm can be summarized as, from \hat{x}(k|k), Pₓₓ(k|k)
\hat{x}(k+1|k)=Φ(k)\hat{x}(k|k)
\hat{z}(k+1|k)=H(k)\hat{x}(k+1|k)
Pₓₓ(k+1|k)=Φ(k)Pₓₓ(k|k)Φ′(k)+Q(k)
B(k)=H(k)Pₓₓ(k+1|k)H′(k)+R(k) (74)
K(k)=Pₓₓ(k+1|k)H′(k)B⁻¹(k) (75)
ν(k)=z(k)−\hat{z}(k+1|k) (76)

Based on the conditional mean definition as shown in equation (63), the state has been updated by innovation shown in equation (76) and the filter gain shown in equation (75)
\hat{x}(k+1|k+1)=\hat{x}(k+1|k)+K(k)ν(k)
and its corresponding covariance as shown in equation (64) is
Pₓₓ(k+1|k+1)=Pₓₓ(k+1|k)−K(k)B(k)K′(k).
A.1 Confidence Interval for Variance of a Normal Distribution

From [57], if x₁, . . . , xₙ is a sample from the normal distribution having unknown parameters μ and σ², then we can construct a confidence interval for σ² by using the fact that

$$\begin{matrix}( n - 1 ) \frac{{S}^{2}}{{σ}^{2}} \sim {χ}_{n - 1}^{2} \\ Also , \\ ( n - 1 ) {S}^{2} = {nS}_{n}^{2} \\ i . e . , \\ n \frac{{S}_{n}^{2}}{{σ}^{2}} \sim {χ}_{n - 1}^{2} \\ Hence \\ P \{ {χ}_{\frac{α}{2} , n - 1}^{2} \leq ( n - 1 ) \frac{{S}^{2}}{{σ}^{2}} \leq {χ}_{( 1 - \frac{α}{2} ) , n - 1}^{2} \} = 1 - α \\ or \\ P \{ \frac{( n - 1 ) {S}^{2}}{{χ}_{\frac{α}{2} , n - 1}^{2}} \leq {σ}^{2} \leq \frac{( n - 1 ) {S}^{2}}{{χ}_{( 1 - \frac{α}{2} ) , n - 1}^{2}} \} = 1 - α\end{matrix} \qquad ( 77 )$$

that is, when the S²=s², a 100(1−α) percent confidence interval for σ² is

$${σ}^{2} ∈ \{ \frac{( n - 1 ) {S}^{2}}{{χ}_{\frac{α}{2} , n - 1}^{2}} , \frac{( n - 1 ) {S}^{2}}{{χ}_{( 1 - \frac{α}{2} ) , n - 1}^{2}} \}$$

A.2 t-Distribution

Let Z and χₙ² the random variables, with Z having a standard normal distribution and χₙ² having chi-square distribution with n degrees of freedom, then the random variable Tₙ defined by

$${T}_{n} = \frac{Z}{\sqrt{\frac{{χ}_{n}^{2}}{n}}} \qquad ( 78 )$$

is said to have a t-distribution with n degrees of freedom. Its probability density function is

$$p ( x ) = \frac{1}{\sqrt{n π}} \frac{Γ ( \frac{1}{2} n + \frac{1}{2} )}{Γ ( \frac{n}{2} )} {( 1 + \frac{{x}^{2}}{n} )}^{\frac{- 1}{2} ( n + 1 )}$$

The mean and variance of Tₙ can be shown to equal

$$\{ \begin{matrix}E [ {T}_{n} ] = 0 , n > 1 \\ Var [ {T}_{n} ] = \frac{n}{n - 2} , n > 2\end{matrix}$$

—A.3 Prediction Error Decomposition Form

For a Gaussian model, as disclosed in [26] (referring to equation (74)), therefore the logarithm likelihood function can be written as

$$log L = - \frac{NT}{2} log ( 2 π ) - \frac{1}{2} {\sum }_{k = 1}^{M} log \vert B ( k ) \vert - \frac{1}{2} {\sum }_{k = 1}^{M} {v}_{i}^{′} ( k ) {B}^{- 1} ( k ) {v}_{i} ( k ) \qquad ( 79 )$$

where the innovation term νᵢ(k) can be interpreted as the prediction error at the k^{th} step and there are i states. Sometimes, it is called prediction error decomposition form.
A.4 Bayesian Forcasting

Referring to [71] and page 363 of [2], the state vector at time t summarizes the information from the past that is necessary to predict the future. Therefore, before forecasts of future observations can be calculated, it is necessary to make inferences about the state vector Sₜ. In the context of Bayesian forecasting, the general linear model in terms of the unknown states Sₜ is
Sₜ₊₁=ΦSₜ+aₜ₊₁
yₜ=HₜSₜ+εₜ

Since the unknown coefficients Sₜ themselves vary over time, they refer to this model as the dynamic linear model. The objective of Bayesian forecasting is to derive the predictive distribution of a future observation
yₜ₊ₗ=Hₜ₊ₗSₜ₊ₗ+εₜ₊₁

For this, we have to make inference about the future states Sₜ₊ₗ and the independent variables Hₜ₊ₗ, the i-step-ahead forecasting of yₜ is given by

$$\begin{matrix}{\hat{y}}_{t + 1} = E [ {y}_{t + l} \vert Y ] \\ = {H}_{t + l} {\hat{S}}_{t + l} \\ = {H}_{t + l} {Φ}^{l} {\hat{S}}_{t}\end{matrix} \qquad ( 80 )$$

and its covariance matrix by

$$\begin{matrix}V ( {y}_{t + l} \vert {Y}_{t} ) = {H}_{t + l} ( {\hat{β}}_{t + l} ) {H}_{t + l}^{′} + {R}_{t} \\ = {H}_{t + 1} [ {Φ}^{l} {{P}_{t} ( {Φ}^{t} )}^{l} + {\sum }_{j = 0}^{l - 1} \sum {Φ}^{j} {{Q}_{j} ( {Φ}^{′} )}^{j} ] {H}_{t + l}^{′} + {R}_{t}\end{matrix}$$

where the covariance matrices Qₜ, Rₜ are
εₜ˜N(0, Rₜ)
and
aₜ˜N(0,Qₜ).
B Distributed Kalman Filtering Algorithms
B.1 Independent Tracks

Consider the local information measurements are independent case. Let \hat{x}₁ and \hat{x}₂ be two estimates of x with independent Gaussian errors of covariance P₁ and P₂, respectively. Then the combined information is
\hat{x}_{c}=[P₁⁻¹+P₂⁻¹]⁻¹[P₁⁻¹\hat{x}₁+P₂⁻¹\hat{x}₂].
And the resulting fused estimate will have an error covariance as disclosed in [11, Bayesian Inference]
P_{C}=[P₁⁻¹+P₂⁻¹]⁻¹.

Let the first estimate be the prior information and the second estimate be an information measurement, and search the posterior distribution of the parameters given all data. i.e. Given the first estimate, the distribution of the parameters is
x|\hat{x}₁=\hat{x}₁+\tilde{x}₁˜N(\hat{x}₁, P₁)
where N(μ, P) indicates a Gaussian distribution with μ and error covariance P. The second estimate \hat{x}₂=x−\tilde{x}₂=\hat{x}₁+\tilde{x}₁−\tilde{x}₂, joint two estimates together as

$$[ \begin{matrix}x \vert {\hat{x}}_{1} \\ {\hat{x}}_{2}\end{matrix} ] \sim N ( [ \begin{matrix}{{\hat{x}}^{}}_{1} \\ {\hat{x}}_{1}\end{matrix} ] , [ \begin{matrix}{P}_{1} & {P}_{1} \\ {P}_{1} & {P}_{1} + {P}_{2}\end{matrix} ] ) .$$

Applying the Kalman filtering to this system, obtain the gain is

$${K}_{C} = {[ {P}_{1}^{- 1} + {P}_{2}^{- 1} ]}^{- 1} {P}_{1}^{- 1}$$

$$and$$

$$x \vert {\hat{x}}_{1} , {\hat{x}}_{2} \sim N ( {\hat{x}}_{1} + {{P}_{1} [ {P}_{1}^{- 1} + {P}_{2}^{- 1} ]}^{- 1} [ {\hat{x}}_{2} - {\hat{x}}_{1} ] , {P}_{1} - {{P}_{1} [ {P}_{1}^{- 1} + {P}_{2}^{- 1} ]}^{- 1} {P}_{1} ) ∼ N ( {[ {P}_{1}^{- 1} + {P}_{2}^{- 1} ]}^{- 1} [ {P}_{2}^{- 1} {\hat{x}}_{2} + {P}_{1}^{- 1} {\hat{x}}_{1} ] , {[ {P}_{1}^{- 1} + {P}_{2}^{- 1} ]}^{- 1} ) .$$

B.1 Dependent Tracks

In general, the fused system covariance matrices are as disclosed in [7, Chap 10.3]

$$[ \begin{matrix}{P}^{i} & {P}^{ij} \\ {P}^{ji} & {P}^{j}\end{matrix} ]$$

where the cross-covariance matrix is
P^{ij}=E└(\tilde{x}ⁱ)(\tilde{x}^{j})^{t}┘,
E└(\tilde{x}ⁱ)(\tilde{x}ⁱ−\tilde{x}^{j})^{t}┘=Pⁱ−P^{ij},
E└(\tilde{x}ⁱ−\tilde{x}^{j})(\tilde{x}ⁱ−\tilde{x}^{j})^{t}┘=Pⁱ+P^{j}−P^{ij}−(P^{ij})^{t}.

Then the fused state estimate
\hat{x}^{ij}=\hat{x}ⁱ+[Pⁱ−P^{ij}][Pⁱ+P^{j}−P^{ij}−(P^{ij})^{t}]⁻¹[\hat{x}^{j}−\hat{x}ⁱ]
and the corresponding covariance is
M^{ij}=Pⁱ−[Pⁱ−P^{ij}][Pⁱ+P^{j}−P^{ij}−(P^{ij})^{t}]⁻¹[Pⁱ−P^{ij}]^{t}.

The dynamics of the target are
x(k+1)=F(k)x(k)+νₖ, νₖ˜N(0, Q).
The measurement equations
z^{m}(k)=H^{m}(k)x(k)+w^{m}(k), m=i, j. and wₖ^{m}˜N(0,R^{m}).

At time k,
\hat{x}^{m}(k|k)=F(k−1)\hat{x}^{m}(k−1|k−1)+W^{m}(k)[z^{m}(k)−H^{m}(k)F(k−1)\hat{x}^{m}(k−1|k−1)]

where W^{m}(k) is the Kalman gain in the information processor m=i,j. The m sensor system estimation error is

$$\begin{matrix}{\tilde{x}}^{m} ( k \vert k ) = x ( k ) - {\hat{x}}^{m} ( k \vert k ) \\ = F ( k - 1 ) x ( k - 1 ) + v ( k - 1 ) - F ( k - 1 ) {\hat{x}}^{m} ( k - 1 ) - \\ {W}^{m} ( k ) [ {H}^{m} F ( k - 1 ) x ( k - 1 ) + v ( k - 1 ) + {w}^{m} ( k ) - \\ {H}^{m} ( k ) F ( k - 1 ) {\hat{x}}^{m} ( k - 1 \vert k - 1 ) ] \\ = [ I - {W}^{m} ( k ) {H}^{m} ( k ) F ( k - 1 ) {\tilde{x}}^{m} ( k - 1 \vert k - 1 ) ] + \\ [ I - {W}^{m} ( k ) {H}^{m} ( k ) ] v ( k - 1 ) - {W}^{m} ( k ) {w}^{m} ( k ) .\end{matrix}$$

The cross-covariance matrix recursion is

$$\begin{matrix}{P}^{ij} ( k \vert k ) = E [ {\tilde{x}}^{i} ( k \vert k ) {{\tilde{x}}^{j} ( k \vert k )}^{′} ] \\ = [ I - {W}^{i} ( k ) {H}^{i} ( k ) ] [ F ( k - 1 ) {P}^{ij} ( k - 1 \vert k - 1 ) {F ( k - 1 )}^{′} + Q ] \\ {[ I - {W}^{j} ( k ) {H}^{j} ( k ) ]}^{′}\end{matrix}$$

and which is a linear recursion with initial condition
P^{ij}(0|0)=0.

The cross-covariance matrix is

$$\begin{matrix}{T}^{ij} ( k \vert k ) = E [ {\tilde{Δ}}^{ij} ( k \vert k ) {{\tilde{Δ}}^{ij} ( k \vert k )}^{′} ] \\ = E [ ( {\tilde{x}}^{i} - {\tilde{x}}^{j} ) {( {\tilde{x}}^{i} - {\tilde{x}}^{j} )}^{′} ] \\ = {P}^{i} ( k \vert k ) + {P}^{j} ( k \vert k ) - {P}^{ij} ( k \vert k ) - {P}^{ji} ( k \vert k ) .\end{matrix}$$

The states estimate of fusion is
\hat{x}^{ij}=\hat{x}ⁱ+[Pⁱ(k|k)−P^{ij}(k|k)][Pⁱ(k|k)+P^{j}(k|k)−P^{ij}(k|k)−P^{ji}(k|k)]⁻¹(\hat{x}^{j}(k|k)−\hat{x}ⁱ(k|k))
and covariance of fusion estimate is

$$\begin{matrix}{M}^{ij} = {P}^{i} ( k \vert k ) - \\ {[ {P}^{i} ( k \vert k ) - {P}^{ij} ( k \vert k ) ] [ {P}^{i} ( k \vert k ) + {P}^{j} ( k \vert k ) - {P}^{ij} ( k \vert k ) - {P}^{ji} ( k \vert k ) ]}^{- 1} \\ [ {P}^{i} ( k \vert k ) - {P}^{ij} ( k \vert k ) ]\end{matrix}$$

B.3 Covariance Intersection (Decentralized Kalman Filtering Algorithm)

Because the cross covariance matrices are too complicated and strictly unknown, to overcome this problem, one can modify the information fusion algorithm via convex combination idea of two system error covariance matrices as disclosed in [68, Covariance Intersection]. There exists a parameter α, where 0≦α≦1, such that
P_{C}=[αP₁⁻¹+(1−α)P₂⁻¹]⁻¹.
and new updated estimate is
\tilde{x}_{C}=P_{C}(k|k)[αP₁⁻¹(k|k)x₁+(1−α)P₂⁻¹(k|k)x₂].

But we should guarantee the matrix
P_{C}−E[\tilde{x}_{C}\tilde{x}_{C}^{t}]
is positive semi-definite for cross covariance P₁₂ between two prior estimates. Consider the error \tilde{c} as
\tilde{x}_{C}=P_{C}[αP₁⁻¹\tilde{x}₁+(1−α)P₂⁻¹\tilde{x}₂]
and take the expectation for \tilde{x}_{C}\tilde{x}_{C}^{t} as

$$\begin{matrix}E [ {\tilde{x}}_{C} {\tilde{x}}_{C}^{t} ] = {P}_{C} \{ {[ α {P}_{1}^{- 1} {\tilde{x}}_{1} + ( 1 - α ) {P}_{2}^{- 1} {\tilde{x}}_{2} ] [ α {P}_{1}^{- 1} {\tilde{x}}_{1} + ( 1 - α ) {P}_{2}^{- 1} {\tilde{x}}_{2} ]}^{t} \} {P}_{C} \\ = {P}_{C} \{ {α}^{2} {P}_{1}^{- 1} + {( 1 - α )}^{2} {P}_{2} + α ( 1 - α ) [ {P}_{1}^{- 1} {P}_{12} {P}_{2}^{- 1} + {P}_{2}^{- 1} {P}_{12}^{t} {P}_{1}^{- 1} ] \} {P}_{C}\end{matrix}$$

such that
P_{C}−E[\tilde{x}_{C}\tilde{x}_{C}^{t}]=P_{C}−P_{C}{α²P₁⁻¹+(1−α)²P₂+α(1−α)[P₁⁻¹P₁₂P₂⁻¹+P₂⁻¹P₁₂^{t}P₁⁻¹]}P_{C}
then take pre and post multiplication with P_{C}⁻¹

$$\begin{matrix}{P}_{C} - E [ {\tilde{x}}_{C} {\tilde{x}}_{C}^{t} ] = {P}_{C}^{- 1} \{ {α}^{2} {P}_{1}^{- 1} + {( 1 - α )}^{2} {P}_{2} + \\ α ( 1 - α ) [ {P}_{1}^{- 1} {P}_{12} {P}_{2}^{- 1} + {P}_{2}^{- 1} {P}_{12}^{t} {P}_{1}^{- 1} ] \} \\ = [ α {P}_{1}^{- 1} + ( 1 - α ) {P}_{2}^{- 1} ] - \\ \{ {α}^{2} {P}_{1}^{- 1} + {( 1 - α )}^{2} {P}_{2} + α ( 1 - α ) [ {P}_{1}^{- 1} {P}_{12} {P}_{2}^{- 1} + {P}_{2}^{- 1} {P}_{12}^{t} {P}_{1}^{- 1} ] \} \\ = α ( 1 - α ) [ {P}_{1}^{- 1} + {P}_{2}^{- 1} - {P}_{1}^{- 1} {P}_{12} {P}_{2}^{- 1} - {P}_{2}^{- 1} {P}_{12}^{t} {P}_{1}^{1} ] .\end{matrix}$$

Defining the new updated estimate error is
\tilde{d}=P₁⁻¹\tilde{x}₁−P₂⁻¹\tilde{x}₂
the corresponding covariance matrix is

$$\begin{matrix}{P}_{\tilde{d}} = E [ \tilde{d} {\tilde{d}}^{t} ] \\ = E [ ( {P}_{1}^{- 1} {\tilde{x}}_{1} - {P}_{2}^{- 1} {\tilde{x}}_{2} ) {( {P}_{1}^{- 1} {\tilde{x}}_{1} - {P}_{2}^{- 1} {\tilde{x}}_{2} )}^{t} ] \\ = {P}_{1}^{- 1} E [ {\tilde{x}}_{1} {\tilde{x}}_{1}^{t} ] {P}_{1}^{- 1} + {P}_{2}^{- 1} E [ {\tilde{x}}_{2} {\tilde{x}}_{2}^{t} ] {P}_{2}^{- 1} - {P}_{1}^{- 1} E [ {\tilde{x}}_{1} {\tilde{x}}_{2}^{t} ] {P}_{2}^{- 1} - {P}_{2}^{- 1} E [ {\tilde{x}}_{2} {\tilde{x}}_{1}^{t} ] {P}_{1}^{- 1} \\ = {P}_{1}^{- 1} + {P}_{2}^{- 1} - {P}_{1}^{- 1} {P}_{12} {P}_{2}^{- 1} - {P}_{2}^{- 1} {P}_{21} {P}_{1}^{- 1} .\end{matrix}$$

Comparing P_{C}−E[\tilde{x}_{C}\tilde{x}_{C}^{t}] with P _{d̅}, we can find it out that P_{C}−E[\tilde{x}_{C}\tilde{x}_{C}^{t}] is α(1−α) times of P _{d̅}. i.e.
P_{C}−E[\tilde{x}_{C}\tilde{x}_{C}^{t}]=α(1−α)P _{d̅}.

By definition of covariance, P_{C}−E[\tilde{x}_{C}\tilde{x}_{C}^{t}] should be a positive semidefinite matrix at least if 0≦α≦1 ways for any cross covariance P₁₂. In general, for the fused covariance P_{C} the positive semidefinite property is conservative for any unknown cross covariance P^{ij}. Basically, for any two estimates defined by their means and covariances, how can we guarantee the κ-sigma contours contained the intersection of κ-sigma contours of two system estimates? The goal of fusion is to obtain more precision and the combined covariance matrix has to be smaller than either P₁ or P₂. Again, we consider the normalized statistical length as following. Let f_{C}(x) be a normalized squared distance with the point x as
f_{C}(x)=\tilde{x}^{t}P_{C}⁻¹\tilde{x}
=κ².

Now given the {x₁,P₁} and {x₂,P₂} estimates, the feasible fused estimate is {\hat{x}_{C},P_{C}} if
f_{C}(x)≦max(f₁(x),f₂(x)), ∀x.

The suitable representation of f_{C}(x) is in terms of a weighted average of f₁(x) and f₂(x)
f_{C}(x)≦αf₁(x)+(1−α)f₂(x), 0≧α≦1.
where f_{C}(x) is less than or equal to larger of f₁(x) and f₂(x) for every x. Now defining the f_{C}(x), f₁(x), f₂(x) are as following
f_{C}=\tilde{x}^{t}P_{C}⁻¹\tilde{x},
f₁=\tilde{x}^{t}P₁⁻¹\tilde{x},
f₂=\tilde{x}^{t}P₂⁻¹\tilde{x},
substituting f_{C}(x), f₁(x), f₂(x) into the weighted average of f₁(x) and f₂(x) such that
\tilde{x}^{t}P_{C}⁻¹\tilde{x}≦α\tilde{x}^{t}P₁⁻¹\tilde{x}+(1−α)\tilde{x}^{t}P₂⁻¹\tilde{x}
or
\tilde{x}^{t}P_{C}⁻¹\tilde{x}≦\tilde{x}^{t}[αP₁⁻¹+(1−α)P₂⁻¹]\tilde{x}.

Give the fused covariance matrix to be
P_{C}=[αP₁⁻¹+(1−α)P₂⁻¹]⁻¹
and the fused estimate \hat{x}_{C} is
\hat{x}_{C}=C[αP₁⁻¹\hat{x}₁+(1−α)P₂⁻¹\hat{x}₂]

Furthermore, a convex function is introduced
g(u,U)=u^{t}U⁻¹u
and the convexity property of g(u, U)
g(αu+(−α)ν, αU+(1−α)V)≦αg(u,U)+(1−α)g(ν,V).

Let the new variables are
u=αP₁⁻¹(x−x₁), U=αP₁⁻¹
ν=(1−α)P₂⁻¹(x−x₂), V=(1−α)P₂⁻¹
then

$$\begin{matrix}g ( u , U ) = {{[ α {P}_{1}^{- 1} ( x - {x}_{1} ) ]}^{t} [ α {P}_{1}^{1} ]}^{- 1} [ α {P}_{1}^{- 1} ( x - {x}_{1} ) ] \\ = {α ( x - {x}_{1} )}^{t} {P}_{1}^{- 1} ( x - {x}_{1} ) \\ = α {f}_{1} ( x ) . \\ Similarly , \\ g ( v , V ) = {{[ ( 1 - α ) {P}_{2}^{- 1} ( x - {x}_{2} ) ]}^{t} [ ( 1 - α ) {P}_{2}^{- 1} ]}^{- 1} [ ( 1 - α ) {P}_{2}^{- 1} ( x - {x}_{2} ) ] \\ = ( 1 - α ) {( x - {x}_{2} )}^{t} {P}_{2}^{- 1} ( x - {x}_{2} ) \\ = ( 1 - α ) {f}_{2 } ( x ) . \\ Finally , \\ g ( u + v , U + V ) = g ( [ α {P}_{1}^{- 1} ( x - {x}_{1} ) + ( 1 - α ) {P}_{2}^{- 1} ( x - {x}_{2} ) ] , \\ [ α {P}_{1}^{- 1} + ( 1 - α ) {P}_{2}^{- 1} ] ) \\ = {[ α {P}_{1}^{- 1} ( x - {x}_{1} ) + ( 1 - α ) {P}_{2}^{- 1} ( x - {x}_{2} ) ]}^{t} \\ {[ α {P}_{1}^{- 1} + ( 1 - α ) {P}_{2}^{- 1} ]}^{- 1} \\ [ α {P}_{1}^{- 1} ( x - {x}_{1} ) + ( 1 - α ) {P}_{2}^{- 1} ( x - {x}_{2} ) ] \\ = {( [ α {P}_{1}^{- 1} + ( 1 - α ) {P}_{2}^{- 1} ] x - [ α {P}_{1}^{- 1} {x}_{1} + ( 1 - α ) {P}_{2}^{- 1} {x}_{2} ] )}^{t} \\ {[ α {P}_{1}^{- 1} + ( 1 - α ) {P}_{2}^{- 1} ]}^{- 1} \\ ( [ α {P}_{1}^{- 1} + ( 1 - α ) {P}_{2}^{- 1} ] x - [ α {P}_{1}^{- 1} {x}_{1} + ( 1 - α ) {P}_{2}^{- 1} {x}_{2} ] ) \\ = {( {P}_{C}^{- 1} x - {P}_{C}^{- 1} {\hat{x}}_{C} )}^{t} {P}_{C} ( {P}_{C}^{- 1} x - {P}_{C}^{- 1} {\hat{x}}_{C} ) \\ = {( x - {\hat{x}}_{C} )}^{t} {P}_{C}^{- 1} ( x - {\hat{x}}_{C} ) \\ = {f}_{C} ( x )\end{matrix}$$

implies that the fused estimate {\hat{x}_{C},P_{C}} satisfy
f_{C}(x)≦αf₁(x)+(1−α)f₂(x), for 0≦α≦1.

Consider the limiting case, i.e. x₁=x₂=\hat{x}_{c}, the function f_{C}(x) is

$$\begin{matrix}{f}_{C} ( x ) = {\hat{x}}_{c}^{t} ( [ α {P}_{1}^{- 1} + ( 1 - α ) {P}_{2}^{- 1} ] ) {\hat{x}}_{c} \\ = α {\hat{x}}_{c}^{t} {P}_{1}^{- 1} {\hat{x}}_{c} + ( 1 - α ) {\hat{x}}_{c}^{t} {P}_{2}^{- 1} {\hat{x}}_{c} \\ = α {f}_{1} ( x ) + ( 1 - α ) {f}_{2} ( x ) .\end{matrix}$$

That is, the up and low bound of f_{C}(x) is
min(f₁(x),f₂(x))≦f_{C}(x)≦max(f₁(x),f₂(x)),
such that implies that the fused estimate \hat{x}_{C} is chosen in the intersection area always. Whatever, to guarantee the convexity of Covariance Intersection as disclosed in [68, Covariance Intersection] and free computing the cross covariance, the α should be chosen as 0≦α≦1.
C Prediction Interval

Let x₁, x₂, . . . , xₙ, xₙ₊₁ denote a sample from a normal population whose mean μ and variance σ² are unknown. Suppose that we are interested in using the observed values of x₁, x₂, . . . , xₙ to determine the interval, called a prediction interval, and then we predict and will obtain the value xₙ₊₁ with 100(1−α) percent confidence. Since the normal sample population is
x₁, x₂, . . . , xₙ, xₙ₊₁˜N(μ,σ²)

In other words, the difference between xₙ₊₁ and sample mean x̅ or x̅ₙ is

$${x}_{n + 1} - \overline{x} \sim N ( 0 , {σ}^{2} + \frac{{σ}^{2}}{n} )$$

$$or$$

$${x}_{n + 1} - \overline{x} \sim N ( 0 , \frac{( n + 1 ) {σ}^{2}}{n} )$$

, and difference between xₙ₊₁ and sample mean x̅ is a normal random variable with zero mean and variance one as

$$\frac{{x}_{n + 1} - \overline{x}}{\sqrt{\frac{n + 1}{n}} σ} \sim N ( 0 , 1 )$$

Based on the definition oft-distribution as shown in equation (78), with (n−1) degrees of freedom,

$${T}_{n - 1} = \frac{Z}{\sqrt{\frac{{x}_{n - 1}^{2}}{n - 1}}}$$

where the random variable Z˜N(0,1) then Tₙ₋₁˜tₙ₋₁. Now let the random variable Z be

$$Z = \frac{{x}_{n + 1} - \overline{x}}{\sqrt{\frac{n + 1}{n} σ}}$$

and refer to the equation (77), Tₙ₋₁ becomes

$$\begin{matrix}{T}_{n - 1} = \frac{Z}{\sqrt{\frac{{x}_{n - 1}^{2}}{n - 1}}} \sim {t}_{n - 1} \\ = \frac{( \frac{{x}_{n + 1} - \overline{x}}{\sqrt{\frac{n + 1}{n} σ}} )}{\sqrt{\frac{{nS}_{n}^{2}}{{σ}^{2} ( n - 1 )}}} \sim {t}_{n - 1} \\ = ( \sqrt{\frac{n - 1}{n}} ) ( \frac{{x}_{n + 1} - \overline{x}}{\sqrt{\frac{n + 1}{n} {S}_{n}}} ) \sim {t}_{n - 1} \\ = ( \sqrt{\frac{n - 1}{n + 1}} ) ( \frac{{x}_{n + 1} - \overline{x}}{{S}_{n}} ) \sim {t}_{n - 1}\end{matrix} \qquad ( 81 )$$

Since the number n is a constant, the term in the equation (81)

$$( \frac{{x}_{n + 1} - \overline{x}}{\sqrt{\frac{n + 1}{n} {S}_{n}}} )$$

is still a random variable,

$$( \frac{{x}_{n + 1} - \overline{x}}{\sqrt{\frac{n + 1}{n} {S}_{n}}} ) \sim {t}_{n - 1}$$

the prediction interval of xₙ₊₁ with 100(1−α) confidence is

$$P [ \vert ( \sqrt{\frac{n + 1}{n + 1}} ) ( \frac{{x}_{n + 1} - \overline{x}}{{S}_{n}} ) \vert \leq {t}_{\frac{α}{2} , n - 1} ] = 1 - α$$

That is, finally, the prediction interval of xₙ₊₁ with 100 (1−α) confidence is

$$\overline{x} - {S}_{n} ( \sqrt{\frac{n + 1}{n - 1}} ) {t}_{\frac{α}{2} , n - 1} \leq {x}_{n + 1} \leq \overline{x} + {S}_{n} ( \sqrt{\frac{n + 1}{n - 1}} ) {t}_{\frac{α}{2} , n - 1} \qquad ( 82 )$$

Or, in terms of X̅ₙ̅

$${\overline{x}}_{n} - {S}_{n} ( \sqrt{\frac{n + 1}{n - 1}} ) {t}_{\frac{α}{2} , n - 1} \leq {x}_{n + 1} \leq {\overline{x}}_{n} + {S}_{n} ( \sqrt{\frac{n + 1}{n - 1}} ) {t}_{\frac{α}{2} , n - 1}$$

We say, the forecast of xₙ₊₁ is \hat{x}ₙ₊₁

$$\begin{matrix}{\hat{x}}_{n + 1} = {\overline{x}}_{n} \pm {S}_{n} ( \sqrt{\frac{n + 1}{n - 1}} ) {t}_{\frac{α}{2} , n - 1} \\ = {\overline{x}}_{n} \pm {b}_{n}\end{matrix} \qquad ( 83 )$$

where xₙ is called the level value and the term bₙ

$${b}_{n} ( \sqrt{\frac{n + 1}{n - 1}} {S}_{n} ) {t}_{\frac{α}{2} , n - 1}$$

is called the long-term movement.

For constructing the recursive relationship of the sample mean, given the sum of the population x₁, x₂, . . . , xₙ, xₙ₊₁ and x₁, x₂, . . . , xₙ

$${\overline{x}}_{n} = \frac{1}{n} {\sum }_{i = 1}^{n} {x}_{i}$$

$$n {\overline{x}}_{n} = {x}_{1} + {x}_{2} + … + {x}_{n}$$

$${\overline{x}}_{n + 1} = \frac{1}{n + 1} {\sum }_{i = 1}^{( n + 1 )} {x}_{i} \\ ( n + 1 ) {\overline{x}}_{n + 1} = {x}_{1} + {x}_{2} + … + {x}_{n + 1}$$

where it is assumed that this population x₁, x₂, . . . , xₙ, xₙ₊₁ with unknown population mean μ and variance σ² as
x₁, x₂, . . . , xₙ, xₙ₊₁˜N(μ,σ²)
the recursive relationship between the sample mean x̅ₙ₊₁ and x̅ₙ is

$$( n + 1 ) {\overline{x}}_{n + 1} - ( n ) {\overline{x}}_{n} = {x}_{n + 1} \\ or \\ {\overline{x}}_{n + 1} = ( \frac{1}{n + 1} ) {y}_{n + 1} + ( \frac{n}{n + 1} ) {\overline{x}}_{n} \qquad ( 84 )$$

, where yₙ₊₁ is equal to xₙ₊₁.

Similarly, the recursive relationship between the sample variance Sₙ₊₁² and Sₙ² is constructed as follows: defining the sample variance to be

$${S}_{n + 1}^{2} = ( \frac{1}{n + 1} ) {\sum }_{i = 1}^{( n + 1 )} {( {x}_{i} - {\overline{x}}_{n + 1} )}^{2} ,$$

the relationship of the sample variance Sₙ₊₁² and Sₙ² can be obtained

$$( n + 1 ) {S}_{n + 1}^{2} - n {S}_{n}^{2} = ( \frac{n}{n + 1} ) {( {x}_{n + 1} - {\overline{x}}_{n} )}^{2} \\ {S}_{n + 1}^{2} = ( \frac{n}{n + 1} ) {S}_{n}^{2} + \frac{n}{( n + 1 )} \frac{{( {y}_{n + 1} - {\overline{x}}_{n} )}^{2}}{( n + 1 )} \qquad ( 85 )$$

D Improved Discounted Least Square Method

Refer to [26] and [2] for the statistical methods for forecasting Kalman Filtering Algorithm and ML Estimator. Following the prediction interval as shown in equation (83), we further consider the discounted least square method as the forecasting principle, if the forecasting model is local linear trend as
yₙ₊₁=Sₙ₋₁+lbₙ₋₁+εₙ₊₁
then the smoothing statistics level value or short-term movement is Sₙ and trend component or long-term movement bₙ at the n^{th} step and the l is called leading time here we just care about the case of l=1, i.e., one-step-ahead. A local trend may change direction of the sample and it is the most recent direction that we want to “extrapolate” into the future.

The construction of forecast functions based on discounted past observations is commonly carried out by exponential smoothing procedures. The time series is modelled as follows

$$\begin{matrix}\begin{matrix}[ \begin{matrix}{S}_{n} \\ {b}_{n}\end{matrix} ] = [ \begin{matrix}1 & 1 \\ 0 & 1\end{matrix} ] [ \begin{matrix}{S}_{n - 1} \\ {b}_{n - 1}\end{matrix} ] + [ \begin{matrix}( 1 - {λ}^{2} ) ( {y}_{n} - {S}_{n - 1} - {b}_{n - 1} ) \\ {( 1 - λ )}^{2} ( \frac{1 - λ}{1 + λ} ) ( {y}_{n} - {S}_{n - 1} - {b}_{n - 1} )\end{matrix} ] \\ = [ \begin{matrix}1 & 1 \\ 0 & 1\end{matrix} ] [ \begin{matrix}{S}_{n - 1} \\ {b}_{n - 1}\end{matrix} ] + [ \begin{matrix}( 1 - {λ}^{2} ) ( {y}_{n} - {S}_{n - 1} - {b}_{n - 1} ) \\ {( 1 - λ )}^{2} ( {y}_{n} - {S}_{n - 1} - {b}_{n - 1} )\end{matrix} ]\end{matrix} & ( 86 ) \\ {y}_{n} = [ \begin{matrix}1 & 0\end{matrix} ] [ \begin{matrix}{S}_{n} \\ {b}_{n}\end{matrix} ] + {ɛ}_{n} & ( 87 )\end{matrix}$$

and by the Holt-Winter forecasting model as disclosed in [26], the forecasting of yₙ₊₁ is ŷₙ₊₁

$$\begin{matrix}{\hat{y}}_{n + 1} = {S}_{n} + {b}_{n} \\ = {S}_{n - 1} + 2 {b}_{n - 1} + 2 ( 1 - λ ) ( {y}_{n} - {S}_{n - 1} - {b}_{n - 1} )\end{matrix} \qquad ( 88 )$$

or in the unknown smoothing constant form,

$$λ = \frac{2 {y}_{n} - {\hat{y}}_{n + 1} - {S}_{n - 1}}{2 ( {y}_{n} - {S}_{n - 1} - {b}_{n - 1} )}$$

then the prediction error eₙ is defined as
eₙ≡ŷₙ₊₁−yₙ₊₁
and
qₙ²=E[(yₙ−Sₙ₋₁−bₙ₋₁)²]

In the Kalman filtering algorithm as disclosed in [7], [26] and page 165 of [12], one needs to construct the transition, sensory model, state and output covariance process noise matrices Φₙ, Hₙ, Pₙ, Rₙ, Qₙ and we compute the matrix of them as following: Firstly, the process noise matrix Qₙ is

$${Q}_{n} = [ \begin{matrix}{Q}_{11} & {Q}_{12} \\ {Q}_{12} & {Q}_{22}\end{matrix} ]$$

where the components of Q matrix are

$$\begin{matrix}{Q}_{11} = {( 1 - λ )}^{2} {( 1 + λ )}^{2} E [ {( {y}_{n} - {S}_{n - 1} - {b}_{n - 1} )}^{2} ] \\ = {( 1 - λ )}^{2} {( 1 + λ )}^{2} {q}_{n}^{2} \\ {Q}_{12} = ( 1 - {λ}^{2} ) {( 1 - λ )}^{2} E [ {( {y}_{n} - {S}_{n - 1} - {b}_{n - 1} )}^{2} ] \\ = ( 1 - {λ}^{2} ) {( 1 - λ )}^{2} {q}_{n}^{2} \\ {Q}_{11} + {Q}_{12} = {( 1 - λ )}^{2} {( 1 + λ )}^{2} {q}_{n}^{2} + ( 1 - {λ}^{2} ) {( 1 - λ )}^{2} {q}_{n}^{2} \\ = 2 {( 1 - λ )}^{2} {( 1 + λ )}^{2} {q}_{n}^{2}\end{matrix}$$

$$and$$

$$\begin{matrix}{Q}_{22} = {( 1 - λ )}^{4} E [ {( {y}_{n} - {S}_{n - 1} - {b}_{n - 1} )}^{2} ] \\ = {( 1 - λ )}^{4} {q}_{n}^{2}\end{matrix}$$

, respectively. The other matrices are

$${Φ}_{n} = [ \begin{matrix}1 & 1 \\ 0 & 1\end{matrix} ]$$

$${P}_{n} = [ \begin{matrix}{P}_{11} & {P}_{12} \\ {P}_{12} & {P}_{22}\end{matrix} ]$$

$${H}_{n} = [ \begin{matrix}1 & 0\end{matrix} ]$$

$$and$$

$$\begin{matrix}{R}_{n} = E [ {( {y}_{n} - {S}_{n} )}^{2} ] \\ = {λ}^{4} E [ {( {y}_{n} - {S}_{n - 1} - {b}_{n - 1} )}^{2} ] \\ = {λ}^{4} {q}_{n}^{2}\end{matrix}$$

where the term Sₙ can be replaced by the component of equation (86) as

$$\begin{matrix}{y}_{n} - {S}_{n} = ( {y}_{n} - {S}_{n - 1} - {b}_{n - 1} ) - ( 1 - {λ}^{2} ) ( {y}_{n} - {S}_{n - 1} - {b}_{n - 1} ) \\ = {λ}^{2} ( {y}_{n} - {S}_{n - 1} - {b}_{n - 1} )\end{matrix}$$

The Kalman gain Wₙ is

$$\begin{matrix}{W}_{n} = {P}_{n}^{+} {H}_{n}^{′} {B}_{n}^{- 1} \\ = [ \begin{matrix}{W}_{n 1} \\ {W}_{n 2}\end{matrix} ]\end{matrix}$$

$$where$$

$$\begin{matrix}{P}_{n}^{+} = {Φ}_{n} {P}_{n} {Φ}_{n}^{′} + {Q}_{n} \\ = [ \begin{matrix}1 & 1 \\ 0 & 1\end{matrix} ] [ \begin{matrix}{P}_{11} & {P}_{12} \\ {P}_{12} & {P}_{22}\end{matrix} ] [ \begin{matrix}1 & 0 \\ 1 & 1\end{matrix} ] + [ \begin{matrix}{Q}_{11} & {Q}_{12} \\ {Q}_{12} & {Q}_{22}\end{matrix} ] \\ = [ \begin{matrix}{P}_{11} + 2 {P}_{12} + {P}_{22} + {Q}_{11} & {P}_{12} + {P}_{22} + {Q}_{12} \\ {P}_{12} + {P}_{22} + {Q}_{12} & {P}_{22} + {Q}_{22}\end{matrix} ]\end{matrix}$$

$$\begin{matrix}{B}_{n} = {H}_{n} ( {Φ}_{n} {P}_{n} {Φ}_{n}^{′} + {Q}_{n} ) {H}_{n}^{′} + {R}_{n} \\ = [ \begin{matrix}1 & 0\end{matrix} ] [ \begin{matrix}{P}_{11} + 2 {P}_{12} + {P}_{22} + {Q}_{11} & {P}_{12} + {P}_{22} + {Q}_{12} \\ {P}_{12} + {P}_{22} + {Q}_{12} & {P}_{22} + {Q}_{22}\end{matrix} ] [ \begin{matrix}1 \\ 0\end{matrix} ] + {R}_{n} \\ = {P}_{11} + 2 {P}_{12} + {P}_{22} + {R}_{n} + {Q}_{11}\end{matrix}$$

Consequently, the updated state equation is

$$\begin{matrix}[ \begin{matrix}{\hat{S}}_{n} \\ {\hat{b}}_{n}\end{matrix} ] = [ \begin{matrix}1 & 1 \\ 0 & 1\end{matrix} ] [ \begin{matrix}{S}_{n - 1} \\ {b}_{n - 1}\end{matrix} ] + \\ {W}_{n} ( {y}_{n} - [ \begin{matrix}1 & 0\end{matrix} ] [ \begin{matrix}1 & 1 \\ 0 & 1\end{matrix} ] [ \begin{matrix}{S}_{n - 1} \\ {b}_{n - 1}\end{matrix} ] ) \\ = [ \begin{matrix}1 & 1 \\ 0 & 1\end{matrix} ] [ \begin{matrix}{S}_{n - 1} \\ {b}_{n - 1}\end{matrix} ] + [ \begin{matrix}{W}_{n 1} \\ {W}_{n 2}\end{matrix} ] ( {y}_{n} - {S}_{n - 1} - {b}_{n - 1} )\end{matrix} \qquad ( 89 )$$

and the updated error covariance is

$$\begin{matrix}{\hat{P}}_{n + 1} = {P}_{n}^{+} - {W}_{n} {B}_{n} {W}_{n}^{′} \\ = [ \begin{matrix}{P}_{11} + 2 {P}_{12} + {P}_{22} + {Q}_{11} & {P}_{12} + {P}_{22} + {Q}_{12} \\ {P}_{12} + {P}_{22} + {Q}_{12} & {P}_{22} + {Q}_{22}\end{matrix} ] - \\ [ \begin{matrix}{P}_{11} + 2 {P}_{12} + {P}_{22} + {Q}_{11} \\ {P}_{12} + {P}_{22} + {Q}_{12}\end{matrix} ] \\ ( \frac{[ \begin{matrix}{P}_{11} + 2 {P}_{12} + {P}_{22} + {Q}_{11} & {P}_{12} + {P}_{22} + {Q}_{12}\end{matrix} ]}{{P}_{11} + 2 {P}_{12} + {P}_{22} + {R}_{n} + {Q}_{11}} )\end{matrix}$$

Also, by changing the notation in the n^{th} step, the covariance matrix \hat{P}ₙ₊₁ components are

$$\begin{matrix}{\hat{P}}_{n + 1}^{11} = ( {P}_{n}^{11} + 2 {P}_{n}^{12} + {P}_{n}^{22} + {Q}_{11} ) \\ ( \frac{ \begin{matrix}( {R}_{n} + {P}_{n}^{11} + 2 {P}_{n}^{12} + {P}_{n}^{22} + {Q}_{11} ) - \\ ( {P}_{n}^{11} + 2 {P}_{n}^{12} + {P}_{n}^{22} + {Q}_{11} )\end{matrix}}{{R}_{n} + {P}_{n}^{11} + 2 {P}_{n}^{12} + {P}_{n}^{22} + {Q}_{11}} ) \\ {\hat{P}}_{n + 1}^{12} = \frac{{R}_{n} ( {P}_{n}^{12} + {P}_{n}^{22} + {Q}_{12} )}{{R}_{n} + {P}_{n}^{11} + 2 {P}_{n}^{12} + {P}_{n}^{22} + {Q}_{11}}\end{matrix}$$

$$and$$

$${\hat{P}}_{n + 1}^{22} = \frac{\begin{matrix}( {P}_{22} + {Q}_{22} ) ( {R}_{n} + {P}_{n}^{11} + {P}_{n}^{12} + {P}_{n}^{22} + {Q}_{11} ) - \\ {( {P}_{n}^{12} + {P}_{n}^{22} + {Q}_{12} )}^{2}\end{matrix}}{{R}_{n} + {P}_{n}^{11} + 2 {P}_{n}^{12} + {P}_{n}^{22} + {Q}_{11}}$$

Referring to equation (88), the forecasting ŷₙ₊₁ is obtained from the updated states as shown in equation (89)

$$\begin{matrix}{\hat{y}}_{n + 1} = {\hat{S}}_{n} + {\hat{b}}_{n} \\ = {S}_{n - 1} + 2 {b}_{n - 1} + ( {W}_{n 1} + {W}_{n 2} ) ( {y}_{n} - {S}_{n - 1} - {b}_{n - 1} )\end{matrix} \qquad ( 90 )$$

Also, from the viewpoint of Bayesian forecasting framework as disclosed in [71] and [2], referring to equation (80), for one-step-ahead forecasting of yₙ,

$$\begin{matrix}{\hat{y}}_{n + 1} = E [ {y}_{n + 1} \vert {Y}_{n} ] \\ = {H}_{n + 1} {\hat{S}}_{n + 1} \\ = {H}_{n + 1} {Φ}^{1} {\hat{S}}_{n} \\ = [ \begin{matrix}1 & 0\end{matrix} ] [ \begin{matrix}1 & 1 \\ 0 & 1\end{matrix} ] [ \begin{matrix}{\hat{S}}_{n} \\ {\hat{b}}_{n}\end{matrix} ] \\ = [ \begin{matrix}1 & 1\end{matrix} ] [ \begin{matrix}1 & 1 \\ 0 & 1\end{matrix} ] [ \begin{matrix}{S}_{n - 1} \\ {b}_{n - 1}\end{matrix} ] + [ \begin{matrix}{W}_{n 1} \\ {W}_{n 2}\end{matrix} ] ( {y}_{n} - {S}_{n - 1} - {b}_{n - 1} ) \\ = [ \begin{matrix}1 & 2\end{matrix} ] [ \begin{matrix}{S}_{n - 1} \\ {b}_{n - 1}\end{matrix} ] + [ \begin{matrix}1 & 1\end{matrix} ] [ \begin{matrix}{W}_{n 1} \\ {W}_{n 2}\end{matrix} ] ( {y}_{n} - {S}_{n - 1} - {b}_{n - 1} ) \\ = {S}_{n - 1} + 2 {b}_{n - 1} + ( {W}_{n 1} + {W}_{n 2} ) ( {y}_{n} - {S}_{n - 1} - {b}_{n - 1} )\end{matrix} \qquad ( 91 )$$

Note that the Holt process and Bayesian framework have the same forecasting results as shown in equations (88) and (91).

Comparing forecasting output of equation (88) with that of equation (90) or (91)

$$\begin{matrix}2 ( 1 - λ ) = ( {W}_{n 1} + {W}_{n 2} ) \\ = ( \frac{{P}_{n}^{11} + 3 {P}_{n}^{12} + 2 {P}_{n}^{22} + {Q}_{11} + {Q}_{12}}{{P}_{n}^{11} + 2 {P}_{n}^{12} + {P}_{n}^{22} + {R}_{n} + {Q}_{11}} ) \\ = ( \frac{{P}_{n}^{11} + 3 {P}_{n}^{12} + 2 {P}_{n}^{22} + 2 {( 1 - λ )}^{2} ( 1 + λ ) {q}_{n}^{2}}{{P}_{n}^{11} + 2 {P}_{n}^{12} + {P}_{n}^{22} + ( 2 {λ}^{4} - 2 {λ}^{2} + 1 ) {q}_{n}^{2}} ) ,\end{matrix}$$

one can construct the a 5-root equation (92)

$$\begin{matrix}0 = 2 ( 1 - λ ) ( {P}_{n}^{11} + 2 {P}_{n}^{12} + {P}_{n}^{22} + ( 2 {λ}^{4} - 2 {λ}^{2} + 1 ) {q}_{n}^{2} ) - \\ ( {P}_{n}^{11} + 3 {P}_{n}^{12} + 2 {P}_{n}^{22} + 2 {( 1 - λ )}^{2} ( 1 + λ ) {q}_{n}^{2} ) \\ = 2 {λ}^{5} - 2 {λ}^{4} - {λ}^{3} + {λ}^{2} + ( \frac{1}{{q}_{n}^{2}} ) ( {P}_{n}^{11} + 2 {P}_{n}^{12} + {P}_{n}^{22} ) λ - \\ ( \frac{1}{2 {q}_{n}^{2}} ) ( {P}_{n}^{11} + {P}_{n}^{12} )\end{matrix} \qquad ( 92 )$$

where the roots of equation (92) have to satisfy the following constraint
0<λ<1 (93)

In particular, if we consider the special case as pₙ¹²=0 (trend and level components are uncorrelated), Pₙ²²=εPₙ¹¹, the higher order terms in equation (92) are discarded, then

$$\begin{matrix}\hat{λ} = ( \frac{1}{2} ) ( \frac{{P}_{n}^{11}}{{P}_{n}^{11} + {P}_{n}^{22}} ) \\ = ( \frac{1}{2} ) ( \frac{1}{1 + ɛ} )\end{matrix}$$

where the small constant ε is about 10⁻³. If there exists the root of equation (92) \hat{λ}, also satisfy the constraint as shown in equation (93) simultaneously, then the forecasting output becomes

$$\begin{matrix}{\hat{y}}_{n + 1} = {\hat{S}}_{n} + {\hat{b}}_{n} \\ = {S}_{n - 1} + 2 {b}_{n - 1} + 2 ( 1 - \hat{λ} ) ( {y}_{n} - {S}_{n - 1} - {b}_{n - 1} )\end{matrix} \qquad ( 94 )$$

When the initial values are assigned to be zero
P₁₁=P₁₂=P₂₂=0
then (92) becomes

$${λ}^{5} - {λ}^{4} - \frac{{λ}^{3}}{2} + \frac{{λ}^{2}}{2} = 0$$

Also, the roots are

$$0 , 1 , - \frac{1}{2} \sqrt{2} and \frac{1}{2} \sqrt{2} ,$$

that is, we assign the initial value of λ to be
λ=0.707.
Based on equation (92), the discounted factor λ is not any more obtained by a stochastic simulation. This is a comprehensive reason why we say the “improved” discounted least square method.

For most complicated cases, i.e., the equation (92) can not be obtained neither one exactly real root nor equation (93) hold, the discounted factor λ is no explicit model to produce it. In other words, we can define the log-likelihood function from the prediction error decomposition as disclosed in [26] (refer to equation (79)), in the form of

$$f ( λ ) = {\sum }_{k = 1}^{M} [ \frac{{v}^{2} ( k )}{B ( k )} + log ( 2 π B ( k ) ) ] \qquad ( 95 )$$

where the constant M is the sampled window length, then the unknown parameter λ is obtained by minimizing the log-likelihood function as shown in equation (95). This opens the way for the estimation of any unknown parameters in the model, denoted as

$$\hat{λ} = {min}_{arg ( λ )} f ( λ )$$

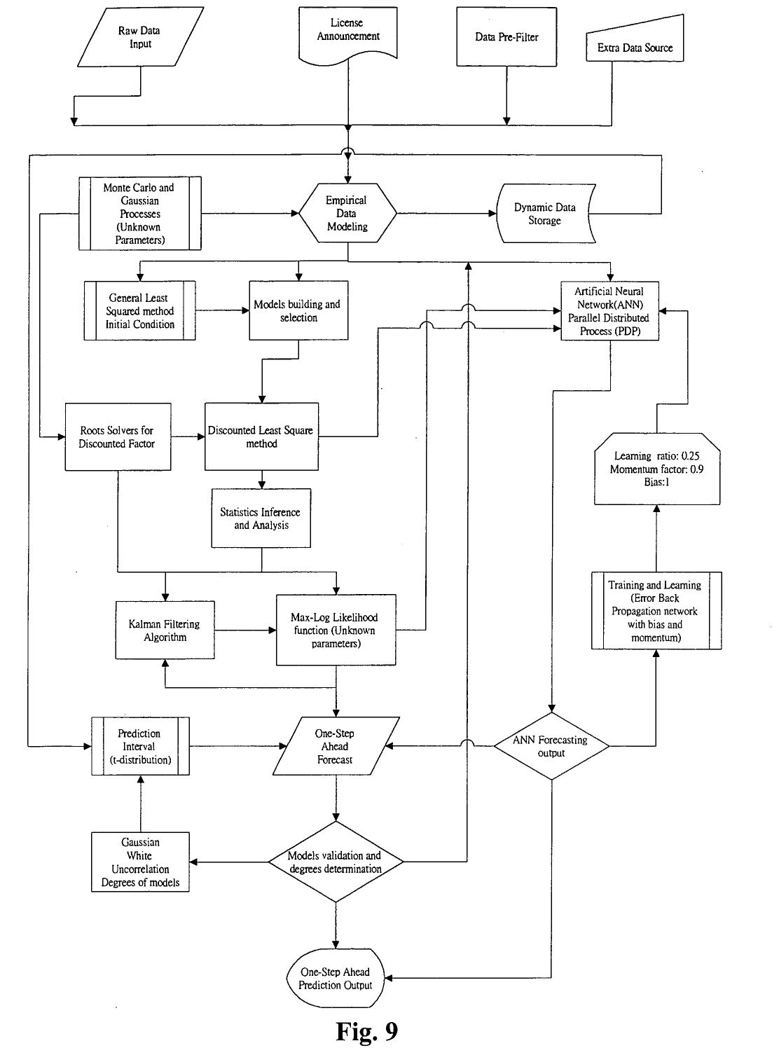

Then forecasting output becomes the form of equation (94). It also provides the basis for statistical testing and model selections. If the normality assumption is dropped, there is no longer any guarantee that the Kalman filter will give the conditional mean of these the state vector. However, it is still an optimal estimator in the sense that it minimizes the mean square error within the class of all linear estimators. In the technical point of view, the stability of numerical computation algorithms is more concerned about. Thanks to the context disclosed in [51], it has enriched numerical algorithms. The improved discounted least square method can be concluded in FIG. 9.

In particular, by the results of equations (94) and (100), we call it as the improved discounted least square method because the discounted factor λ has satisfied equation (92) and is recursively dependent on the error covariance terms

$$( \frac{1}{{q}_{n}^{2}} ) ( {P}_{n}^{11} + 2 {P}_{n}^{12} + {P}_{n}^{22} ) and ( \frac{1}{2 {q}_{n}^{2}} ) ( {P}_{n}^{11} + 2 {P}_{n}^{12} )$$

for each time step movement. This indicates the improved discounted least square method can be implemented in a real-time forecasting system. In addition, for numerical convergent and stability considerations, one can be embedded into the artificial neutral network as disclosed in [42, Vol 1, Chapter 8] algorithm provided for learning and for allowing this system to be stable and fast convergent. For further readings about the model selection and validation, white-noise and autocorrelation signals checking, refer to the books [26], [12, page 165], [51] and [2, Chapter 2, 3, 5, 8].
E Power Waveform Distortion

Referring to [62], there are five crucial sources of power waveform distortion as following:

1. DC Offset or Bias

DC current or voltage exists in an AC power system. The primary drawback is the transformer core may easily become a saturation situation such that the temperature of the transformer core gets high and there may be loss of efficiency even under a normal operation condition.

2. Harmonics

Due to the material defects and more complex nonlinear properties, the voltages or currents have integer multiples of the fundamental frequency (60 or 50 Hz).

3. Subharmonics or Interharmonics

Due to the material defects and more complex nonlinear properties, the voltages or currents have non-integer multiples of the fundamental frequency (60 or 50 Hz). They appear as discrete frequencies or a broadband spectrum.

Let the power be the function of time P=P(t), and P(t) can be decomposed into

$$P ( t ) = \frac{{a}_{0}}{2} + {\sum }_{h > 0}^{{h}_{n}} [ {a}_{h} cos ( {ω}_{h} t + {β}_{h} ) + {b}_{h} sin ( {ω}_{h} t + {β}_{h} ) ] \qquad ( 96 )$$

where h and hₙ are real positive numbers (integers and non-integers included),

$$\frac{{a}_{0}}{2}$$

is called the DC offset, ωₕ and βₙ is the h^{th}-order spectrum and initial phase respectively. Also, aₕ and bₕ are the intensity of power for the h^{th}-order component.

4. Notching

It is caused by current commutated from one phase βₕ_{₁} to another phase βₕ_{₂} as equation (96), where βₕ_{₁}≠βₕ_{₂}.

5. Noise

It is a random signal and unwanted distortion of power which is not classified as the (sub)harmonic distortion or transients.

F Harmonic or Subharmonic Waveforms Reasoning

Refer to [18, Chapter 1, 4, 5, 6, 7], and consider the general forced system

$$\frac{{ⅆ}^{2} x}{ⅆ {t}^{2}} + {Ω}^{2} x = F ( ω t ) - ɛ h ( \frac{ⅆ x}{ⅆ t} , x ) \qquad ( 97 )$$

where ε is a small parameter contributed from the material defects and unmodeled environmental disturbances, ω is an input exciting frequency and

$$h ( \frac{ⅆ x}{ⅆ t} , x )$$

is the nonlinear damper. Supposing that the force input F(ωt) is periodic, with the time variable scaled to give it the period 2π, and its mean value is zero, such that can be expressed as the form of Fouries series:

$$\begin{matrix}F ( τ ) = F ( ω t ) \\ = {\sum }_{n = 1}^{∞} {A}_{n} cos n τ + {B}_{n} sin n π\end{matrix} \qquad ( 98 )$$

and allows the term Ω to be close to an integer N expressed as
Ω²=N²+εβ (99)

In common knowledge of perturbation methods of requiring that the periodic solutions emerges from periodic solutions of a linear system. For making the damping term of the system (97), i.e., h(dx/dt, x), to be zero, the equation (97) is rearranged, and let

$$\begin{matrix}f ( τ ) = F ( τ ) - ɛ A cos N τ - ɛ B sin N τ \\ = {\sum }_{n \neq N}^{∞} {A}_{n} cos n τ + {B}_{n} sin n τ\end{matrix}$$

where if we write
A_{N}=εA
B_{N}=εB
then equation (97) becomes

$$\frac{{ⅆ}^{2} x}{ⅆ {t}^{2}} + {N}^{2} x = f ( τ ) + ɛ [ - h ( \frac{ⅆ x}{ⅆ t} , x ) - β x + A cos N τ + B sin N τ ]$$

The linearized equation is

$$\frac{{ⅆ}^{2} x}{ⅆ {t}^{2}} + {N}^{2} x = f ( τ )$$

with no resonance. As usual, let the solution of equation (97) be perturbed by the parameter ε as
x(ε,τ)=x₀(τ)+εx₁(τ)+ε²x₂(τ)+ (100)
assuming that the each order solutions x₀x₁, . . . are periodic functions. Also, the damping term

$$h ( \frac{ⅆ x}{ⅆ t} , x )$$

is the sum of powers of ε as

$$h ( \frac{ⅆ x}{ⅆ t} , x ) = {h}_{0} ( \frac{ⅆ {x}_{0}}{ⅆ t} , {x}_{0} ) + ɛ {h}_{1} ( \frac{ⅆ {x}_{1}}{ⅆ t} , \frac{ⅆ {x}_{0}}{ⅆ t} , {x}_{1} , {x}_{0} ) + …$$

For obtaining each coefficient of the order of ε, h₀, h₁, . . . need to be further calculated. In a sequel, for each order of ε, the system (97) is perturbed as follows

$$\begin{matrix}\frac{{ⅆ}^{2} {x}_{0}}{ⅆ {t}^{2}} + {N}^{2} {x}_{0} = {\sum }_{n \neq N}^{∞} {A}_{n} cos n τ + {B}_{n} sin n τ & ( 101 ) \\ \frac{{ⅆ}^{2} {x}_{1}}{ⅆ {t}^{2}} + {N}^{2} {x}_{1} = - h ( \frac{ⅆ {x}_{0}}{ⅆ t} , {x}_{0} ) - β {x}_{0} + A cos N τ + B sin N τ & ( 102 ) \\ \frac{{ⅆ}^{2} {x}_{2}}{ⅆ {t}^{2}} + {N}^{2} {x}_{2} = - {h}_{1} ( \frac{ⅆ {x}_{1}}{ⅆ t} , \frac{ⅆ {x}_{0}}{ⅆ t} , {x}_{1} , {x}_{0} ) - β {x}_{1} & \end{matrix}$$

and so on. The solution of equation (101) is

$$\begin{matrix}{x}_{0} ( τ ) = {a}_{0} cos N τ + {b}_{0} sin N τ + {\sum }_{n \neq N}^{∞} \frac{{A}_{n} cos n τ + {B}_{n} sin n τ}{{N}^{2} - {n}^{2}} \\ = {a}_{0} cos N τ + {b}_{0} sin N τ + ϕ ( τ )\end{matrix} \qquad ( 103 )$$

where a₀, b₀ are obtained by computing the next order periodic solution x₁. From equation (102), to be sure it is a periodic solution, it is equivalent to search the periodic function x₁ and satisfies equation (102) such that the right-hand side has no Fourier term of order N. The a₀, b₀ are obtained so as to solve the following equations

$$\begin{matrix}β {a}_{0} = - \frac{1}{π} {\int }_{0}^{2 π} h ( ( {a}_{0} cos N τ + {b}_{0} sin N τ + ϕ ( τ ) ) , \\ - {a}_{0} N sin N τ + {b}_{0} N cos N τ + {ϕ}^{′} ( τ ) ) cos N τ ⅆ τ + A\end{matrix}$$

$$and$$

$$\begin{matrix}β {b}_{0} = - \frac{1}{π} {\int }_{0}^{2 π} h ( ( {a}_{0} cos N τ + {b}_{0} sin N τ + ϕ ( τ ) ) , \\ - {a}_{0} N sin N τ + {b}_{0} N cos N τ + {ϕ}^{′} ( τ ) ) sin N τ ⅆ τ + B\end{matrix}$$

In a sequel, the approximated solution of the system (97) is then obtained from this perturbation method for the small parameter ε as the equation (100). In other words, the system is perturbed by the small parameter ε and the worst case is caused to the harmonic [18, Chapter 5] or subharmonic [18, Chapter 6] waveforms appearance. Also from equation (103), this solution is divided into two parts: the resonance N and the non-resonant part φ(τ). For taking another perturbation method into consideration, singular perturbation method [18, Chapter 6], we should prevent the system from the singularity occurrence. For instance, the inductance is less precisely determined but brings out the system singularity. It is necessary to take away a small inductance.

For example, if the system is

$$\frac{{ⅆ}^{2} x}{ⅆ {t}^{2}} + \frac{1}{{n}^{2}} x = Γ cos t$$

all solutions of this simple system are

$$x ( t ) = a cos ( \frac{t}{n} ) + b sin ( \frac{t}{n} ) - \frac{{n}^{2} Γ}{{n}^{2} - 1} cos t$$

If n is an integer, the period is 2nπ. The response is said to be a “subharmonic” of order 1/n. For considering the case of rectification, let the system be

$$\frac{{ⅆ}^{2} x}{ⅆ {t}^{2}} + {Ω}^{2} x - ɛ {x}^{2} = Γ cos t$$

where ε>0. Taking the form of solutions as equation (100), assumed that firstly Ω is not closed to an integer, then

$$\frac{{ⅆ}^{2} {x}_{0}}{ⅆ {t}^{2}} + {Ω}^{2} {x}_{0} = Γ cos t$$

$$\frac{{ⅆ}^{2} {x}_{1}}{ⅆ {t}^{2}} + {Ω}^{2} {x}_{1} = {x}_{0}^{2}$$

The first-order periodic solution is

$${x}_{0} ( t ) = \frac{Γ}{{Ω}^{2} - 1} cos t$$

and of course the 2^{nd}-order solution is

$$\begin{matrix}\frac{{ⅆ}^{2} {x}_{1}}{ⅆ {t}^{2}} + {Ω}^{2} {x}_{1} = {( \frac{Γ}{{Ω}^{2} - 1} )}^{2} {cos}^{2} t \\ = \frac{1}{2} {( \frac{Γ}{{Ω}^{2} - 1} )}^{2} ( 1 + cos 2 t )\end{matrix}$$

$$i . e . , \\ {x}_{1} = \frac{1}{2 {Ω}^{2}} {( \frac{Γ}{{Ω}^{2} - 1} )}^{2} + \frac{1}{2 ( {Ω}^{2} - 4 )} {( \frac{Γ}{{Ω}^{2} - 1} )}^{2} cos 2 t + a cos Ω t + b sin Ω t$$

Since x₁(t) is a period 2π function, i.e., a =b=0

Therefore the solution can be expressed as

$$x ( t , ɛ ) = \frac{Γ}{{Ω}^{2} - 1} cos t + ɛ [ \frac{1}{2 {Ω}^{2}} {( \frac{Γ}{{Ω}^{2} - 1} )}^{2} + \frac{1}{2 ( {Ω}^{2} - 4 )} {( \frac{Γ}{{Ω}^{2} - 1} )}^{2} cos 2 t ]$$

Now suppose that the Ω is close to one, i.e., Ω≈1, and also assume that
Ω²=1+εβ
Γ=εγ
the system becomes

$$\frac{{ⅆ}^{2} x}{ⅆ {t}^{2}} + x = ɛ ( γ cos t + {x}^{2} - β x )$$

$$then$$

$$\frac{{ⅆ}^{2} {x}_{0}}{ⅆ {t}^{2}} + {x}_{0} = 0$$

$$\frac{{ⅆ}^{2} {x}_{1}}{ⅆ {t}^{2}} + {x}_{1} = ɛ ( γ cos t + {x}_{0}^{2} - β {x}_{0} )$$

Similarly, the solution is

$$x ( ɛ , t ) \approx \frac{γ}{β} cos t + ɛ ( \frac{1}{2} {( \frac{γ}{β} )}^{2} - \frac{1}{6} {( \frac{γ}{β} )}^{2} cos 2 t + {a}_{1} cos t + {b}_{1} sin t )$$

where a₁, b₁ are obtained for next order solution. Finally, we can obtain a conclusion that harmonic source is brought in if performing rectification. And the sources of (sub)harmonic are contributed from the material properties which totally in term of ε and nonlinear damping and spring terms

$$h ( \frac{ⅆ x}{ⅆ t} , x ) ,$$

we say:

$$ɛ h ( \frac{ⅆ x}{ⅆ t} , x ) \qquad ( 104 )$$

and a near integer
Ω. (105)

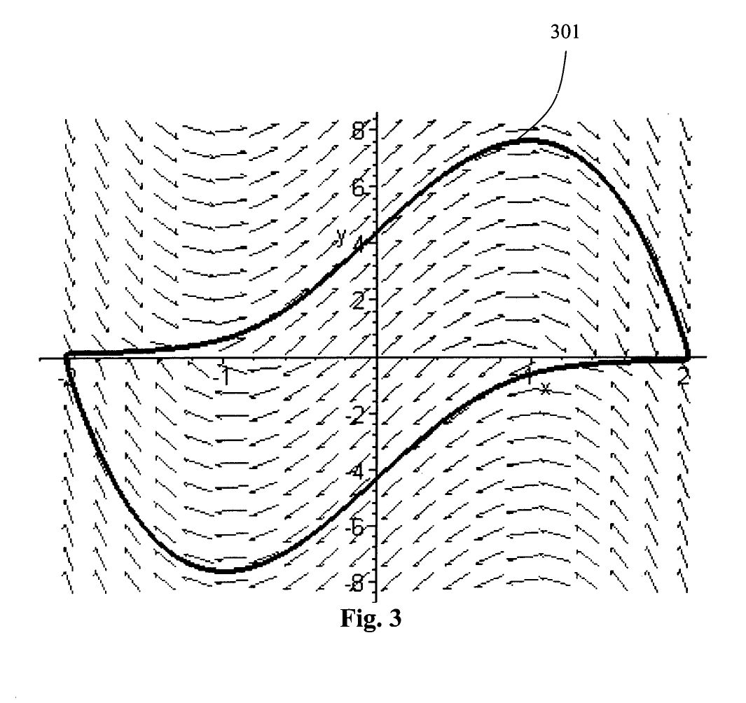

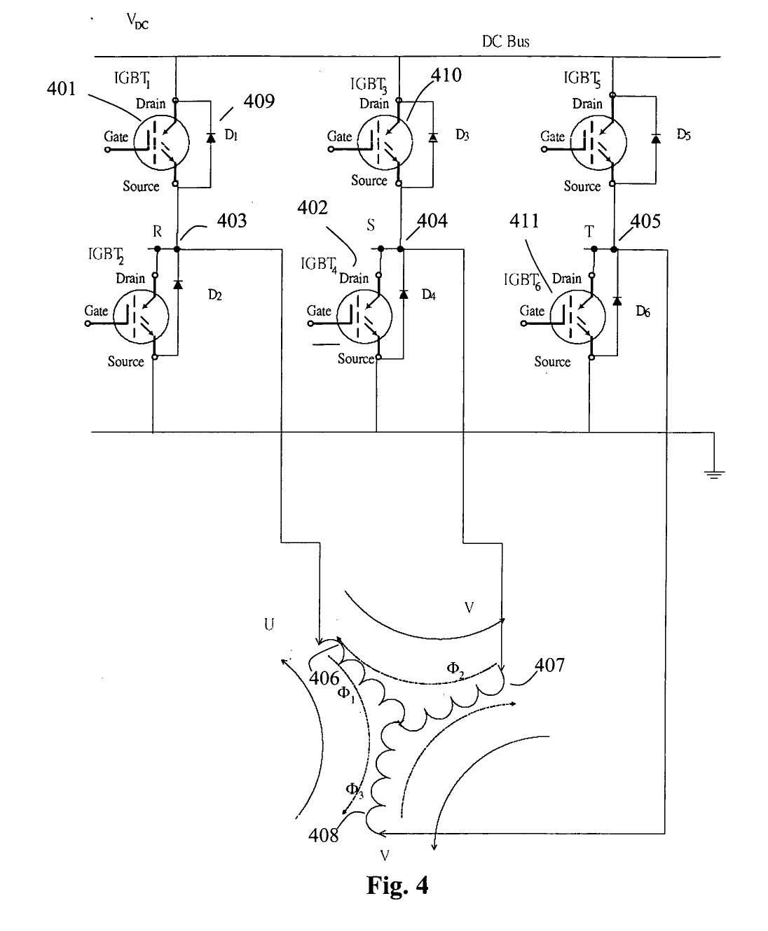

We have already assumed that there exist the periodic solutions in the equation (97). These periodic solutions are the “limit cycles” as disclosed in [27] and [18, Chapter 6]. As shown in FIG. 3 (refer to the website http:/hopf.chem.brandeis.edu/yanglingfa/pattern/rd), if the state is located outside the closed phase orbit 301 (labeled as bold-line), the arrows are inward, i.e., α-limit cycle, and vice versa, ω-limit cycle.

A straightforward skill for finding a limit cycle in planar system (97) is Poincaré-Bendixson theorem. Under this theorem, any closed phase orbit of system as the form shown in equation (97) implies that the system has a nontrivial periodic solution. Furthermore, let a closed orbit be γ and suppose that the domain Ω of the system (97) includes the whole open region U enclosed by this closed orbit γ, then U contains either an equilibrium or limit cycle. The corresponding limit cycle exists too. The system (97) can be parameterized by the parameter ε and the eigenvalue character of an equilibrium perturbed by this parameter ε suddenly from a sink to a source.

G Hopf's Bifurcation

In the real world, referring to [27] and [24, Chapter 3], the electrical circuit is modelled by Kirchhoff's law as a dynamical system and encounters this differential equation with the parameter, for example, temperature or frequency. Consider an autonomous dynamic system

$$\frac{ⅆ x}{ⅆ t} = {g}_{μ} ( x )$$

where μ is the parameter and is allowed to vary over some parameter space, for instance, −1≦μ≦1, and it may be the temperature of resistor, cooling rate and so on. Then its phase orbit change is very dependent on the variation of parameter μ. Now restrict to the simple case as shown in FIG. 18, the system becomes

$$[ \begin{matrix}\frac{ⅆ x}{ⅆ t} \\ \frac{ⅆ y}{ⅆ t}\end{matrix} ] = [ \begin{matrix}y - {f}_{μ} ( x ) \\ - x\end{matrix} ] \qquad ( 106 )$$

and puts the input function as
f_{μ}(x)=x³−μx
(see [27], [78] and [15] for details). We summarize as follows: for each
−1≦μ≦1,
the resistor is passive and all solutions tend asymptotically to be zero as t→∞. It means that the circuit is dead after a period of transition, and all currents and voltages stay at zero or close to zero. But if μ crosses zero, the circuit becomes alive and oscillating. When
0<μ≦1
, the system (106) has a unique periodic solution γ_{μ} and the origin becomes a source. If −1≦μ<0, the origin of the system (106) is a sink. For the system (106), μ=0 is the bifurcation value of the parameter. In conclusion, if a system is alive, it should be parameterized by some kind of parameter. Frequency is chosen to parameterize a system in the present invention.
H Nonlinear Systems Identification Scenario

For identifying and extracting some specific information from one unknown nonlinear systems, to scan all resonant points over the ultra band domain and construct a resonance vector as shown in equation (87) by the order-∞ resonant tank is proposed:
Ω=[ω₁, ω₂, . . . , ωₙ] (87)
wherein elements are consisted of all identified resonant points. Also there is a nonzero integer-value vector, called the resonance index,
M=[m₁, m₂, . . . , mₙ] (88)
for which the resonance condition
(M,Ω)=0
holds. Once the resonance vector and index are determined, the resonance hypersurface would be easily established. All of system information can be extracted from this resonance hypersurface.

### I Reference

[1] D. Tollik A. Pietkiewicz. Snubber circuit and mosfet paralleling considerations for high power boost-based powerfactor correctors, 1995.
[2] Bovas Abraham and Johannes Ledolter. Statistical Methods for Forecasting. John Wiley and Sons, Inc., 1983.
[3] Sam Haddad Andrew D. Dimarogonas. Vibration for Engineers. Prentice-Hall, Inc., http://www.prenticehall.com/, 1992.
[4] Tom M. Apostol. Mathematical Analysis. Addison-Wesley Publishing Company, http://www.aw-bc.com/, 2nd edition, 1975.
[5] V. I. Arnold. Geometrical Methods in the Theory of Ordinary Differential Equations. Springer-Verlag, http://www.springer.com/, 2nd edition, 1996.
[6] Yaakov Bar-Shalom. MulitTarget-MultiSensor Tracking: Applications and Advances Vol. 3. YBS, 2000.
[7] Yaakov Bar-Shalom and Thomas E. Fortmann. Tracking and Data Association. Academic Press, Inc., 1988.
[8] Sam Ben-Yaakov and Gregory Ivensky. Passive lossless snubbers for high frequency pwm converters.
[9] S. Ben-Yakov. Efficiency snubbers for voltage-source gto inverters, 1992.
[10] S. Ben-Yakov. analysis of snubber circuit, 1997.
[11] Niclas Bergman. Recursive Bayesian Estimation: Navigation and Tracking Applications. PhD thesis, 1999.
[12] George E. P. Box, G. M. Jenkins, and Gregory C. Reinsel. Time Series Analysis, Forecasting and Control. Prentice-Hall Inc., http://vig.prenhall.com, 3rd edition, 1994.
[13] O. Calvo, J. Cartwright, D. Gonz, O. Piro, and F. Sportolari. Three-frequency resonances in coupled phase-locked loops, 1998.
[14] O. Calvo, J. H. E. Cartwright, D. L. Gonzalez, O. Piro, and O. A. Rosso. Three-frequency resonances in dynamical systems. Int. J of Bifurcation and Chaos, 9(11):2181-2187, 1999.
[15] W. C. Y. Chan and C. K. Tse. Bifurcations in current-programmed DC/DC buck switching regulators—conjecturing a universal bifurcation path. Int. J. Circ. Theor. And Appl., 26(2):127-145, 1998.
[16] M. Chow, K. Siu, C. Tse, and Y. Lee. A novel method for elimination of line current harmonics in single-stage pfc regulators, 1998.
[17] S. Cooper. A Frequency Response Method for Sensor Suite Selection with Application to High-Speed Vehicle Dynamic Map Building and Localization New Theoretical Foundation. PhD thesis, University of Oxford, 1995.
[18] Peter Smith D. W. Jordan. Nonlinear Ordinary Differential Equations. Oxford University Press, http://www.oup.co.uk/academic/, 1985.
[19] Wei Dong. Analysis and Evaluation of Soft-switching Inverter Techniques in Electric Vehicle Applications. PhD thesis, Virginia Polytechnic Institute, 2003.
[20] G. N. Watson E. T. Whittaker. A Course of Modern Analysis. Cambridge Mathematical Library, http://www.cambridge.org, 4th edition, 1975.
[21] Schramm Buss Federal. Mathematical analysis of a new harmonic cancellation technique of the input line current in dicm boost converters, 1998.
[22] Canales Abarca Francisco Venustiano. Novel DC/DC Converters For High-Power Distributed Power Systems. PhD thesis, Virginia Polytechnic Institute, 2003.
[23] Frank Gross. Smart Antennas for Wireless Communications. McGraw-Hill Professional, 2005.
[24] John Guckenheimer and Philip Holmes. Nonlinear Oscillations, Dynamical Systems, and Bifurcations of Vector Fields. Springer-Verlag, http://www.springer.com/, 1997.
[25] Daniel W. Hart. Introduction to Power Electronics. Printice Hall Inc., 2nd edition, 1997.
[26] Andrew C. Harvey. Forecasting, Structural Time Series Models and the Kalman Filter. Cambridge University Press, 1991.
[27] Morris W. Hirsh and Stephen Smale. Differential Equations, Dynamical Systems and Linear Algebra. Academic Press, http://www.academicpress.com/, 1974.
[28] Electric Power Research Institute. Voltage-sag solutions for industrial customers, 2003.
[29] Petros A. Ioannou. Automated Highway Systems. Plenum Press, http://www.plenum.com, 1997.
[30] K. H. Werner J. Holtz/S. Salma. A nondissipative snubber circuit for high-power gto inverters, 1989.
[31] Andrew H. Jazwinski. Stochastic Processes and Filtering Theory, volume 64 of Mathematics in Science and Engineering. Academic Press, New York and London, 1970.
[32] K. L. Johnson. Contact Mechanics. Cambridge University Press, 1987.
[33] Mark Smith Jr. Properties and synthesis of passive, lossless soft-switching pwm converters.
[34] Simon Julier. Navigation and Parameter Estimation of High Speed Road Vehicles. PhD thesis, University of Oxford, 1998.
[35] B O Jacobson/Joost Kalker. Rolling Contact Phenomena. Springer Wien New York, 2000.
[36] Myron Kayton and Walter Fried. Avionics Navigation Systems. John Wiley and Sons Ltd., 2ed edition, 1997.
[37] P Gomes L. Freitas. A high-power high frequency zcs-zvs-pwm buck converter using a feedback resonant circuit, 1993.
[38] Anthony Lawrence. Modern Inertial Technology. Springer-Verlag, 1998.
[39] H. Levy, I. Zafrani, G. Ivensky, and S. Ben-Yaakov. Analysis and evaluation of a lossless turn-on snubber.
[40] A. E. H. Love. Advanced Mechanics of Materials. Dover Publications Inc., 4th edition, 1944.
[41] Edward M. Nakauchi Mark I. Montrose. Testing for EMC Compliance: Approaches and Techniques. Wiley-IEEE Press, 2004.
[42] James L. McClelland and David E. RumeLhart. Parallel Distributed Processing., volume 2. MIT Press, http://www.mitpress.com, tenth printing edition, 1986.
[43] Sebastien E. Gay /Ali Emadi. Mehrdad Ehsani/Yimin Gao. Modern Electric, Hybrid Electric, And Fuel Cell Vehicles: Fundamentals, Theory, And Design. CRC Press, http://www.crcpress.com, 2004.
[44] Thomas A. Milligan. Modern Antenna Design. IEEE Press, 2nd edition, 2005.
[45] Arthur G. O. Mutambara. Decentralized Estimation and Control for Multisensor Systems. CRC Press, 1998.
[46] Christopher Nwagboso. Advanced Vehicle and Infrastructure Systems. John Wiley and Sons Ltd., 1997.
[47] U.S. Department of Energy. Fuel Cell Handbook. U.S. Department of Energy, http://www.nrel.gov, 5th edition, 2000.
[48] U.S. Department of Energy. 21st Century Complete Guide to Hydrogen Power Energy and Fuel Cell Cars. U.S. Department of Energy, http://www.nrel.gov, 2003.
[49] Jan Palmqvist. On Integrity Monitoring of Integrated Navigation Systems. PhD thesis, Linkoping University, 1997.
[50] Michael A. Peavey. Fuel From Water: Energy Independence With Hydrogen. Merit, Inc., http://www.manhattanproject.com, 11th edition, 2003.
[51] W. H. Press, W. T. Vetterling, S. A. Teukolsky, and B. P. Flannery. Numerical Recipes in C. Cambridge University Press, 2nd edition, 1992.
[52] Jinrong Qian. Advanced Single-Stage Power Factor Correction Techniques. PhD thesis, Virginia Polytechnic Institute, 1998.
[53] D. Maksimovic R. Erickson. Fundamentals of Power Electronics. Kluwer Academic Publishers, http://ece-www.colorado.edu/pwrelect, 2nd edition, 2000.
[54] Paulo F. Ribeiro. Energy storage systems for advanced power applications.
[55] Paulo F. Ribeiro. Future analysis tools for power quality.
[56] Paulo F. Ribeiro. New harmonic diagnostic indices a proposition for discussion, 2002.
[57] Sheldon M. Ross. Introduction to Probability and Statistics for Engineers and Scientists. Academic Press, http://www.academicpress.com, second edition, 2000.
[58] K. Smith and K. Smedley. A comparison of voltage mode soft switching methods for pwm converters, 1996.
[59] K. Mark Smith, Jr., and K. M. Smedley. Lossless, passive soft switching methods for inverters and amplifiers.
[60] Robert W. Wills Stephen L. Ruggles. Phase-lock-loop application for fiber optic receiver, 1991.
[61] Gilbert Strang and Kai Borre. Linear Algebra, Geodesy, and GPS. Wellesley-Cambridge Press, Wellesley Mass., 1997.
[62] Roger C. Dugan/Mark F. McGranaghan Surya Santoso/H. Wayne Beaty. Electrical Power Systems Quality. McGraw-Hill Inc., 2nd edition, 2002.
[63] T. Rogne/M. Hernes T. Undeland/F. Jenset/A. Steinbakk. A snubber configuration for both power transistors and gto pwm inverters, 1993.
[64] S. P. Timoshenko and J. N. Goodier. Theory of Elasticity. McGRAW-HILL Book Company, 1970.
[65] Phillip C. Todd. Snubber circuits: Theory, design and application.
[66] Keith B. Wipke/Ahmad A. Pesaran Tony Markel/Matthew Zolot. Energy storage system requirements for hybrid fuel cell.
[67] T. D. Geist T. S. Key/H. E. Sitzlar. Fast response, load-matching hybrid fuel cell: Final technical progress report.
[68] Jeffrey Uhlmann. Dynamic Map Building and Localization New Theoretical Foundation. PhD thesis, University of Oxford, 1995.
[69] D. Rausen V. Johnson/K. Wipke. Hev control strategy for real-time optimization of fuel economy and emissions, 2000.
[70] William G. Dehard. Walter Wrigely/Walter M. Hollister. Gyroscope Theory, Design and Instrumentation. MIT Press, 1969.
[71] Mike West and Jeff Harrison. Bayesian Forecasting and Dynamic Models. Springer-Verlag New York Inc., http://www.springeronline.com, 2nd edition, 1999.
[72] Tim Williams. EMC for Product Designers. Elsevier Science and Technology, http://www.newnespress.com, 3rd edition, 2001.
[73] Dan H. Wolaver. Phase-Locked Loop Circuit Design. Printice Hall Inc., 1991.
[74] Matthew Sands. W Richard P. Feynman/Robert B. Leighton. Feynman Lectures On Physics: The Complete And Definitive Issue, volume 3. Addison Wesley Publishing Company, http://www.aw-bc.com, 2nd edition, 1964.
[75] A. David Wunsch. Complex Variables with Applications. Addison-Wesley Publishing Company Inc., http://www.aw-bc.com/, 1983.
[76] B. Williams/T. Green X. He/S. Finney. An improved passive lossless turn-on and turn-off snubber, 1993.
[77] Bo Yang. Topology investigation of front end DC/DC converter for distributed power system. PhD thesis, Virginia Polytechnic Institute, 2003.
[78] I. Zafrany and S. Ben-Yaakov. A chaos model of subharmonic oscillations in current mode pwm boost converters, 1995.
[79] Peter W. A. Zegelaar. The Dynamic Response of Tyres To Brake Torque Variations and Road Univennesss. Delft University of Technology, 1998.
[80] Richard S. Zhang. High Performance Power Converter Systems for Nonlinear and Unbalanced Load/Source. PhD thesis, Virginia Polytechnic Institute, 1998.
[81] Yilin Zhao. Vehicle Location and Navigation Systems. Artech House, Inc., 1997.

1. A spectral resistor, wherein
at least a part of said spectral resistor is made of a dielectric material; and
the resistance of said spectral resistor monotonically increases with increasing frequency.

2. The spectral resistor as claimed in claim 1, wherein said dielectric material is GaAs.

3. The spectral resistor as claimed in claim 1, wherein said dielectric material is BaTiO₃.

4. A spectral resistor, wherein
at least a part of said spectral resistor is made of a dielectric material; and
the resistance of said spectral resistor monotonically decreases with increasing frequency.

5. The spectral resistor as claimed in claim 4, wherein said dielectric material is metal oxide.

6. A spectral resistor, wherein the resistance of said spectral resistor monotonically decreases with increasing frequency, and said spectral resistor is a substantial Gunn diode.

7. A spectral resistive element, wherein
the resistance of a first part of said spectral resistive element monotonically increases with increasing frequency, while the resistance of a second part of said spectral resistive element monotonically decreases with increasing frequency; and
wherein said first part is electrically connected in series to said second part.

8. The spectral resistive element as claimed in claim 7, wherein at least a portion of said first part is made of GaAs.

9. The spectral resistive element as claimed in claim 7, wherein at least a portion of said first part is made of BaTiO₃.

10. The spectral resistive element as claimed in claim 7, wherein at least a portion of said second part is made of metal oxide.

11. The spectral resistive element as claimed in claim 7, wherein said first part is a substantial resistor, and said second part is also a substantial resistor.

12. The spectral resistive element as claimed in claim 7, wherein said second part is a substantial Gunn diode.

13. A spectral resistive element, wherein
the resistance of a first part of said spectral resistive element monotonically increases with increasing frequency, while the resistance of a second part of said spectral resistive element monotonically decreases with increasing frequency; and
wherein said first part is electrically connected in parallel to said second part.

14. The spectral resistive element as claimed in claim 13, wherein at least a portion of said first part is made of GaAs.

15. The spectral resistive element as claimed in claim 13, wherein at least a portion of said first part is made of BaTiO₃.

16. The spectral resistive element as claimed in claim 13, wherein at least a portion of said second part is made of metal oxide.

17. The spectral resistive element as claimed in claim 13, wherein said first part is a substantial resistor, and said second part is also a substantial resistor.

18. The spectral resistive element as claimed in claim 13, wherein said second part is a substantial Gunn diode.

19. A substantial order-∞ resonant tank, comprising:
a spectral resistive element as claimed in claim 7;
a substantial capacitive element; and
a substantial inductive element;
wherein said spectral resistive element, said substantial capacitive element and said substantial inductive element are electrically connected to form a substantial order-∞ resonant circuit.

20. The substantial order-∞ resonant tank as claimed in claim 19, wherein said substantial inductive element can be a conductive line, a system with equivalent inductance, or an inductor.

21. The substantial order-∞ resonant tank as claimed in claim 19, wherein said substantial capacitive element can be a capacitor, a system with equivalent capacitance, or two conductive parts.

22. A substantial order-∞ electric filter, for electrically connecting to a substantial inductive circuit to perform filtering operation, comprising
a substantial order-28 resonant tank as claimed in claim 19;
wherein said substantial order-∞ resonant tank is electrically connected in parallel to said substantial inductive circuit.

23. The substantial order-∞ electric filter as claimed in claim 22, wherein said electric filter is functioned as a substantial all-pass filter.

24. The substantial order-∞ electric filter as claimed in claim 22, wherein said electric filter is functioned as a DeLenzor.

25. A harmonic and sub-harmonic power waveform distortion filter, for electrically connecting to a substantial inductive circuit to filter out harmonic and sub-harmonic power waveform distortion, comprising
a substantial order-∞ resonant tank as claimed in claim 19;
wherein said substantial order-∞ resonant tank is electrically connected in parallel to said substantial inductive circuit.

26. A dynamic damper, for electrically connecting to a substantial inductive circuit to perform damping operation, comprising
a substantial order-∞ resonant tank as claimed in claim 19;
wherein said substantial order-∞ resonant tank is electrically connected in parallel to said substantial inductive circuit.

27. An universal dissipative unit, for electrically connecting to a substantial inductive circuit to perform power dissipation operation, comprising
a substantial order-∞ resonant tank as claimed in claim 19;
wherein said substantial order-∞ resonant tank is electrically connected in parallel to said substantial inductive circuit.

28. The universal dissipative unit as claimed in claim 27, wherein said universal dissipative unit is a universal frequency modulation dissipative unit

29. A sparkless electric switch circuit, comprising:
a switching element; and
a substantial order-∞ resonant tank as claimed in claim 19;
wherein said substantial order-∞ resonant tank is electrically connected in parallel to said switching element.

30. An inertial navigation system, comprising:
a sensing element; and
a substantial order-∞ resonant tank as claimed in claim 19;
wherein said substantial order-∞ resonant tank is electrically connected to said sensing element for extracting pure AC signal from an output of said sensing element.

31. A dynamic impedance matching circuit, for performing impedance matching with at least one nonlinear load, comprising
a substantial order-∞ resonant tank as claimed in claim 19;
wherein said substantial order-∞ resonant tank is electrically connected in parallel to said at least one nonlinear load.

32. A dynamic power factor corrector circuit, receiving power from an external power source and connected to at least one nonlinear load, comprising:
a switching element;
a switching controller; and
a substantial order-∞ resonant tank as claimed in claim 19;
wherein said substantial order-∞ resonant tank is electrically connected in parallel to said at least one nonlinear load;
wherein said dynamic power factor corrector circuit receives power in a first form from said external power source, converts said power from said first form to a second form by switching said switching element on and off at an adjustable frequency, and provides said power in said second form to said at least one nonlinear load; and
wherein said adjustable frequency is controlled by said switching controller according to said at least one nonlinear load.

33. The dynamic power factor corrector circuit as claimed in claim 32, wherein said switching controller is a pulse-width modulation controller.

34. The dynamic power factor corrector circuit as claimed in claim 32, further comprising:
a transformer; and
a AC-to-DC converter;
wherein said transformer regenerates power from the current induced by said at least one nonlinear load and extracted by said substantial order-∞ resonant tank, and said AC-to-DC converter converts said regenerated power to become DC power.

35. The dynamic power factor corrector circuit as claimed in claim 34, wherein said DC power is provided to an external electric energy storage device.

36. The dynamic power factor corrector circuit as claimed in claim 34, further comprising a DC bus, wherein said DC power is provided to said DC bus.

37. The dynamic power factor corrector circuit as claimed in claim 34, further comprising an electric energy storage element, wherein said DC power is provided to said electric energy storage device.

38. An uninterruptible power supply apparatus, comprising a dynamic power factor corrector circuit as claimed in claim 37, wherein said uninterruptible power supply apparatus provides power to said at least one nonlinear load from said electric energy storage device.

39. A redundant uninterruptible power supply system, comprising a plurality of uninterruptible power supply apparatuses as claimed in claim 38; wherein said plurality of uninterruptible power supply apparatuses are electrically connected in parallel to each other.

40. An electric power resource management system, comprising:
a dynamic power factor corrector circuit as claimed in claim 32;
wherein said dynamic power factor corrector circuit reports power status data to said external power source; and
wherein said external power source calculates a future need of power of said at least one nonlinear load by using said power status data and a prediction algorithm.

41. The electric power resource management system as claimed in claim 40, wherein said external power source can be a power plant, a transformer station, a power converter or a power inverter.

42. An electric power resource management system, comprising:
a dynamic power factor corrector circuit as claimed in claim 32;
wherein said dynamic power factor corrector circuit calculates a future need of power of said nonlinear load by using a prediction algorithm and reports the calculated data to said external power source.

43. The electric power resource management system as claimed in claim 42, wherein said external power source can be a power plant, a transformer station, a power converter or a power inverter.

44. A pseudo vacuum tube power amplifier, connected between an audio signal source and a speaker, comprising
a dynamic power factor corrector circuit as claimed in claim 32; wherein said dynamic power factor corrector circuit receives audio signal from said audio signal source, amplifies said audio signal, and provides the amplified audio signal to said speaker.

45. An electromagnetic wave absorbing material, comprising:
a first dielectric material; and
a second dielectric material;
wherein at least a part of said first dielectric material is substantially electrically connected to at least a part of said second dielectric material; and
wherein the resistance of said first dielectric material monotonically increases with increasing frequency, and the resistance of said second dielectric material monotonically decreases with increasing frequency.

46. The electromagnetic wave absorbing material as claimed in claim 45, wherein said first dielectric material is GaAs.

47. The electromagnetic wave absorbing material as claimed in claim 45, wherein said first dielectric material is BaTiO₃.

48. The electromagnetic wave absorbing material as claimed in claim 45, wherein said second dielectric material is metal oxide.

49. A microwave absorber, comprising:
a surface; and
an electromagnetic wave absorbing material as claimed in claim 45;
wherein said electromagnetic wave absorbing material is arranged on said surface.

50. An electrostatic discharge protector, comprising:
a surface; and
an electromagnetic wave absorbing material as claimed in claim 45;
wherein said electromagnetic wave absorbing material is arranged on said surface.

51. An antenna, comprising:
a surface; and
an electromagnetic wave absorbing material as claimed in claim 45;
wherein said electromagnetic wave absorbing material is arranged on said surface and is substantially electrically connected to said surface.

52. A radio frequency identification device comprising a radio frequency identification controller and an antenna as claimed in claim 51, wherein said antenna is electrically connected to said controller.

53. A nuclear power converting apparatus, comprising:
a nuclear material;
a container, containing said nuclear material; and
an electromagnetic wave absorbing material as claimed in claim 45;
wherein said electromagnetic wave absorbing material is arranged on at least a part of the surface of said container to extract electric power from radioactive decay energy released by said nuclear material.

54. The nuclear power converting apparatus as claimed in claim 53, further comprising:
a AC-to-DC converter, electrically connected to said at least part of the surface of said container for converting the extracted electric power to be DC power.

55. A data transmission bus, electrically connected to digital controllers, comprising:
an electromagnetic wave absorbing material as claimed in claim 45.

56. The data transmission bus as claimed in claim 55, wherein said data transmission bus can be a control bus, an address bus or a data bus.

57. A fanless cooling system, for electrically connecting to a substantial inductive circuit, comprising:
a substantial order-∞ resonant tank as claimed in claim 19;
wherein said substantial order-∞ resonant tank is electrically connected in parallel to said substantial inductive circuit to perform power dissipation.

58. A spectral capacitor, comprising:
a first plate;
a second plate;
a first dielectric material; and
a second dielectric material;
wherein said first and second dielectric materials are arranged between said first plate and said second plate; and
wherein the capacitance of said first dielectric material monotonically increases with increasing frequency, and the capacitance of said second dielectric material monotonically decreases with increasing frequency.

59. The spectral capacitor as claimed in claim 58, wherein said first dielectric material is GaAs.

60. The spectral capacitor as claimed in claim 58, wherein said first dielectric material is BaTiO₃.

61. The spectral capacitor as claimed in claim 58, wherein said second dielectric material is metal oxide.

62. An adaptive voltage controlled oscillator circuit, comprising:
a spectral capacitor as claimed in claim 58; and
a voltage controlled oscillator;
wherein said spectral capacitor is connected in parallel to the input of said voltage controlled oscillator.

63. A phase-locked loop circuit, comprising:
a phase detector;
a low pass filter, connected to said phase detector; and
an adaptive voltage controlled oscillator circuit as claimed in claim 62;
wherein said voltage controlled oscillator circuit receives a signal from said low pass filter and provides a feedback signal to said phase detector.

64. A non-contact anti-skid braking system, used in a vehicle having a transmission line, comprising:
a rotor, driven by an element on said transmission line;
an electric power storage device;
a brake controller;
a pulse-width modulation controller, triggered by said brake controller to receive power from said electric power storage device and provide pulse-width modulated DC current to said rotor;
a stator; and
a substantial order-∞ resonant tank as claimed in claim 19, connected in series to said stator;
wherein when said DC current pass through said rotor, an AC current is induced at said stator and extracted by said substantial order-∞ resonant tank.

65. The non-contact anti-skid braking system as claimed in claim 64, wherein said pulse-width modulation controller is controlled by one or more of the factors including the strength sensed by said brake controller, the speed of said vehicle, and the tilt level of said vehicle.

66. The non-contact anti-skid braking system as claimed in claim 64, further comprising:
a AC-to-DC converter;
wherein said AC-to-DC converter receives the power extracted by said substantial order-∞ resonant tank, converts the received power to be DC power and provides said DC power to said electric power storage device.

67. A hybrid-electric vehicle, comprising a non-contact anti-skid braking system as claimed in claim 64.

68. The hybrid-electric vehicle as claimed in claim 67, further comprising a nuclear power converting apparatus as comprising:
a nuclear material,
a container containing said nuclear material, and
an electromagnetic wave absorbing material comprising:
a first dielectric material; and
a second dielectric material,
wherein at least a part of said first dielectric material is substantially electrically connected to at least a part of said second dielectric material; and
wherein the resistance of said first dielectric material monotonically increases with increasing frequency and the resistance of said second dielectric material monotonically decreases with increasing frequency;
wherein said electromagnetic wave absorbing material is arranged on at least a part of the surface of said container to extract electric power from radioactive decay energy released by said nuclear material;
and further comprising:
a AC-to-DC converter electrically connected to said at least part of the surface of said container for converting the extracted electric power to be DC power.

69. An electric vehicle, comprising a non-contact anti-skid braking system as claimed in 64.

70. The electric vehicle as claimed in claim 69, further comprising a nuclear power converting apparatus comprising:
a nuclear material,
a container, containing said nuclear material; and
an electromagnetic wave absorbing material comprising:
a first dielectric material; and
a second dielectric material;
wherein at least a part of said first dielectric material is substantially electrically connected to at least a part of said second dielectric material; and
wherein the resistance of said first dielectric material monotonically increases with increasing frequency and the resistance of said second dielectric material monotonically decreases with increasing frequency;
wherein said electromagnetic wave absorbing material is arranged on at least a part of the surface of said container to extract electric power from radioactive decay energy released by said nuclear material;
and further comprising:
a AC-to-DC converter, electrically connected to said at least part of the surface of said container for converting the extracted electric power to be DC power.

71. A power generating apparatus, for generating electrical energy, comprising:
a rotor, driven by a mechanical force;
a stator; and
a substantial order-∞ resonant tank as claimed in claim 19, connected in series to said stator;
wherein when said rotor is driven, an AC current is induced at said stator and extracted by said substantial order-∞ resonant tank.

72. A non-contact anti-crash transporting device, comprising:
a frame, for providing vertical transportation;
a first coil, arranged vertically in parallel to said frame without contact;
a second coil, attached to said frame;
a cable, connected to said frame;
a detector, for detecting an event of a breach of said cable and for providing a signal indicating said event;
a controller, for providing power to said first coil in response to said signal; and
a substantial order-∞ resonant tank as claimed in claim 19 connected in series to said second coil.

73. A switching-mode power converting apparatus, receiving power from an external power source and connected to at least one nonlinear load, comprising:
a switching element;
a switching controller;
a substantial order-∞ resonant tank as claimed in claim 19;
wherein said substantial order-∞ resonant tank is electrically connected in parallel to said at least one nonlinear load;
wherein said switching-mode power converting apparatus receives power in a first form from said external power source, converts said power from said first form to a second form by switching said switching element on and off at an adjustable frequency, and provides said power in said second form to said at least one nonlinear load; and
wherein said adjustable frequency is controlled by said switching controller according to said at least one nonlinear load.

74. The switching-mode power converting apparatus as claimed in claim 73, further comprising:
a transformer; and
a AC-to-DC converter;
wherein said transformer regenerates power from the current induced by said at least one nonlinear load and extracted by said substantial order-∞ resonant tank, and said AC-to-DC converter converts said regenerated power to become DC power.

75. An electric vehicle, comprising a switching-mode power converting apparatus as claimed in claim 73.

76. The electric vehicle as claimed in claim 75, further comprising a nuclear power converting apparatus comprising:
a nuclear material;
a container, containing said nuclear material; and
an electromagnetic wave absorbing material comprising:
a first dielectric material; and
a second dielectric material;
wherein at least a part of said first dielectric material is substantially electrically connected to at least a part of said second dielectric material; and
wherein the resistance of said first dielectric material monotonically increases with increasing frequency, and the resistance of said second dielectric material monotonically decreases with increasing frequency;
wherein said electromagnetic wave absorbing material is arranged on at least a part of the surface of said container to extract electric power from radioactive decay energy released by said nuclear material;
and further comprising:
a AC-to-DC converter, electrically connected to said at least part of the surface of said container for converting the extracted electric power to be DC power.
